(19) United States
(12) Patent Application Publication
(10) Pub. No.: US 2026/0344177 A1
(43) Pub. Date: Oct. 29, 2026

(54) ACTIVE MATRIX ORGANIC ELECTROLUMINESCENT DISPLAY

(71) Applicant: BEIJING SUMMER SPROUT TECHNOLOGY CO., LTD., Beijing (CN)

(72) Inventors: Zhihao CUI, Beijing (CN); Renjie ZHENG, Beijing (CN); Xiaoyong ZHANG, Beijing (CN); Wantian XU, Beijing (CN); Xingxing CHAI, Beijing (CN); Lei ZHAO, Beijing (CN); Chi Yuen Raymond Kwong, Beijing (CN); Chuanjun Xia, Beijing (CN)

(21) Appl. No.: 19/639,452

(22) Filed: Apr. 6, 2026

(30) Foreign Application Priority Data
Apr. 9, 2025 (CN) 202510436623.1

(51) Int. Cl. H10K 50/15; H10K 50/19; H10K 101/30; H10K 101/40; H10K 102/00

(52) U.S. Cl. CPC H10K 50/15; H10K 50/19; H10K 2101/30; H10K 2101/40; H10K 2102/351

(57) ABSTRACT

Disclosed is an active matrix organic electroluminescent display including a stacked organic electroluminescent device. The stacked organic electroluminescent device comprises a common P-type charge generation layer and a common hole transport layer. The common P-type charge generation layer comprises a first P-type conductive doping material and a first hole transport material, and the common hole transport layer comprises a second hole transport material. The HOMO energy level of the second hole transport material is deeper than the HOMO energy level of the first hole transport material. The common P-type charge generation layer and the common hole transport layer have a higher lateral resistance value, and when used in an active OLED display, can more significantly suppress lateral crosstalk between pixels in the display and maintain low voltage and high efficiency with excellent device performance, offering significant advantages for commercial applications.

### CROSS-REFERENCE TO RELATED APPLICATION(S)

This application claims priority to Chinese Patent Application No. 202510436623.1 filed on Apr. 9, 2025, the disclosure of which is incorporated herein by reference in its entirety.

### TECHNICAL FIELD

The present disclosure relates to an active matrix organic electroluminescent display. More particularly, the present disclosure relates to an active matrix organic electroluminescent display comprising a stacked organic electroluminescent device.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

In display applications, lateral crosstalk is one of the key issues affecting display performance. In particular, in high-resolution display applications, lateral crosstalk between pixels may reduce image clarity and degrade picture quality and thus becomes one of the key issues affecting display performance. An active matrix organic electroluminescent display including a stacked organic electroluminescent device generally contains common layers, and lateral crosstalk between pixels is typically caused by the common layers. When a significant number of holes migrate laterally from one pixel to other pixels through the common layers, the lateral migration can result in pixel or color crosstalk. As a result, when a specific pixel is intended to be illuminated, one or more adjacent pixels may also be lit, thereby causing an undesired crosstalk phenomenon. Blurred display images, color bleeding, reduced contrast, and other display issues are raised, thereby affecting the display performance of the display. Therefore, while ensuring excellent performance of individual pixels, such as low voltage and high efficiency, how to suppress or even eliminate lateral crosstalk between pixels has always been a critical focus of research and development in the industry.

### SUMMARY

The present disclosure discloses an active matrix organic electroluminescent display to solve at least part of the above-mentioned problems. The display comprises a stacked OLED. The stacked OLED comprises at least one common P-type charge generation layer and at least one common hole transport layer. The common P-type charge generation layer comprises a first P-type conductive doping material and a first hole transport material, and the common hole transport layer comprises a second hole transport material. The HOMO energy level of the second hole transport material is deeper than the HOMO energy level of the first hole transport material. The common P-type charge generation layer and the common hole transport layer have higher lateral resistance, and when used in an active OLED display, can more significantly suppress lateral crosstalk between pixels in the display and maintain excellent device performance such as low voltage and high efficiency, thereby offering significant advantages for commercial applications.

According to an embodiment of the present disclosure, an active matrix organic electroluminescent device is disclosed, which comprises multiple pixels;
wherein each of the multiple pixels at least comprises a stacked organic electroluminescent device; and
the stacked organic electroluminescent device comprises an anode, a cathode, at least one common P-type charge generation layer disposed between the anode and the cathode, and a common hole transport layer which is disposed between the common P-type charge generation layer and the cathode and is in direct contact with the common P-type charge generation layer;
wherein the common P-type charge generation layer and the common hole transport layer are shared by at least two adjacent pixels;
the common P-type charge generation layer comprises a first P-type conductive doping material and a first hole transport material;
the common hole transport layer comprises a second hole transport material;
the first hole transport material is different from the second hole transport material;
the HOMO energy level of the first hole transport material is HOMO₁, the HOMO energy level of the second hole transport material is HOMO₂, and HOMO₁−HOMO₂>0 eV; and
the common P-type charge generation layer and the common hole transport layer simultaneously meet the following two conditions:
(1) the lateral resistance of a film layer A formed by the common P-type charge generation layer and the common hole transport layer measured using interdigitated electrodes is R₁, and R₁≥15 MΩ; and
(2) R₁/R₂≥1.1, wherein R₂ is the lateral resistance of a film layer B measured using interdigitated electrodes, and the film layer B is identical to the film layer A except that the second hole transport material in the common hole transport layer of the film layer A is replaced with the first hole transport material.

The present disclosure discloses an active matrix organic electroluminescent display with a particular device structure. The active matrix organic electroluminescent display comprises a stacked OLED. The stacked OLED comprises a common P-type charge generation layer and a common hole transport layer. The common P-type charge generation layer comprises a first P-type conductive doping material and a first hole transport material, and the common hole transport layer comprises a second hole transport material. The HOMO energy level of the second hole transport material is deeper than the HOMO energy level of the first hole transport material. The common P-type charge generation layer and the common hole transport layer have higher lateral resistance, and when used in an active OLED display, can more significantly suppress lateral crosstalk between pixels in the display and maintain excellent device performance such as low voltage and high efficiency, thereby offering significant advantages for commercial applications.

### BRIEF DESCRIPTION OF DRAWINGS

FIG. 1 is a structure diagram of a single-layer organic light-emitting device.

FIG. 2 is a structure diagram of another single-layer organic light-emitting device.

FIG. 3 is a structure diagram of a stacked organic light-emitting device included in a display of the present disclosure.

FIG. 4 is a structure diagram of an active matrix organic electroluminescent display according to the present disclosure.

FIG. 5 is a schematic diagram of a device structure of a crosstalk test device.

FIG. 6 is a top view of interdigitated electrodes.

FIG. 7 is a partial section view of interdigitated electrodes.

### DETAILED DESCRIPTION

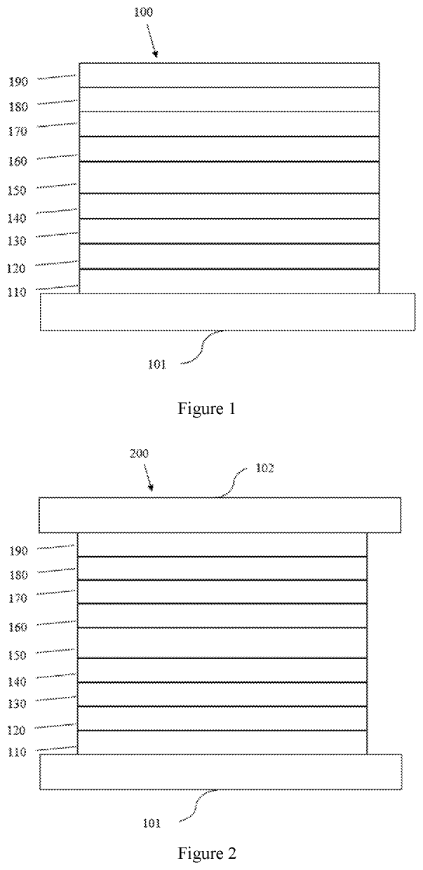

OLEDs can be fabricated on various types of substrates such as glass, plastic, and metal foil. FIG. 1 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

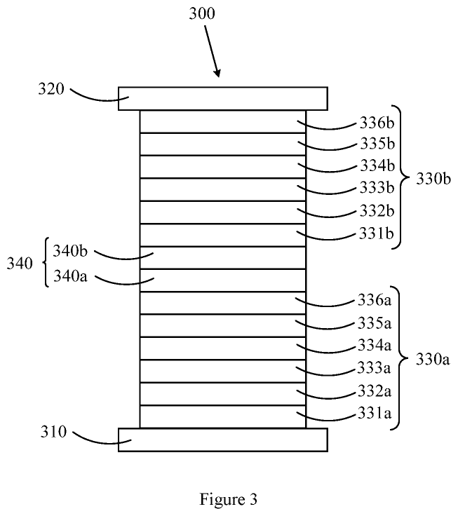

An OLED can be encapsulated by a barrier layer. FIG. 2 schematically shows an organic light emitting device 200 without limitation. FIG. 2 differs from FIG. 1 in that the organic light emitting device includes a barrier layer 102, which is above the cathode 190, to protect it from harmful species from the environment such as moisture and oxygen. The barrier layer can be a thin-film encapsulation with a thickness of less than 100 micrometers, which involves depositing one or more thin films directly onto the device, or it can be a cover glass adhered to a substrate. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Herein, two or more OLED units may be connected in series by a charge generation layer to form a stacked OLED. FIG. 3 schematically and non-restrictively illustrates a structure diagram of a stacked organic light-emitting device 300 included in a display of the present disclosure. The device 300 may include an anode 310, a first light-emitting unit 330a, a charge generation layer 340, a second light-emitting unit 330b and a cathode 320. The first light-emitting unit 330a includes a hole injection layer 331a, a hole transport layer 332a, an electron blocking layer 333a, a light-emitting layer 334a, a hole blocking layer 335a and an electron transport layer 336a. Certain layers in the first light-emitting unit may be omitted or other layers not explicitly described may also be included in the first light-emitting unit as needed, which is not repeated here. The charge generation layer 340 includes an N-type charge generation layer 340a and a P-type charge generation layer 340b. The N-type charge generation layer 340a may also have a function of an electron injection layer of the first light-emitting unit, the P-type charge generation layer 340b may also have a function of a hole injection layer of the second light-emitting unit, and the N-type charge generation layer may also be regarded as an electron injection layer. Other layers may also be included between the N-type charge generation layer 340a and the P-type charge generation layer 340b as needed. For example, a buffer layer may also be included between the N-type charge generation layer 340a and the P-type charge generation layer 340b, which is not shown in the figure. The second light-emitting unit 330b includes a hole transport layer 331b, an electron blocking layer 332b, a light-emitting layer 333b, a hole blocking layer 334b, an electron transport layer 335b, an electron injection layer 336b and a cathode 320. Other layers not explicitly described may also be included in the second light-emitting unit as needed. For example, a hole injection layer may also be included between the P-type charge generation layer 340b and the hole transport layer 331b, which is not shown in the figure. Certain layers in the second light-emitting unit may be omitted, which is not repeated here. An encapsulation layer may also be included above the cathode 320, which is not shown in the figure.

Active matrix OLED displays fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

As used herein, the term “independent driving” means that two or more OLEDs are controlled separately using active matrix driving technology where each pixel is controlled by an independent thin-film transistor (TFT). An active matrix organic electroluminescent display can independently control the light emission of each pixel so that the pixels can emit light continuously and independently, thereby finally forming a desired image.

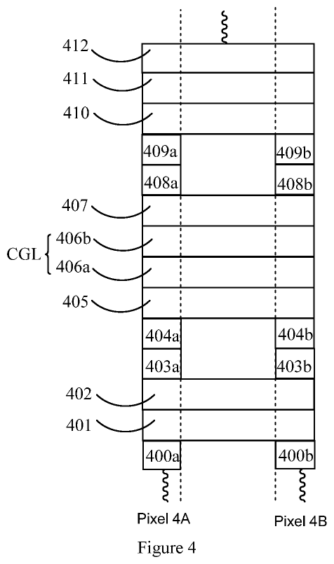

As used herein, the term “common P-type charge generation layer” refers to a common P-type charge generation layer that is shared by at least two adjacent pixels in an active matrix organic electroluminescent display, that is, the common P-type charge generation layer is continuous and undivided across multiple pixels, as illustrated by the common P-type charge generation layer 406b in FIG. 4.

As used herein, the term “common hole transport layer” refers to a common hole transport layer that is shared by at least two adjacent pixels in an active matrix organic electroluminescent display, that is, the common hole transport layer is continuous and undivided across multiple pixels, as illustrated by the common hole transport layer 407 in FIG. 4.

As used herein, the term “P-type conductive doping material” refers to a dopant with an oxidizing capability, which has a strong electron-withdrawing ability and is an electron acceptor.

As used herein, regarding materials being “identical” or “different”, “identical” means that two or more materials have an identical chemical structural formula or that the only difference between two or more materials is that hydrogen in the chemical structural formulas is partially or fully substituted with deuterium. Conversely, “different” means that the chemical structural formulas of the organic materials used are different (that is, the difference in the chemical structural formulas is not only the partial or complete substitution of hydrogen with deuterium in the molecular formula).

As used herein, all “HOMO energy levels” and “LUMO energy levels” are expressed as negative values, and a smaller numerical value (i.e., a larger absolute value) indicates a deeper energy level. For example, HOMO₁−HOMO₂>0 eV herein, that is, the HOMO energy level of the first hole transport material is numerically larger (i.e., has a smaller absolute value) than the HOMO energy level of the second hole transport material, which also means that the HOMO energy level of the second hole transport material is deeper than the HOMO energy level of the first hole transport material.

As used herein, “the mass doping proportion of the first P-type conductive doping material in the common P-type charge generation layer” refers to the percentage of the mass of the first P-type conductive doping material in the common P-type charge generation layer to the total mass of the common P-type charge generation layer. For example, assuming that the mass of the first P-type conductive doping material contained in the common P-type charge generation layer is 20 milligrams and the total mass of the common P-type charge generation layer is 100 milligrams, the mass doping proportion of the first P-type conductive doping material in the common P-type charge generation layer is 20%.

FIG. 4 schematically and non-restrictively illustrates a structure diagram of an active matrix organic electroluminescent display according to the present disclosure. As distinguished by the dashed lines in FIG. 4, the display includes a pixel 4A and a pixel 4B. Both the pixel 4A and the pixel 4B include a stacked OLED, and the stacked OLED includes two light-emitting units. 400a and 400b are the anodes of the pixel 4A and the pixel 4B, respectively. 401 is the common hole injection layer of the first light-emitting unit. 402 is the common hole transport layer of the first light-emitting unit. 403a and 403b are the auxiliary light-emitting layers (prime layers, also called electron blocking layers) of the first light-emitting units of the pixel 4A and the pixel 4B, respectively. 404a and 404b are the light-emitting layers of the first light-emitting units of the pixel 4A and the pixel 4B, respectively. 405 is the common electron transport layer of the first light-emitting unit. Other layers not explicitly described may also be included in the first light-emitting unit as needed. For example, a hole blocking layer may also be included between the light-emitting layers 404a and 404b and the common electron transport layer 405, which is not shown in the figure. Certain layers in the first light-emitting unit may also be omitted, which is not repeated here. 406a is the common N-type charge generation layer. 406b is the common P-type charge generation layer. 407 is the common hole transport layer of the second light-emitting unit. 408a and 408b are the auxiliary light-emitting layers (prime layers, also called electron blocking layers) of the second light-emitting units of the pixel 4A and the pixel 4B, respectively. 409a and 409b are the light-emitting layers of the second light-emitting units of the pixel 4A and the pixel 4B, respectively. 410 is the common electron transport layer of the second light-emitting unit. 411 is the common electron injection layer of the second light-emitting unit. 412 is the common cathode. Other layers not explicitly described may also be included in the second light-emitting unit as needed. For example, a hole blocking layer may also be included between the light-emitting layers 409a and 409b and the common electron transport layer 410, which is not shown in the figure. Certain layers in the second light-emitting unit may also be omitted, which is not repeated here. By applying individual drive currents to the anodes 400a and 400b, respectively, each pixel operates independently. For example, if a current is applied to the pixel 4A but no current is applied to the pixel 4B, only the pixel 4A is lit. During this process, if the lateral resistance of the common P-type charge generation layer 406b and the common hole transport layer 407 of the second light-emitting unit is too low, a current may flow from the pixel 4A to the pixel 4B through the common P-type charge generation layer 406b and the common hole transport layer 407 of the second light-emitting unit, causing the pixel 4B to emit light and resulting in color crosstalk.

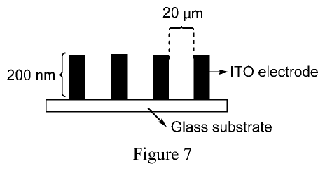

FIGS. 6 and 7 schematically and non-restrictively illustrate the structure diagrams of interdigitated electrodes used in the present disclosure. FIG. 6 is a top view of the interdigitated electrodes, and FIG. 7 is a partial section view of the interdigitated electrodes. As shown in FIGS. 6 and 7, the interdigitated electrodes have a total of 40 ITO fingers, and each ITO finger has a width of 0.02 mm. The 40 ITO fingers form 39 trench areas. Each trench area has a length of 1.92 mm, a width of 20 μm (that is, the inter-finger gap is 20 μm, meaning the distance between two adjacent ITO fingers is 20 μm), and a height of 200 nm.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e., P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as the temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AEs-T). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in a small AEs-T. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, an n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butyldimethylgermanylmethyl, triethylgermanylmethyl, triethylgermanylethyl, triisopropylgermanylmethyl, triisopropylgermanylethyl, trimethylsilylmethyl, trimethylsilylethyl, trimethylsilylisopropyl, triisopropylsilylmethyl, and triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates a germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc., means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more groups selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl group having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g., phenyl, phenylene, naphthyl, dibenzofuryl) or as if it were the whole molecule (e.g., benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to their enhancements of device efficiency and stability.

In the compounds mentioned in the present disclosure, multiple substitutions refer to a range that includes di-substitutions, up to the maximum available substitutions. When substitution in the compounds mentioned in the present disclosure represents multiple substitutions (including di-, tri-, and tetra-substitutions, etc.), that means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fused cyclic, etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

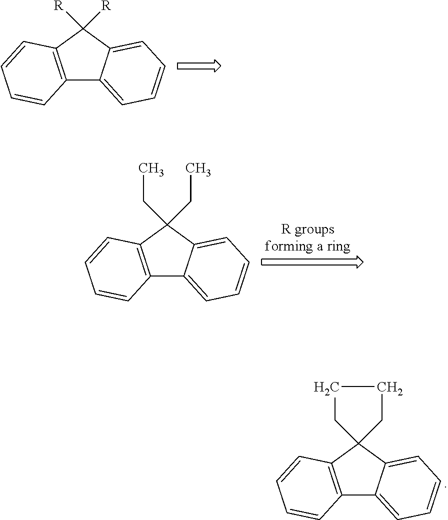

The expression that adjacent substituents can be optionally joined to form a ring is also intended to mean that two substituents bonded to carbon atoms which are directly bonded to each other are joined to each other via a chemical bond to form a ring, which can be exemplified by the following formula:

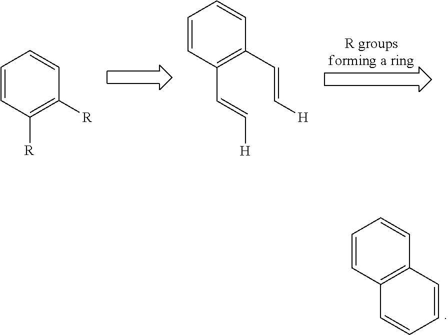

The expression that adjacent substituents can be optionally joined to form a ring is also intended to mean that two substituents bonded to further distant carbon atoms are joined to each other via a chemical bond to form a ring, which can be exemplified by the following formula:

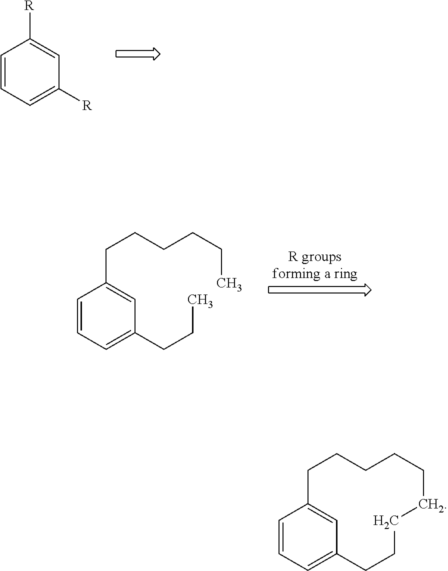

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

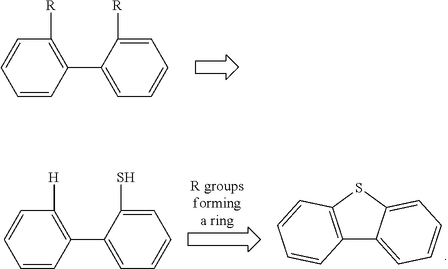

According to an embodiment of the present disclosure, an active matrix organic electroluminescent device is disclosed, which comprises multiple pixels;
wherein each of the multiple pixels at least comprises a stacked organic electroluminescent device; and
the stacked organic electroluminescent device comprises an anode, a cathode, at least one common P-type charge generation layer disposed between the anode and the cathode, and a common hole transport layer which is disposed between the common P-type charge generation layer and the cathode and is in direct contact with the common P-type charge generation layer;
wherein the common P-type charge generation layer and the common hole transport layer are shared by at least two adjacent pixels;
the common P-type charge generation layer comprises a first P-type conductive doping material and a first hole transport material;
the common hole transport layer comprises a second hole transport material;
the first hole transport material is different from the second hole transport material;
the HOMO energy level of the first hole transport material is HOMO₁, the HOMO energy level of the second hole transport material is HOMO₂, and HOMO₁−HOMO₂>0 eV; and
the common P-type charge generation layer and the common hole transport layer simultaneously meet the following two conditions:
(1) the lateral resistance of a film layer A formed by the common P-type charge generation layer and the common hole transport layer measured using interdigitated electrodes is R₁, and R₁≥15 MΩ; and
(2) R₁/R₂≥1.1, wherein R₂ is the lateral resistance of a film layer B measured using interdigitated electrodes, and the film layer B is identical to the film layer A except that the second hole transport material in the common hole transport layer of the film layer A is replaced with the first hole transport material.

According to an embodiment of the present disclosure, the common P-type charge generation layer is formed by the first P-type conductive doping material and the first hole transport material, and the common hole transport layer is formed by the second hole transport material.

According to an embodiment of the present disclosure, the film layer A is formed by the common P-type charge generation layer and the common hole transport layer, the common P-type charge generation layer in the film layer A is formed by the first P-type conductive doping material and the first hole transport material, and the common hole transport layer in the film layer A is formed by the second hole transport material.

According to an embodiment of the present disclosure, the film layer B is formed by the common P-type charge generation layer and the common hole transport layer, the common P-type charge generation layer in the film layer B is formed by the first P-type conductive doping material and the first hole transport material, and the common hole transport layer in the film layer B is formed by the first hole transport material.

According to an embodiment of the present disclosure, the common P-type charge generation layers in the film layer A and the film layer B are totally identical.

According to an embodiment of the present disclosure, R₁≥16 MΩ; R₁≥17 MΩ; R₁≥18 MΩ; R₁≥19 MΩ; R₁≥20 MΩ; R₁≥22 MΩ2; R₁≥24 MΩ; R₁≥26 MΩ; R₁≥28 MΩ; R₁≥30 MΩ; R₁≥32 MΩ; R₁≥34 MΩ; R₁≥36 MΩ; R₁≥38 MΩ; R₁≥40 MΩ; R₁≥45 MΩ; R₁≥50 MΩ; R₁≥55 MΩ; or R₁≥60 MΩ.

According to an embodiment of the present disclosure, R₁≤10000 MΩ; R₁≤9000 MΩ; R₁≤8000 MΩ; R₁≤7000 MΩ; R₁≤6000 MΩ; R₁≤5000 MΩ; R₁≤4000 MΩ; R₁≤3000 MΩ; R₁≤2000 MΩ; or R₁≤1000 MΩ.

According to an embodiment of the present disclosure, R₁/R₂≥1.12; R₁/R₂≥1.13; R₁/R₂≥1.14; R₁/R₂≥1.15; R₁/R₂≥1.16; R₁/R₂≥1.17; R₁/R₂≥1.18; R₁/R₂≥1.19; R₁/R₂≥1.2; R₁/R₂≥1.22; R₁/R₂≥1.24; R₁/R₂≥1.26; R₁/R₂≥1.28; R₁/R₂≥1.3; R₁/R₂≥1.35; R₁/R₂≥1.4; R₁/R₂≥1.45; R₁/R₂≥1.5; R₁/R₂≥1.55; R₁/R₂≥1.6; R₁/R₂≥1.65; R₁/R₂≥1.7; R₁/R₂≥1.75; R₁/R₂≥1.8; or R₁/R₂≥1.85.

According to an embodiment of the present disclosure, R₁/R₂≤100; R₁/R₂≤80; R₁/R₂≤60; R₁/R₂≤40; or R₁/R₂≤20.

According to an embodiment of the present disclosure, HOMO₁−HOMO₂≥0.01 eV; HOMO₁−HOMO₂≥0.02 eV; HOMO₁−HOMO₂≥0.03 eV; HOMO₁−HOMO₂≥0.04 eV; HOMO₁−HOMO₂≥0.05 eV; HOMO₁−HOMO₂≥0.06 eV; HOMO₁−HOMO₂≥0.07 eV; HOMO₁−HOMO₂≥0.08 eV; HOMO₁−HOMO₂≥0.09 eV; HOMO₁−HOMO₂≥0.10 eV; HOMO₁−HOMO₂>0.11 eV; HOMO₁−HOMO₂>0.12 eV; or HOMO₁−HOMO₂≥0.13 eV.

According to an embodiment of the present disclosure, HOMO₁−HOMO₂≤5 eV; HOMO₁−HOMO₂≤2 eV; HOMO₁−HOMO₂≤1 eV; HOMO₁−HOMO₂≤0.8 eV; HOMO₁−HOMO₂≤0.6 eV; HOMO₁−HOMO₂≤0.4 eV; or HOMO₁−HOMO₂≤0.2 eV.

According to an embodiment of the present disclosure, at a constant current density of 10 mA/cm², the voltage of the stacked organic electroluminescent device is less than or equal to 8.6 V; the voltage is less than or equal to 8.4 V; the voltage is less than or equal to 8.2 V; the voltage is less than or equal to 8.0 V; the voltage is less than or equal to 7.8 V; the voltage is less than or equal to 7.6 V; the voltage is less than or equal to 7.4 V; the voltage is less than or equal to 7.2 V; the voltage is less than or equal to 7.0 V; the voltage is less than or equal to 6.8 V; the voltage is less than or equal to 6.6 V; the voltage is less than or equal to 6.4 V; the voltage is less than or equal to 6.3 V; the voltage is less than or equal to 6.2 V; the voltage is less than or equal to 6.1 V; the voltage is less than or equal to 6.0 V; the voltage is less than or equal to 5.9 V; the voltage is less than or equal to 5.8 V; the voltage is less than or equal to 5.7 V; the voltage is less than or equal to 5.6 V; the voltage is less than or equal to 5.5 V; the voltage is less than or equal to 5.4 V; the voltage is less than or equal to 5.3 V; or the voltage is less than or equal to 5.2 V.

According to an embodiment of the present disclosure, the thickness of the common hole transport layer is greater than or equal to 20 nm; greater than or equal to 30 nm; greater than or equal to 40 nm; greater than or equal to 50 nm; greater than or equal to 60 nm; greater than or equal to 70 nm; greater than or equal to 80 nm; greater than or equal to 90 nm; or greater than or equal to 100 nm.

According to an embodiment of the present disclosure, the thickness of the common hole transport layer is less than or equal to 200 nm, or less than or equal to 150 nm.

According to an embodiment of the present disclosure, the LUMO energy level of the first P-type conductive doping material is LUMO₁, and −5.30 eV≤LUMO₁≤−4.8 eV; −5.20 eV≤LUMO₁≤−4.9 eV; −5.15 eV≤LUMO₁≤−4.95 eV; LUMO₁−HOMO₁≥0 eV; LUMO₁−HOMO₁≥0.02 eV; LUMO₁−HOMO₁≥0.04 eV; LUMO₁−HOMO₁≥0.05 eV; or LUMO₁−HOMO₁≥0.06 eV.

According to an embodiment of the present disclosure, the LUMO energy level of the first P-type conductive doping material is LUMO₁, the HOMO energy level of the first hole transport material is HOMO₁, and LUMO₁−HOMO₁≤0.5 eV; LUMO₁−HOMO₁≤0.4 eV; LUMO₁−HOMO₁≤0.3 eV; or LUMO₁−HOMO₁≤0.2 eV.

According to an embodiment of the present disclosure, the absolute value of the energy level difference between the LUMO energy level of the first P-type conductive doping material and the HOMO energy level of the first hole transport material is less than or equal to 0.1 eV; less than or equal to 0.09 eV; less than or equal to 0.08 eV; less than or equal to 0.07 eV; or less than or equal to 0.06 eV.

According to an embodiment of the present disclosure, the mass doping proportion of the first P-type conductive doping material in the common P-type charge generation layer is greater than or equal to 7%; greater than or equal to 8%; greater than or equal to 9%; greater than or equal to 10%; greater than or equal to 11%; greater than or equal to 12%; greater than or equal to 13%; or greater than or equal to 14%.

According to an embodiment of the present disclosure, the lateral resistance R₁ is measured using the following method. Under a vacuum degree of approximately 10⁻⁶ Torr, on a test substrate pre-patterned with ITO interdigitated electrodes, a first P-type conductive doping material and a first hole transport material are first co-deposited to form a common P-type charge generation layer, and a second hole transport material is deposited by evaporation onto the P-type charge generation layer to form a common hole transport layer, where the test substrate comprises a total of 40 ITO fingers, each with a width of 0.02 mm, the 40 ITO fingers form 39 trench areas, and each trench area has a length of 1.92 mm, a width of 20 μm and a height of 200 nm; and at room temperature, a test fixture is clamped onto the ITO electrode, a voltage is applied, and the current is measured to obtain the resistance value of this area.

According to an embodiment of the present disclosure, the lateral resistance R₂ is measured using the following method. Under a vacuum degree of approximately 10° Torr, on a test substrate pre-patterned with ITO interdigitated electrodes, a first P-type conductive doping material and a first hole transport material are first co-deposited to form a common P-type charge generation layer, and a first hole transport material is deposited by evaporation onto the P-type charge generation layer to form a common hole transport layer, where the test substrate comprises a total of 40 ITO fingers, each with a width of 0.02 mm, the 40 ITO fingers form 39 trench areas, and each trench area has a length of 1.92 mm, a width of 20 μm and a height of 200 nm; and at room temperature, a test fixture is clamped onto the ITO electrode, a voltage is applied, and the current is measured to obtain the resistance value of this area.

According to an embodiment of the present disclosure, in the method for measuring the lateral resistance R₁, the thickness of the common P-type charge generation layer is 100 Å, and the thickness of the common hole transport layer is 400 Å.

According to an embodiment of the present disclosure, the stacked organic electroluminescent device comprises a hole injection layer, and the hole injection layer is disposed between the common P-type charge generation layer and the anode.

According to an embodiment of the present disclosure, the hole injection layer is in direct contact with the anode.

According to an embodiment of the present disclosure, the hole injection layer comprises a second P-type conductive doping material and a third hole transport material.

According to an embodiment of the present disclosure, the second P-type conductive doping material is identical to or different from the first P-type conductive doping material.

According to an embodiment of the present disclosure, the second P-type conductive doping material is identical to the first P-type conductive doping material.

According to an embodiment of the present disclosure, the second P-type conductive doping material is different from the first P-type conductive doping material.

According to an embodiment of the present disclosure, the third hole transport material is identical to or different from the first hole transport material.

According to an embodiment of the present disclosure, the third hole transport material is identical to the first hole transport material.

According to an embodiment of the present disclosure, the third hole transport material is different from the first hole transport material.

According to an embodiment of the present disclosure, the third hole transport material is identical to or different from the second hole transport material.

According to an embodiment of the present disclosure, the third hole transport material is identical to the second hole transport material.

According to an embodiment of the present disclosure, the third hole transport material is different from the second hole transport material.

According to an embodiment of the present disclosure, the P-type conductive doping material (the first P-type conductive doping material or the second P-type conductive doping material) is selected from the following compounds: quinones or quinone derivatives, radialene compounds, dehydrobenzooxazole and dehydrobenzothiazole compounds, bisoxazole or bisthiazole compounds, metal oxides, and metal sulfides.

According to an embodiment of the present disclosure, the P-type conductive doping material (the first P-type conductive doping material or the second P-type conductive doping material) is selected from the following compounds: quinones or quinone derivatives and structures thereof, radialene compounds and structures thereof, dehydrobenzooxazole and dehydrobenzothiazole compounds and structures thereof, bisoxazole or bisthiazole compounds and structures thereof, metal oxides, and metal sulfides.

According to an embodiment of the present disclosure, the P-type conductive doping material has a structure represented by Formula 1:

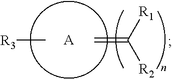

wherein
n is selected from an integer from 1 to 5;
the ring A is selected from a conjugated ring having 3 to 30 ring atoms;
R₃ represents mono-substitution, multiple substitutions, or non-substitution;
R₁, R₂ and R₃ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof, and
adjacent substituents R₁, R₂ and R₃ can be optionally joined to form a ring.

Herein, the expression that “the ring A is selected from a conjugated ring having 3 to 30 ring atoms” is intended to mean that the ring A is a ring structure having 3 to 30 ring atoms and the ring A has a structural feature of conjugation. For example, the ring A includes, but is not limited to, the structures represented by Formula A-1 to Formula A-17 in the present application. The ring A may be a monocyclic structure or a polycyclic structure, wherein the polycyclic ring may be a parallel-ring structure or a fused-ring structure or may be an integrally conjugated structure formed by connecting two conjugated rings via a double bond, such as the structure represented by Formula A-12 in the present application. The ring A may be a carbocyclic ring or a heterocyclic ring.

Herein, the expression that adjacent substituents R₁, R₂ and R₃ can be optionally joined to form a ring is intended to mean that any one or more of groups of adjacent substituents, such as substituents R₃, substituents R₁ and R₂, substituents R₁ and R₃, and substituents R₂ and R₃, can be joined to form a ring. Obviously, it is also possible that none of these substituents are joined to form a ring.

According to an embodiment of the present disclosure, n is an even number.

According to an embodiment of the present disclosure, n is selected from 2, 4 or 6.

According to an embodiment of the present disclosure, n is selected from 1, 2 or 3.

According to an embodiment of the present disclosure, n is selected from 1 or 2.

According to an embodiment of the present disclosure, the ring A is selected from a conjugated ring having 3 to 20 ring atoms.

According to an embodiment of the present disclosure, the ring A is selected from a conjugated ring having 4 to 20 ring atoms.

According to an embodiment of the present disclosure, at least one of the substituents R₁, R₂ and R₃ is a substituent comprising at least one electron-withdrawing group.

According to an embodiment of the present disclosure, R₁ and/or R₂ are a substituent comprising at least one electron-withdrawing group.

According to an embodiment of the present disclosure, the Hammett constant of the electron-withdrawing group is greater than or equal to 0.05.

According to an embodiment of the present disclosure, the Hammett constant of the electron-withdrawing group is greater than or equal to 0.3.

According to an embodiment of the present disclosure, the Hammett constant of the electron-withdrawing group is greater than or equal to 0.5.

In the present disclosure, the Hammett substituent constant of the electron-withdrawing group is ≥0.05, for example, ≥0.1 or ≥0.2; preferably ≥0.3; more preferably ≥0.5. The relatively strong electron-withdrawing ability can significantly reduce the LUMO energy level of the compound, thereby achieving the effect of improving charge mobility.

It is to be noted that the Hammett substituent constant includes the para constant and/or the meta constant of a Hammett substituent, and as long as both the para constant and the meta constant are greater than zero and one of them satisfies being greater than or equal to 0.05, the substituent may be used as the group selected for the present disclosure.

According to an embodiment of the present disclosure, the electron-withdrawing group is selected from the group consisting of: halogen, a nitroso group, a nitro group, an acyl group, a carbonyl group, a carboxylic acid group, an ester group, a cyano group, an isocyano group, SCN, OCN, SF₅, a boryl group, a sulfinyl group, a sulfonyl group, a phosphoroso group, an aza-aromatic ring group, and any one of the following groups substituted with one or more of halogen, a nitroso group, a nitro group, an acyl group, a carbonyl group, a carboxylic acid group, an ester group, a cyano group, an isocyano group, SCN, OCN, SF₅, a boryl group, a sulfinyl group, a sulfonyl group, a phosphoroso group, and an aza-aromatic ring group: alkyl having 1 to 20 carbon atoms, cycloalkyl having 3 to 20 ring carbon atoms, heteroalkyl having 1 to 20 carbon atoms, heterocyclic group having 3 to 20 ring atoms, arylalkyl having 7 to 30 carbon atoms, alkoxy having 1 to 20 carbon atoms, aryloxy having 6 to 30 carbon atoms, alkenyl having 2 to 20 carbon atoms, alkynyl having 2 to 20 carbon atoms, aryl having 6 to 30 carbon atoms, heteroaryl having 3 to 30 carbon atoms, alkylsilyl having 3 to 20 carbon atoms, arylsilyl having 6 to 20 carbon atoms and combinations thereof.

According to an embodiment of the present disclosure, the electron-withdrawing group is selected from the group consisting of: halogen, a nitroso group, a nitro group, an acyl group, a carbonyl group, a carboxylic acid group, an ester group, SF₅, a boryl group, a sulfinyl group, a sulfonyl group, a phosphoroso group, an aza-aromatic ring group, and any one of the following groups substituted with one or more of halogen, a nitroso group, a nitro group, an acyl group, a carbonyl group, a carboxylic acid group, an ester group, a cyano group, an isocyano group, SCN, OCN, SF₅, a boryl group, a sulfinyl group, a sulfonyl group, a phosphoroso group, and an aza-aromatic ring group: alkyl having 1 to 20 carbon atoms, cycloalkyl having 3 to 20 ring carbon atoms, heteroalkyl having 1 to 20 carbon atoms, arylalkyl having 7 to 30 carbon atoms, alkoxy having 1 to 20 carbon atoms, aryloxy having 6 to 30 carbon atoms, alkenyl having 2 to 20 carbon atoms, alkynyl having 2 to 20 carbon atoms, aryl having 6 to 30 carbon atoms, heteroaryl having 3 to 30 carbon atoms, alkylsilyl having 3 to 20 carbon atoms, arylsilyl having 6 to 20 carbon atoms and combinations thereof.

According to an embodiment of the present disclosure, the electron-withdrawing group is selected from the group consisting of: fluorine, an acyl group, a carbonyl group, an ester group, SF₅, a boryl group, an aza-aromatic ring group, and any one of the following groups substituted with one or more of fluorine, a cyano group, an isocyano group, SCN, OCN, SF₅, CF₃, OCF₃, SCF₃ and an aza-aromatic ring group: alkyl having 1 to 20 carbon atoms, cycloalkyl having 3 to 20 ring carbon atoms, heteroalkyl having 1 to 20 carbon atoms, arylalkyl having 7 to 30 carbon atoms, alkoxy having 1 to 20 carbon atoms, aryloxy having 6 to 30 carbon atoms, alkenyl having 2 to 20 carbon atoms, alkynyl having 2 to 20 carbon atoms, aryl having 6 to 30 carbon atoms, heteroaryl having 3 to 30 carbon atoms, alkylsilyl having 3 to 20 carbon atoms, arylsilyl having 6 to 20 carbon atoms and combinations thereof.

According to an embodiment of the present disclosure, the ring A is selected from the group consisting of Formula A-1 to Formula A-17:

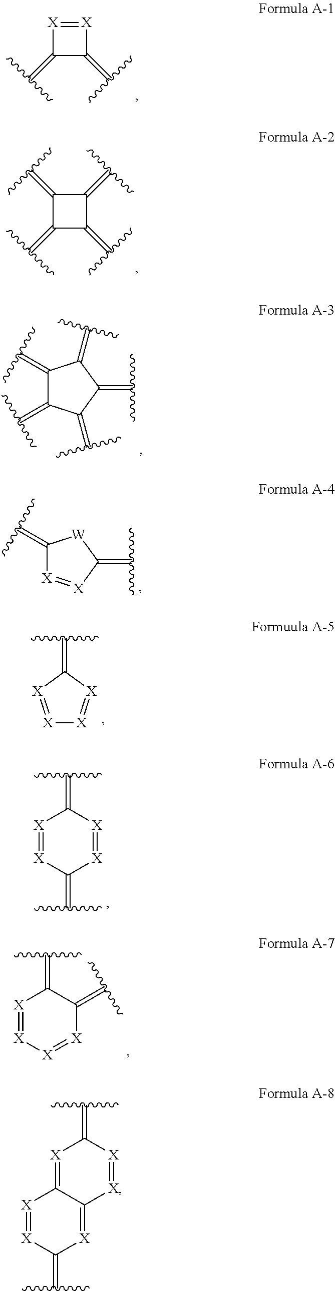

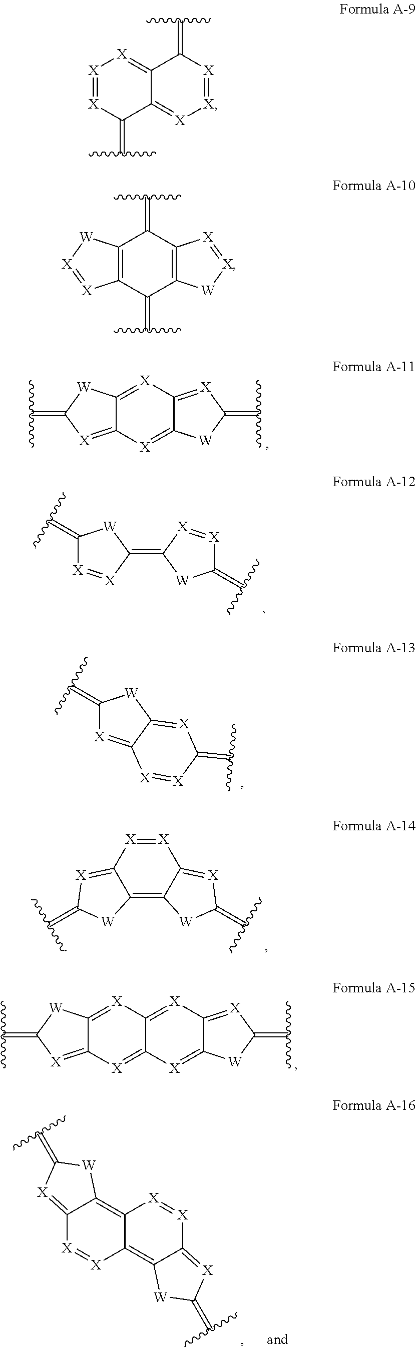

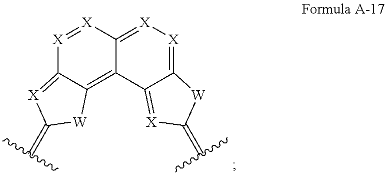

wherein X is, at each occurrence identically or differently, selected from N or CR₃;
W is, at each occurrence identically or differently, selected from O, S, Se or NR₃,
R₃ is, at each occurrence identically or differently, selected from hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group or a combination thereof;
adjacent substituents R₃ can be optionally joined to form a ring; and
“ [symbol] ” represents a position where Formula A-1 to Formula A-17 are joined to a double bond in Formula 1.

According to an embodiment of the present disclosure, the ring A is selected from Formula A-6, Formula A-8, Formula A-10, Formula A-11 or Formula A-12.

According to an embodiment of the present disclosure, the P-type conductive doping material has a structure represented by any one of Formula 1-1 to Formula 1-40:

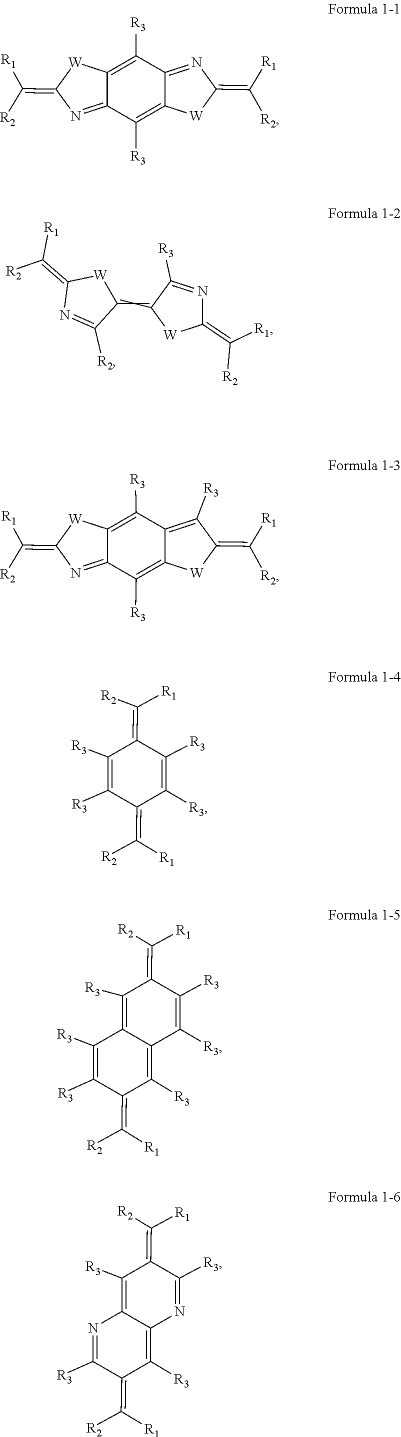

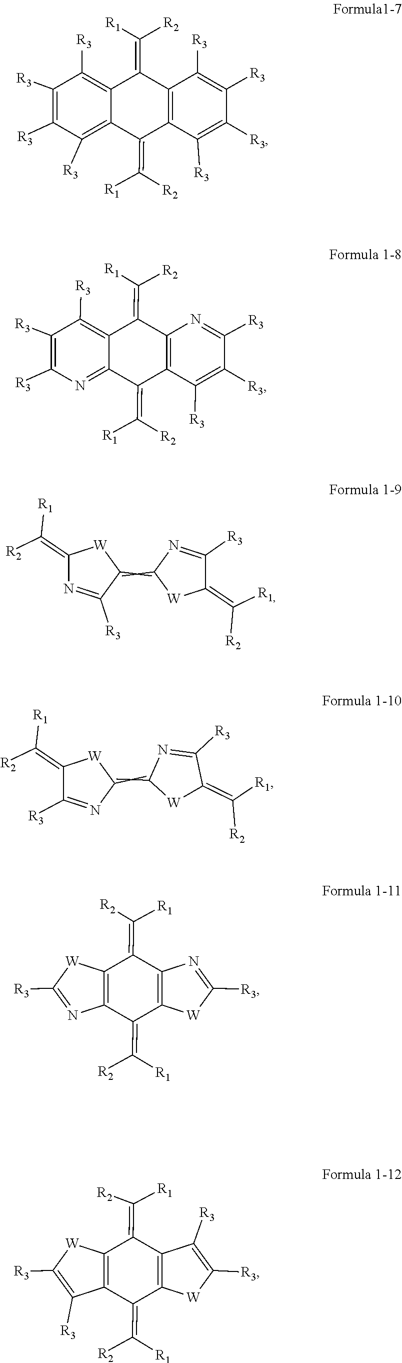

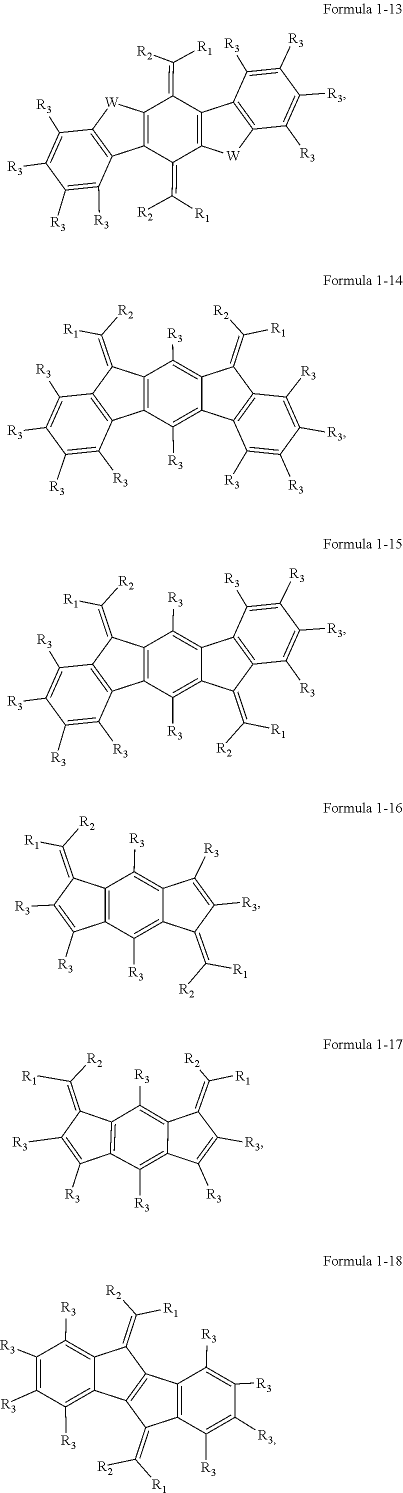

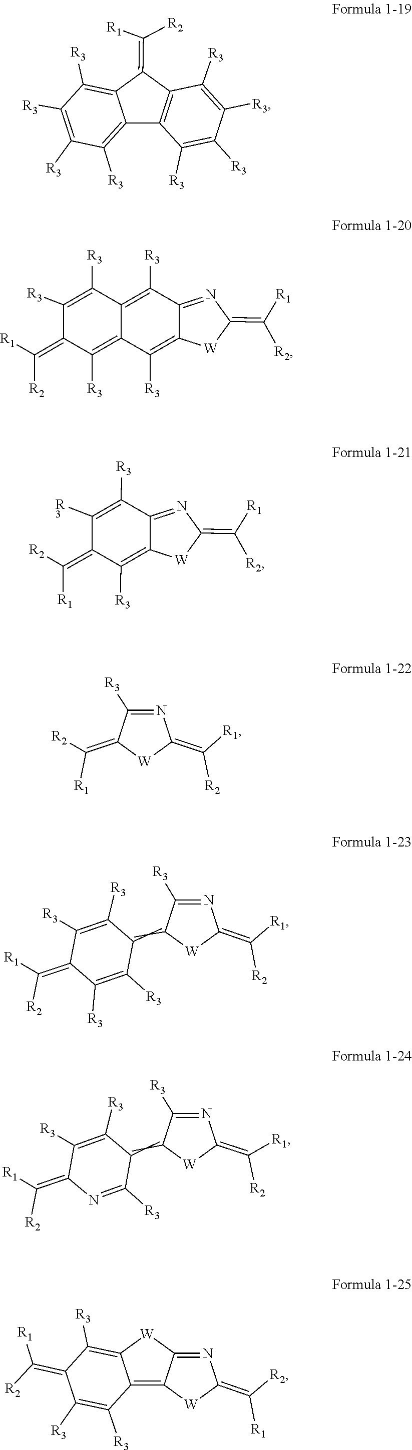

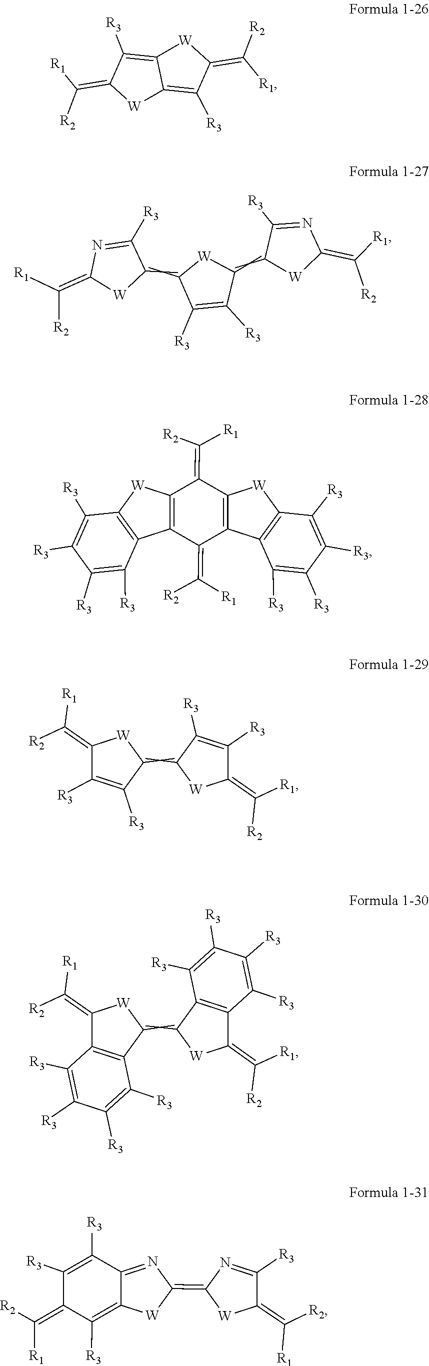

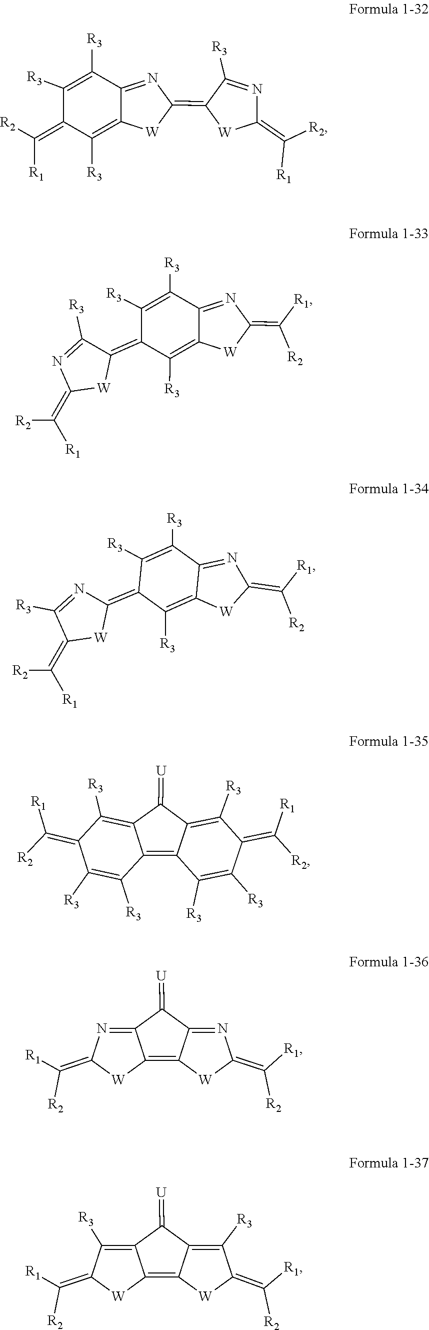

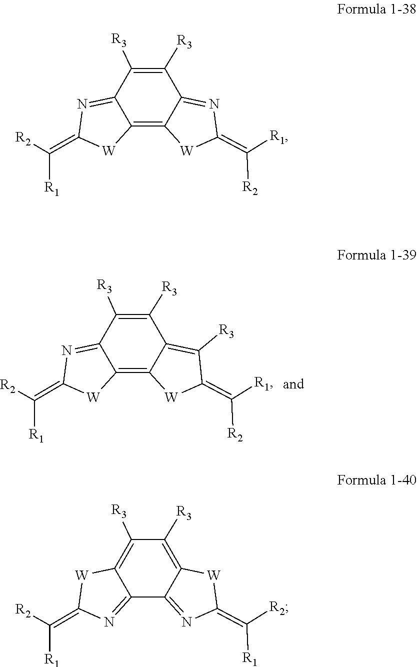

wherein W is, at each occurrence identically or differently, selected from the group consisting of O, S, C═O, S═O, O═S═O, Se and NR₃;
U is, at each occurrence identically or differently, selected from the group consisting of O, S, CR₁R₂ and NR₃;
R₁, R₂ and R₃ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof;
adjacent substituents R₁, R₂ and R₃ can be optionally joined to form a ring; and
in Formula 1-2, Formula 1-9, Formula 1-10, Formula 1-23, Formula 1-24, Formula 1-27, Formula 1-29, and Formula 1-30, “ [symbol] ” represents cis-trans isomerism.

According to an embodiment of the present disclosure, W is, at each occurrence identically or differently, selected from O, S, S═O or O═S═O.

According to an embodiment of the present disclosure, W is, at each occurrence identically or differently, selected from O or S.

According to an embodiment of the present disclosure, W is selected from O.

According to an embodiment of the present disclosure, U is selected from O or CR₁R₂.

According to an embodiment of the present disclosure, R₁, R₂ and R₃ are, at each occurrence identically or differently, selected from the group consisting of: hydrogen, deuterium, halogen, a nitroso group, a nitro group, an acyl group, a carbonyl group, a carboxylic acid group, an ester group, a cyano group, an isocyano group, SCN, OCN, SF₅, a boryl group, a sulfinyl group, a sulfonyl group, a phosphoroso group, unsubstituted alkyl having 1 to 20 carbon atoms, unsubstituted cycloalkyl having 3 to 20 ring carbon atoms, unsubstituted alkoxy having 1 to 20 carbon atoms, unsubstituted alkenyl having 2 to 20 carbon atoms, unsubstituted aryl having 6 to 30 carbon atoms, unsubstituted heteroaryl having 3 to 30 carbon atoms, and any one of the following groups substituted with one or more of halogen, a nitroso group, a nitro group, an acyl group, a carbonyl group, a carboxylic acid group, an ester group, a cyano group, an isocyano group, SCN, OCN, SF₅, a boryl group, a sulfinyl group, a sulfonyl group and a phosphoroso group: alkyl having 1 to 20 carbon atoms, cycloalkyl having 3 to 20 ring carbon atoms, alkoxy having 1 to 20 carbon atoms, alkenyl having 2 to 20 carbon atoms, aryl having 6 to 30 carbon atoms, heteroaryl having 3 to 30 carbon atoms and combinations thereof.

According to an embodiment of the present disclosure, R₁, R₂ and R₃ are, at each occurrence identically or differently, selected from the group consisting of: hydrogen, deuterium, methyl, isopropyl, NO₂, SO₂CH₃, SCF₃, C₂F₅, OC₂F₅, OCH₃, diphenylmethylsilyl, phenyl, methoxyphenyl, p-methylphenyl, 2,6-diisopropylphenyl, biphenyl, polyfluorophenyl, difluoropyridyl, nitrophenyl, dimethylthiazolyl, vinyl substituted with one or more of CN or CF₃, acetenyl substituted with one of CN or CF₃, dimethylphosphoroso, diphenylphosphoroso, F, CF₃, OCF₃, SF₅, SO₂CF₃, a cyano group, an isocyano group, SCN, OCN, trifluoromethylphenyl, trifluoromethoxyphenyl, bis(trifluoromethyl)phenyl, bis(trifluoromethoxy)phenyl, 4-cyanotetrafluorophenyl, phenyl or biphenyl substituted with one or more of F, CN or CF₃, tetrafluoropyridyl, pyrimidinyl, triazinyl, diphenylboryl, oxaboraanthryl and combinations thereof.

According to an embodiment of the present disclosure, R₁ and R₂ are, at each occurrence identically or differently, selected from the group consisting of: halogen, a cyano group, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted aryl having 6 to 30 carbon atoms, substituted or unsubstituted heteroaryl having 3 to 30 carbon atoms and combinations thereof.

According to an embodiment of the present disclosure, R₁ and R₂ are, at each occurrence identically or differently, selected from the group consisting of: a cyano group, substituted or unsubstituted aryl having 6 to 30 carbon atoms, substituted or unsubstituted heteroaryl having 3 to 30 carbon atoms and combinations thereof.

According to an embodiment of the present disclosure, R₁ is selected from a cyano group.

According to an embodiment of the present disclosure, R₁ and/or R₂ are selected from a cyano group.

According to an embodiment of the present disclosure, R₃ is selected from substituted or unsubstituted aryl having 6 to 30 carbon atoms, substituted or unsubstituted heteroaryl having 3 to 30 carbon atoms or a combination thereof.

According to an embodiment of the present disclosure, the P-type conductive doping material has a structure represented by any one of Formula 1-1, Formula 1-2, Formula 1-3, Formula 1-5, Formula 1-13, Formula 1-14, Formula 1-15, Formula 1-21 or Formula 1-28.

According to an embodiment of the present disclosure, the P-type conductive doping material has a structure represented by Formula 1-1-1:

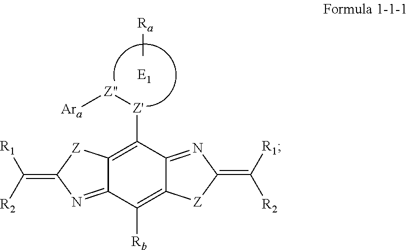

wherein Z is, at each occurrence identically or differently, selected from O, S, Se or NR_{N};
Z′ and Z″ are, at each occurrence identically or differently, selected from C or N;
Arₐ is, at each occurrence identically or differently, selected from the group consisting of: substituted or unsubstituted aryl having 6 to 30 carbon atoms, substituted or unsubstituted heteroaryl having 3 to 30 carbon atoms and combinations thereof; and when Arₐ is selected from substituted aryl or substituted heteroaryl, the aryl or heteroaryl has a substituent R_{b};
Rₐ represents, at each occurrence identically or differently, mono-substitution, multiple substitutions, or non-substitution;
the ring E₁ is, at each occurrence identically or differently, selected from an aromatic ring having 6 to 30 carbon atoms or a heteroaromatic ring having 3 to 30 carbon atoms;
R₁, R₂, Rₐ, R_{b} and R_{N} are, at each occurrence identically or differently, selected from the group consisting of: hydrogen, deuterium, a hydroxyl group, a sulfanyl group, halogen, a nitroso group, a nitro group, an acyl group, a carbonyl group, a carboxylic acid group, an ester group, a cyano group, an isocyano group, SCN, OCN, SF₅, a boryl group, a sulfinyl group, a sulfonyl group, a phosphoroso group, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms and combinations thereof, and
adjacent substituents R₁, R₂, Rₐ and R_{b} can be optionally joined to form a ring.

In this embodiment, in Formula 1-1-1, Z″ and Z′ are directly connected via a chemical bond, which means that Arₐ is connected at an ortho position of Z′.

Herein, the expression that adjacent substituents R₁, R₂, Rₐ and R_{b} can be optionally joined to form a ring is intended to mean that any one or more of groups of adjacent substituents, such as adjacent substituents R₁, adjacent substituents R₂, adjacent substituents R₁ and R₂, and adjacent substituents Rₐ and R_{b}, can be joined to form a ring. Obviously, it is possible that none of these groups of adjacent substituents are joined to form a ring.

According to an embodiment of the present disclosure, at least one of R₁, R₂, Rₐ and R_{b} is, at each occurrence identically or differently, selected from a group comprising at least one electron-withdrawing group.

According to an embodiment of the present disclosure, the P-type conductive doping material has a structure represented by Formula 1-1-1A or Formula 1-1-1B:

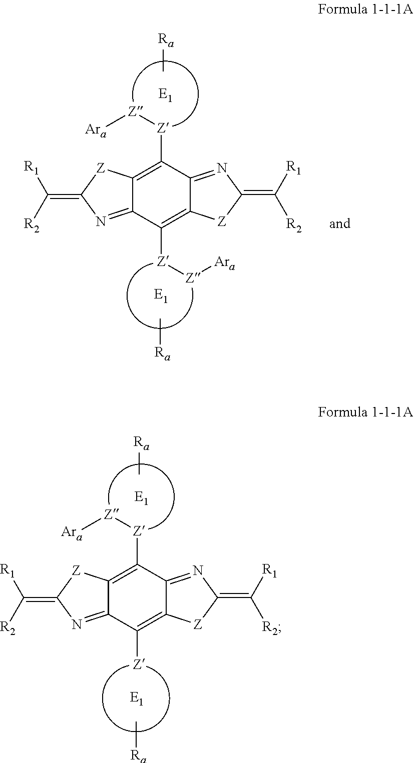

wherein Z is, at each occurrence identically or differently, selected from O, S, Se or NR_{N};
Z′ and Z″ are, at each occurrence identically or differently, selected from C or N;
Arₐ is, at each occurrence identically or differently, selected from the group consisting of: substituted or unsubstituted aryl having 6 to 30 carbon atoms, substituted or unsubstituted heteroaryl having 3 to 30 carbon atoms and combinations thereof; and when Arₐ is selected from substituted aryl or substituted heteroaryl, the aryl or heteroaryl has a substituent R_{b};
Rₐ represents, at each occurrence identically or differently, mono-substitution, multiple substitutions, or non-substitution;
the ring E₁ is, at each occurrence identically or differently, selected from an aromatic ring having 6 to 30 carbon atoms or a heteroaromatic ring having 3 to 30 carbon atoms;
R₁, R₂, Rₐ, R_{b} and R_{N} are, at each occurrence identically or differently, selected from the group consisting of: hydrogen, deuterium, a hydroxyl group, a sulfanyl group, halogen, a nitroso group, a nitro group, an acyl group, a carbonyl group, a carboxylic acid group, an ester group, a cyano group, an isocyano group, SCN, OCN, SF₅, a boryl group, a sulfinyl group, a sulfonyl group, a phosphoroso group, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms and combinations thereof, and
adjacent substituents R₁, R₂, Rₐ and R_{b} can be optionally joined to form a ring.

According to an embodiment of the present disclosure, R₁ and R₂ are, at each occurrence identically or differently, selected from the group consisting of: halogen, a cyano group, SCN, substituted or unsubstituted alkyl having 1 to 20 carbon atoms, substituted or unsubstituted aryl having 6 to 30 carbon atoms, substituted or unsubstituted heteroaryl having 3 to 30 carbon atoms and combinations thereof.

According to an embodiment of the present disclosure, R₁ and R₂ are, at each occurrence identically or differently, selected from the group consisting of: fluorine, a cyano group, SCN, trifluoromethyl, 2,3,5,6-tetrafluoro-4-cyanophenyl, 2,3,5,6-tetrafluoropyridyl, cyanophenyl, fluorophenyl and combinations thereof.

According to an embodiment of the present disclosure, the ring E₁ is, at each occurrence identically or differently, selected from an aromatic ring having 6 to 20 carbon atoms or a heteroaromatic ring having 3 to 20 carbon atoms.

According to an embodiment of the present disclosure, the ring E₁ is, at each occurrence identically or differently, selected from an aromatic ring having 6 to 10 carbon atoms or a heteroaromatic ring having 3 to 10 carbon atoms.

According to an embodiment of the present disclosure, the P-type conductive doping material has a structure represented by any one of Formula 1-1-C to Formula 1-1-1L:

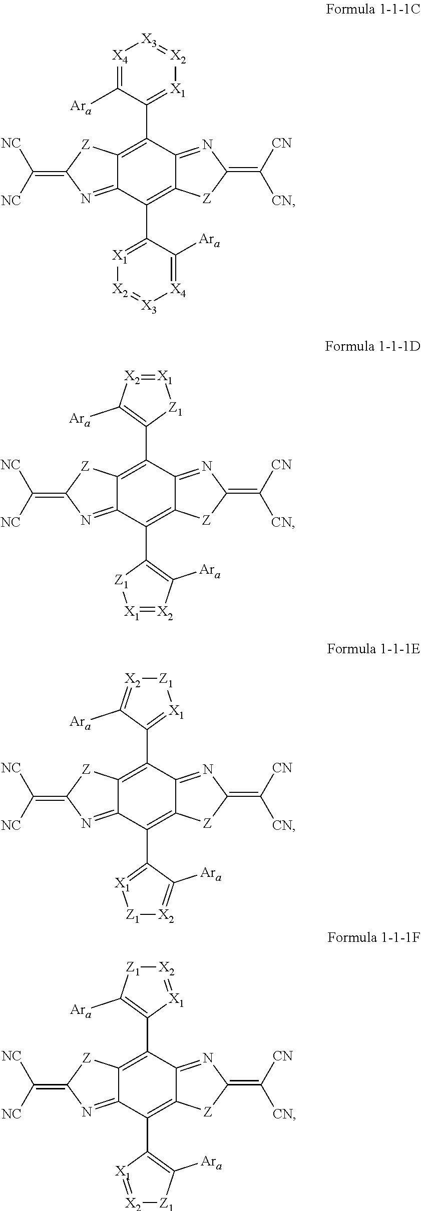

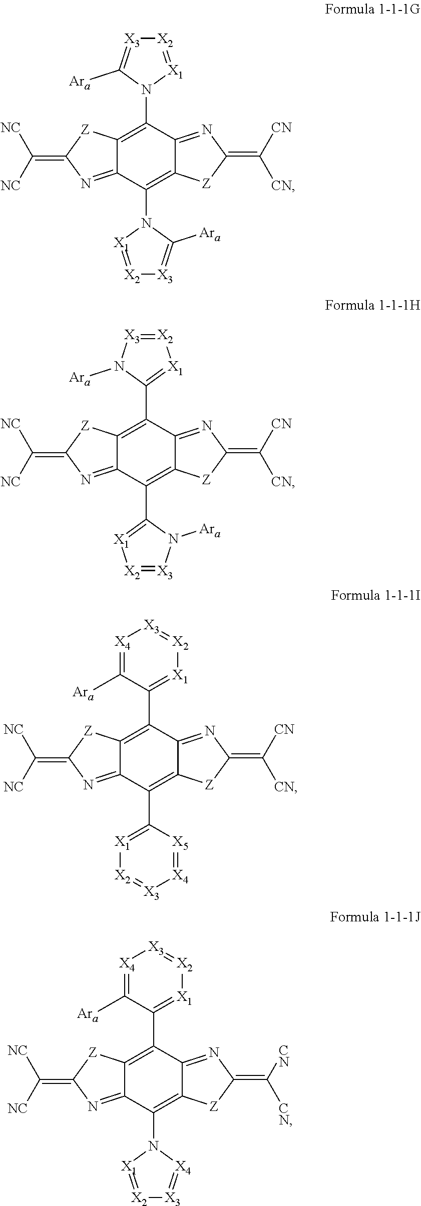

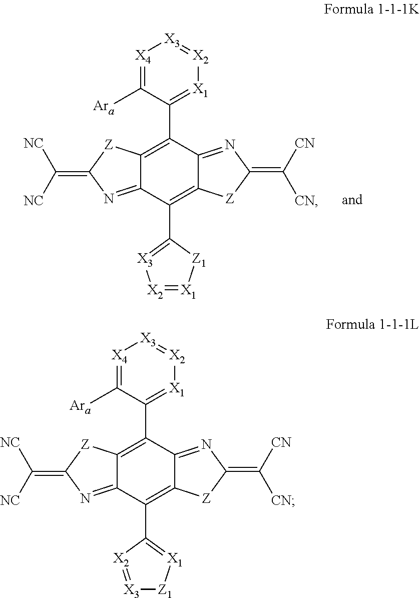

wherein Z is, at each occurrence identically or differently, selected from O, S or Se;
X₁ to X₅ are, at each occurrence identically or differently, selected from N or CRₐ;
Z₁ is, at each occurrence identically or differently, selected from O, S, Se or NR_{N1},
Arₐ is, at each occurrence identically or differently, selected from the group consisting of: substituted or unsubstituted aryl having 6 to 30 carbon atoms, substituted or unsubstituted heteroaryl having 3 to 30 carbon atoms and combinations thereof; and when Arₐ is selected from substituted aryl having 6 to 30 carbon atoms or substituted heteroaryl having 3 to 30 carbon atoms, the aryl or heteroaryl is substituted with one or more R_{b};
the ring E₁ is, at each occurrence identically or differently, selected from an aromatic ring having 6 to 30 carbon atoms or a heteroaromatic ring having 3 to 30 carbon atoms;
Rₐ, R_{b} and R_{N1} are, at each occurrence identically or differently, selected from the group consisting of: hydrogen, deuterium, a hydroxyl group, a sulfanyl group, halogen, a nitroso group, a nitro group, an acyl group, a carbonyl group, a carboxylic acid group, an ester group, a cyano group, an isocyano group, SCN, OCN, SF₅, a boryl group, a sulfinyl group, a sulfonyl group, a phosphoroso group, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms and combinations thereof, and
adjacent substituents Rₐ, R_{b} and R_{N1} can be optionally joined to form a ring.

Herein, the expression that adjacent substituents Rₐ and R_{b} can be optionally joined to form a ring is intended to mean that any one or more of groups of adjacent substituents, such as adjacent substituents R_{b}, adjacent substituents Rₐ, and adjacent substituents R_{b} and Rₐ, can be joined to form a ring. Obviously, it is possible that none of these groups of adjacent substituents are joined to form a ring.

According to an embodiment of the present disclosure, X₁ is, at each occurrence identically or differently, selected from CRₐ.

According to an embodiment of the present disclosure, the P-type conductive doping material has a structure represented by Formula 1-1-1M:

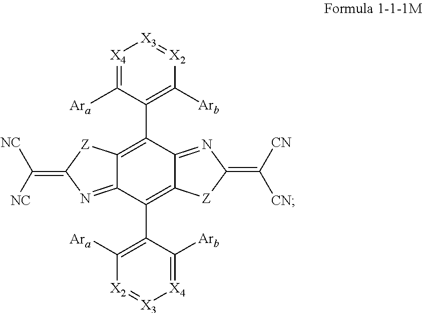

wherein Z is, at each occurrence identically or differently, selected from O, S or Se;
X₂ to X₄ are, at each occurrence identically or differently, selected from N or CRₐ;
Arₐ and Ar_{b} are, at each occurrence identically or differently, selected from the group consisting of: substituted or unsubstituted aryl having 6 to 30 carbon atoms, substituted or unsubstituted heteroaryl having 3 to 30 carbon atoms and combinations thereof, and when Arₐ and Ar_{b} are selected from substituted aryl having 6 to 30 carbon atoms or substituted heteroaryl having 3 to 30 carbon atoms, the aryl or heteroaryl is substituted with one or more R_{b};
Rₐ and R_{b} are, at each occurrence identically or differently, selected from the group consisting of: hydrogen, deuterium, halogen, a hydroxyl group, a sulfanyl group, a nitroso group, a nitro group, an acyl group, a carbonyl group, a carboxylic acid group, an ester group, a cyano group, an isocyano group, SCN, OCN, SF₅, a boryl group, a sulfinyl group, a sulfonyl group, a phosphoroso group, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted alkoxy having 1 to 20 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms and combinations thereof, and
adjacent substituents Rₐ and R_{b} can be optionally joined to form a ring.

According to an embodiment of the present disclosure, Z is, at each occurrence identically or differently, selected from O or S.

According to an embodiment of the present disclosure, Z is selected from O.

According to an embodiment of the present disclosure, in Formula 1-1-1C to Formula 1-1-1M, at least one of X₁ to X₅ is, at each occurrence identically or differently, selected from CRₐ.

According to an embodiment of the present disclosure, in Formula 1-1-1C to Formula 1-1-1M, at least one of X₁ to X₅ is selected from N.

According to an embodiment of the present disclosure, in Formula 1-1-1C to Formula 1-1-1M, at least two of X₁ to X₅ are selected from N.

According to an embodiment of the present disclosure, in Formula 1-1-1C to Formula 1-1-1M, two of X₁ to X₅ are selected from N.

According to an embodiment of the present disclosure, Rₐ and R_{b} are, at each occurrence identically or differently, selected from the group consisting of: hydrogen, deuterium, halogen, a cyano group, an isocyano group, SCN, OCN, SF₅, a boryl group, substituted or unsubstituted alkyl having 1 to 20 carbon atoms, substituted or unsubstituted heteroalkyl having 1 to 20 carbon atoms, substituted or unsubstituted alkoxy having 1 to 20 carbon atoms, substituted or unsubstituted aryl having 6 to 30 carbon atoms, substituted or unsubstituted heteroaryl having 3 to 30 carbon atoms and combinations thereof;
at least one of Rₐ and R_{b} is, at each occurrence identically or differently, selected from the group consisting of: halogen, a cyano group, an isocyano group, SCN, OCN, SF₅, a boryl group, substituted or unsubstituted alkyl having 1 to 20 carbon atoms, substituted or unsubstituted heteroalkyl having 1 to 20 carbon atoms, substituted or unsubstituted alkoxy having 1 to 20 carbon atoms, substituted or unsubstituted aryl having 6 to 30 carbon atoms, substituted or unsubstituted heteroaryl having 3 to 30 carbon atoms and combinations thereof, and
adjacent substituents Rₐ and R_{b} can be optionally joined to form a ring.

According to an embodiment of the present disclosure, Rₐ and R_{b} are, at each occurrence identically or differently, selected from the group consisting of: hydrogen, deuterium, halogen, a cyano group, an isocyano group, SCN, OCN, SF₅, a boryl group, substituted or unsubstituted alkyl having 1 to 20 carbon atoms, substituted or unsubstituted heteroalkyl having 1 to 20 carbon atoms, substituted or unsubstituted alkoxy having 1 to 20 carbon atoms, substituted or unsubstituted aryl having 6 to 30 carbon atoms, substituted or unsubstituted heteroaryl having 3 to 30 carbon atoms and combinations thereof;
at least one of Rₐ and R_{b} is, at each occurrence identically or differently, selected from the group consisting of: fluorine, SF₅, a cyano group, substituted alkyl having 1 to 20 carbon atoms, substituted heteroalkyl having 1 to 20 carbon atoms, substituted alkoxy having 1 to 20 carbon atoms, substituted aryl having 6 to 30 carbon atoms, substituted heteroaryl having 3 to 30 carbon atoms and combinations thereof; and a substituent in the substituted alkyl, substituted heteroalkyl, substituted alkoxy, substituted aryl or substituted heteroaryl comprises at least one electron-withdrawing group; and
adjacent substituents Rₐ and R_{b} can be optionally joined to form a ring.

According to an embodiment of the present disclosure, R₁ and R₂ are, at each occurrence identically or differently, selected from the group consisting of: hydrogen, deuterium, halogen, a cyano group, an isocyano group, SCN, OCN, SF₅, a boryl group, substituted or unsubstituted alkyl having 1 to 20 carbon atoms, substituted or unsubstituted heteroalkyl having 1 to 20 carbon atoms, substituted or unsubstituted alkoxy having 1 to 20 carbon atoms, substituted or unsubstituted aryl having 6 to 30 carbon atoms, substituted or unsubstituted heteroaryl having 3 to 30 carbon atoms and combinations thereof, and
at least one of Rₐ and R_{b} is, at each occurrence identically or differently, selected from the group consisting of: fluorine, SF₅, a cyano group, substituted alkyl having 1 to 20 carbon atoms, substituted heteroalkyl having 1 to 20 carbon atoms, substituted alkoxy having 1 to 20 carbon atoms, substituted aryl having 6 to 30 carbon atoms, substituted heteroaryl having 3 to 30 carbon atoms and combinations thereof; and a substituent in the substituted alkyl, substituted heteroalkyl, substituted alkoxy, substituted aryl or substituted heteroaryl comprises at least one fluorine atom and/or at least one cyano group.

According to an embodiment of the present disclosure, Rₐ and R_{b} are, at each occurrence identically or differently, selected from the group consisting of: hydrogen, deuterium, fluorine, a cyano group, methyl, ethyl, isopropyl, n-propyl, t-butyl, —CF₃, —C₂F₅, —C₃F₇, —C₄F₉, —C₅F₁₁, —C₆F₁₃, —C₇F₁₅, —OCF₃, —OC₂F₅, —OC₃F₇, —OC₄F₉, —OC₅F₁₁, —OC₆F₁₃, —OC₇F₁₅, —SCF₃, —SC₂F₅, —SC₃F₇, —SC₄F₉, —SC₅F₁₁, —SC₆F₁₃, —SC₇F₁₅, —SF₅, and any one of the following groups substituted with one or more groups selected from the group consisting of: fluorine, a cyano group, methyl, ethyl, isopropyl, n-propyl, t-butyl, —CF₃, —C₂F₅, —C₃F₇, —C₄F₉, —C₅F₁₁, —C₆F₁₃, —C₇F₁₅, —OCF₃, —OC₂F₅, —OC₃F₇, —OC₄F₉, —OC₅F₁₁, —OC₆F₁₃, —OC₇F₁₅, —SCF₃, —SC₂F₅, —SC₃F₇, —SC₄F₉, —SC₅F₁₁, —SC₆F₁₃, —SC₇F₁₅ and —SF₅: aryl having 6 to 30 carbon atoms or heteroaryl having 3 to 30 carbon atoms;
at least one of Rₐ and R_{b} are, at each occurrence identically or differently, selected from the group consisting of: fluorine, a cyano group, —CF₃, —C₂F₅, —C₃F₇, —C₄F₉, —C₅F₁₁, —C₆F₁₃, —C₇F₁₅, —OCF₃, —OC₂F₅, —OC₃F₇, —OC₄F₉, —OC₅F₁₁, —OC₆F₁₃, —OC₇F₁₅, —SCF₃, —SC₂F₅, —SC₃F₇, —SC₄F₉, —SC₅F₁₁, —SC₆F₁₃, —SC₇F₁₅, —SF₅, and any one of the following groups substituted with one or more groups selected from the group consisting of: fluorine, a cyano group, —CF₃, —C₂F₅, —C₃F₇, —C₄F₉, —C₅F₁₁, —C₆F₁₃, —C₇F₁₅, —OCF₃, —OC₂F₅, —OC₃F₇, —OC₄F₉, —OC₅F₁₁, —OC₆F₁₃, —OC₇F₁₅, —SCF₃, —SC₂F₅, —SC₃F₇, —SC₄F₉, —SC₅F₁₁, —SC₆F₁₃, —SC₇F₁₅ and —SF₅: aryl having 6 to 30 carbon atoms or heteroaryl having 3 to 30 carbon atoms; and adjacent substituents Rₐ and R_{b} can be optionally joined to form a ring.

Herein, —CₙF₂ₙ₊₁ (wherein n is selected from 1 to 20, for example, —C₃F₇, —C₄F₉, —C₅F₁₁, —C₆F₁₃ or —C₇F₁₅) represents perfluoro-substituted alkyl having n carbon atoms and includes all possible straight-chain and branched-chain isomers thereof. For example, —C₃F₇ represents —CF₂CF₂CF₃ and —CF(CF₃)CF₃. Similarly, —OCₙF₂ₙ₊₁ (wherein n is selected from 1 to 20, for example, —OC₃F₇, —OC₄F₉, —OC₅F₁₁, —OC₆F₁₃ or —OC₇F₁₅) represents perfluoro-substituted alkoxy having n carbon atoms and includes all possible straight-chain and branched-chain isomers thereof. For example, —OC₃F₇ represents —OCF₂CF₂CF₃ and —OCF(CF₃)CF₃. Similarly, —SCₙF₂ₙ₊₁ (wherein n is selected from 1 to 20, for example, —SC₃F₇, —SC₄F₉, —SC₅F₁₁, —SC₆F₁₃ or —SC₇F₁₅) represents perfluoro-substituted alkylthio having n carbon atoms and includes all possible straight-chain and branched-chain isomers thereof. For example, —SC₃F₇ represents —SCF₂CF₂CF₃ and —SCF(CF₃)CF₃. Obviously, it will be appreciated by those skilled in the art that -nCₙF₂ₙ₊₁ (for example, -nC₃F₇, -nC₄F₉, -nC₅F₁₁, -nC₆F₁₃ or -nC₇Fi₅) represents only perfluoro-substituted normal alkyl (straight-chain alkyl) having n carbon atoms; for example, -nC₃F₇ represents only —CF₂CF₂CF₃; similarly, —O-nCₙF₂ₙ₊₁ (for example, —O-nC₃F₇, —O-nC₄F₉, —O-nC₅F₁₁, —O-nC₆F₁₃ or —O-nC₇F₁₅) represents only perfluoro-substituted normal alkoxy (straight-chain alkoxy) having n carbon atoms; for example, —O-nC₃F₇ represents only —O—CF₂CF₂CF₃; similarly, —S-nCₙF₂ₙ₊₁ (for example, —S-nC₃F₇, —S-nC₄F₉, —S-nC₅F₁₁, —S-nC₆F₁₃ or —S-nC₇Fi₅) represents only perfluoro-substituted normal alkylthio (straight-chain alkylthio) having n carbon atoms; for example, —S-nC₃F₇ represents only —S—CF₂CF₂CF₃.

According to an embodiment of the present disclosure, Rₐ and R_{b} are, at each occurrence identically or differently, selected from the group consisting of: hydrogen, deuterium, fluorine, a cyano group, methyl, ethyl, isopropyl, n-propyl, t-butyl, —CF₃, —C₂F₅, —C₃F₇, —C₄F₉, —C₅F₁₁, —C₆F₁₃, —C₇F₁₅, —OCF₃, —OC₂F₅, —OC₃F₇, —OC₄F₉, —OC₅F₁₁, —OC₆F₁₃, —OC₇F₁₅, —SCF₃, —SC₂F₅, —SC₃F₇, —SC₄F₉, —SC₅F₁₁, —SC₆F₁₃, —SC₇F₁₅, —SF₅, and any one of the following groups substituted with one or more groups selected from the group consisting of: F, OCF₃, CN and CF₃: phenyl, biphenyl, pyridyl, pyrimidinyl, triazinyl, oxaboraanthryl and combinations thereof,
at least one of Rₐ and R_{b} is, at each occurrence identically or differently, selected from the group consisting of: fluorine, a cyano group, —CF₃, —C₂F₅, —C₃F₇, —C₄F₉, —C₅F₁₁, —C₆F₁₃, —C₇F₁₅, —OCF₃, —OC₂F₅, —OC₃F₇, —OC₄F₉, —OC₅F₁₁, —OC₆F₁₃, —OC₇F₁₅, —SCF₃, —SC₂F₅, —SC₃F₇, —SC₄F₉, —SC₅F₁₁, —SC₆F₁₃, —SC₇F₁₅, —SF₅, phenyl or biphenyl substituted with one or more of F, OCF₃, CN or CF₃, pyridyl, pyrimidinyl, triazinyl, oxaboraanthryl and combinations thereof, and
adjacent substituents Rₐ and R_{b} can be optionally joined to form a ring.

According to an embodiment of the present disclosure, the P-type conductive doping material is selected from the group consisting of Compound 1-1 to Compound 1-55, Compound 2-1 to Compound 2-11, Compound 3-1 to Compound 3-39 and Compound 4-1 to Compound 4-82:

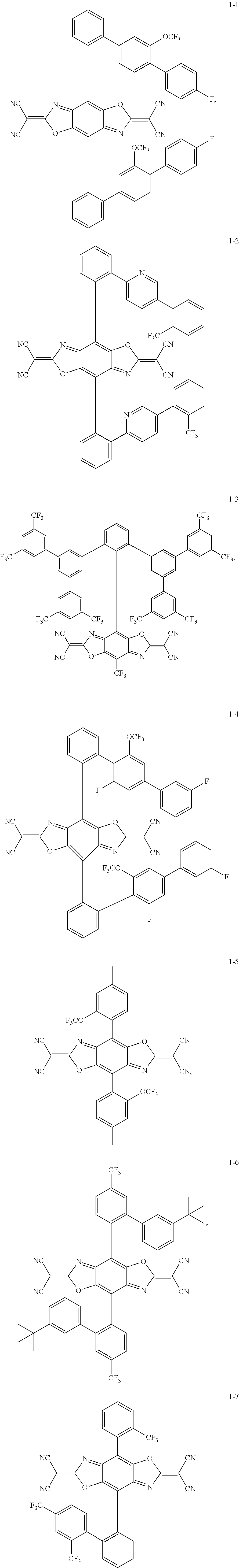

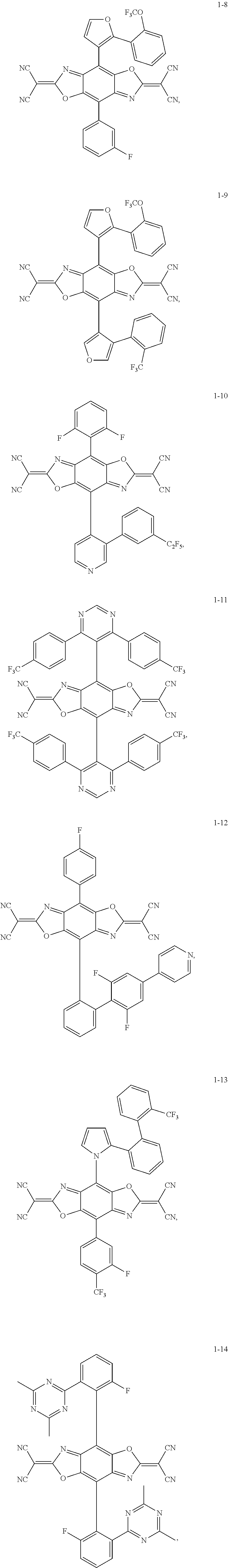

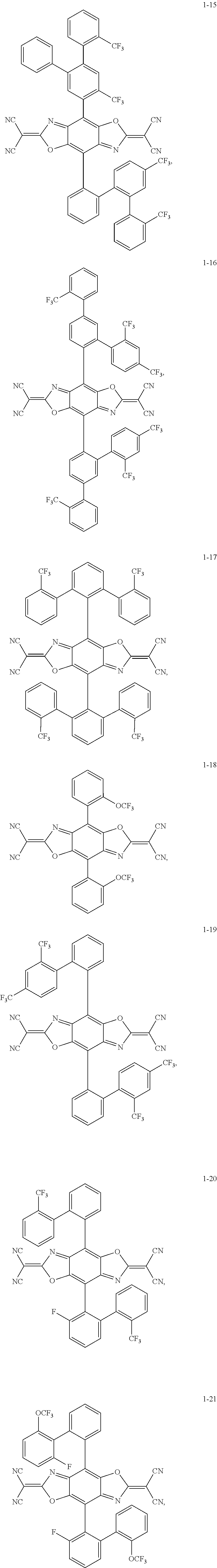

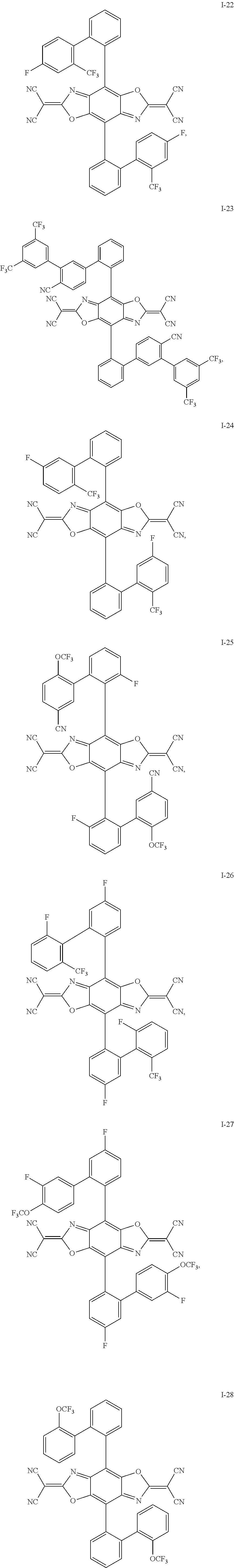

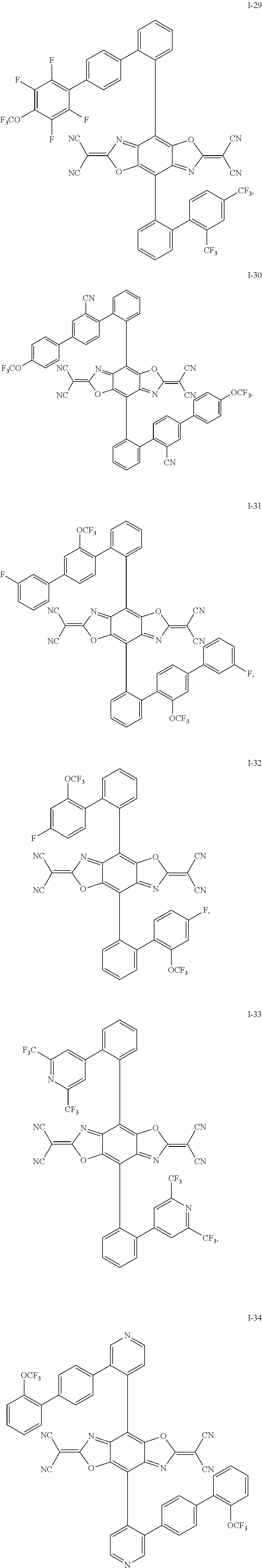

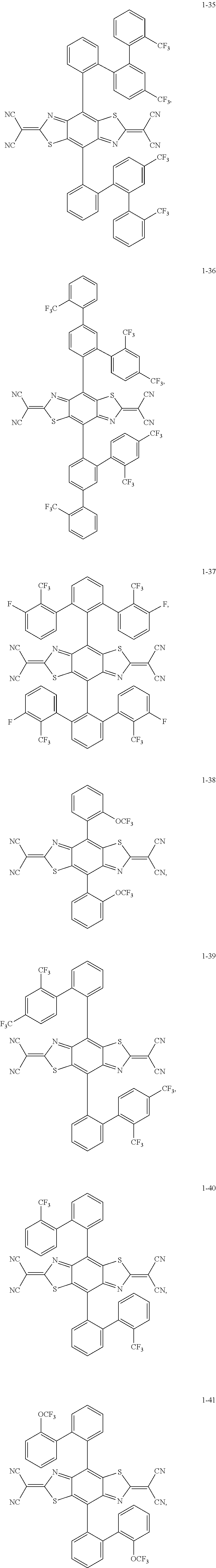

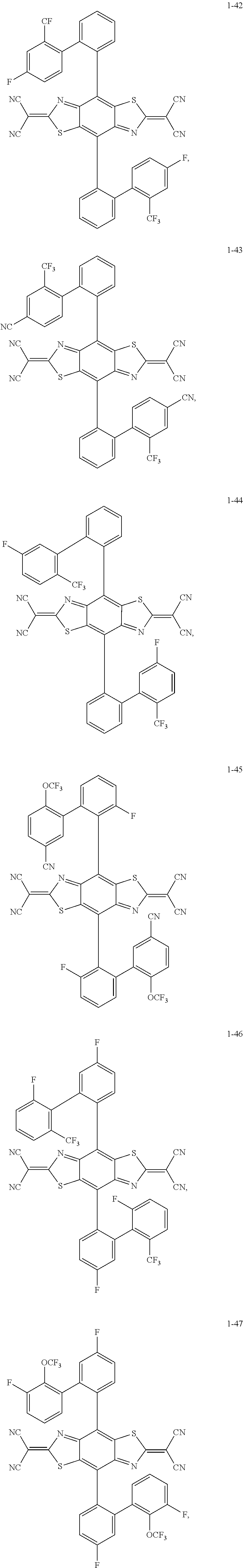

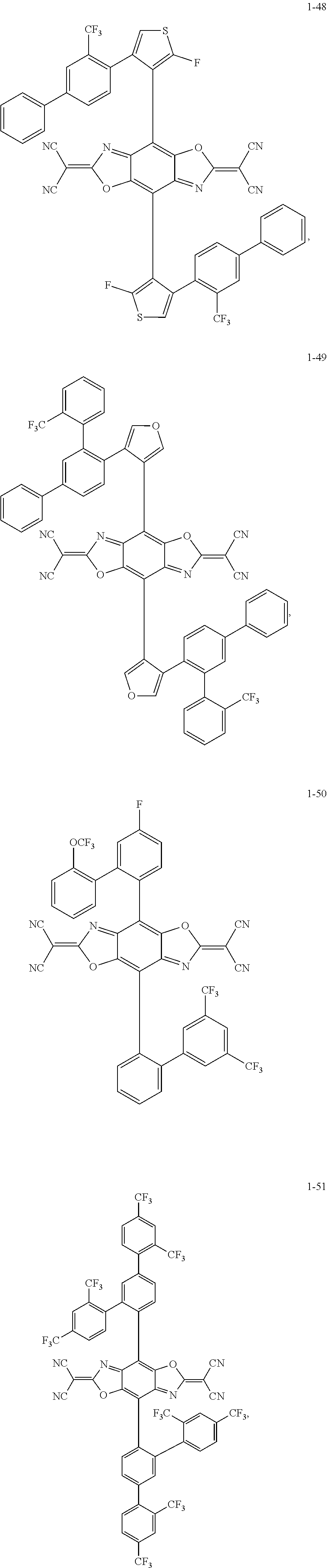

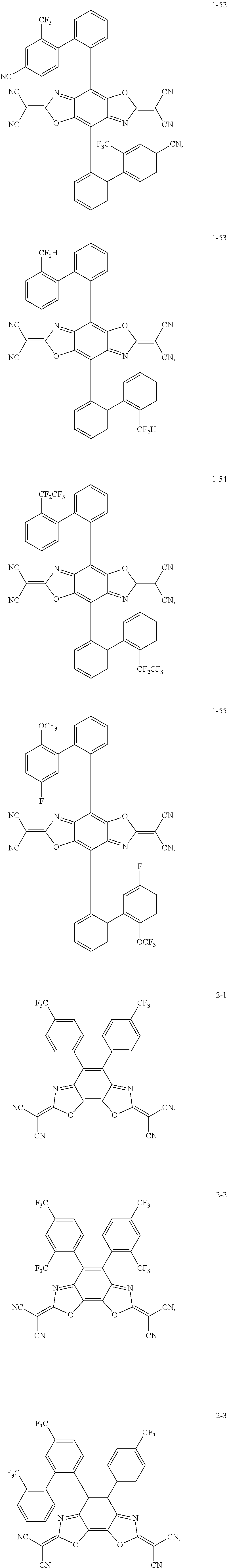

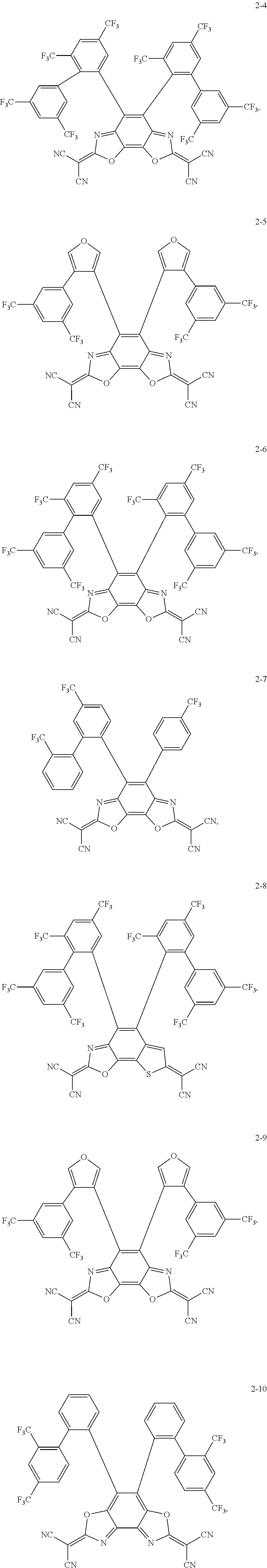

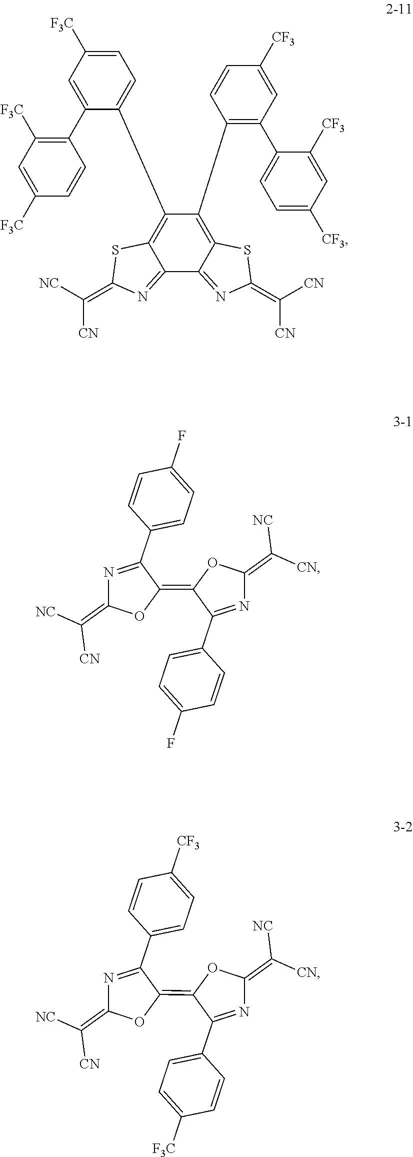 [SMILES: N#CC(C#N)=c1nc2c(s1)c(-c1ccc(C(F)(F)F)cc1-c1ccc(C(F)(F)F)cc1C(F)(F)F)c(-c1ccc(C(F)(F)F)cc1-c1ccc(C(F)(F)F)cc1C(F)(F)F)c1sc(=C(C#N)C#N)nc12 ; N#CC(C#N)=c1nc(-c2ccc(F)cc2)/c(=c2\oc(=C(C#N)C#N)nc2-c2ccc(F)cc2)o1 ; N#CC(C#N)=c1nc(-c2ccc(C(F)(F)F)cc2)/c(=c2\oc(=C(C#N)C#N)nc2-c2ccc(C(F)(F)F)cc2)o1]

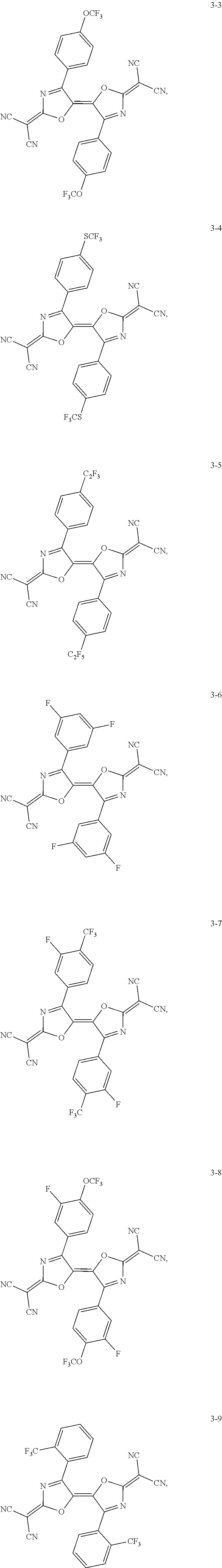

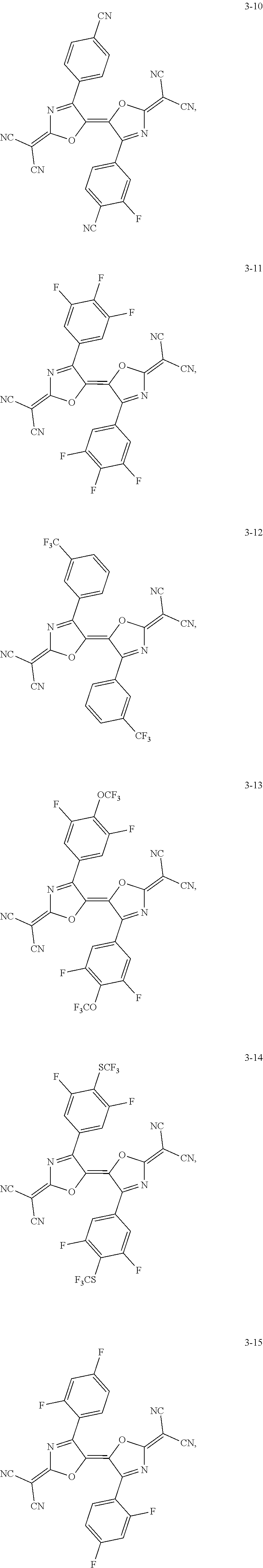

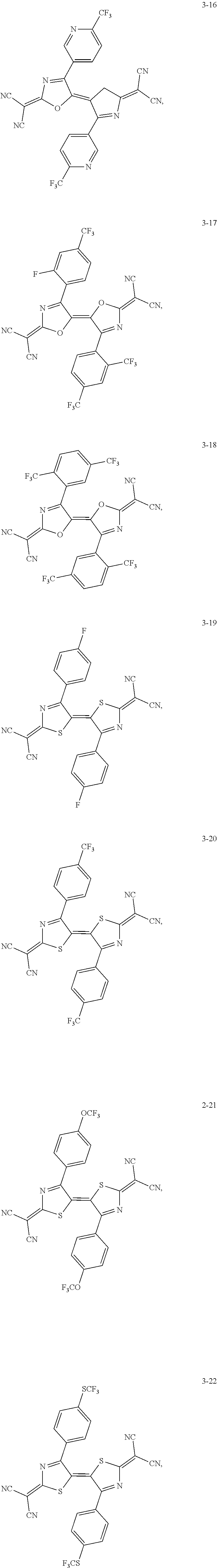

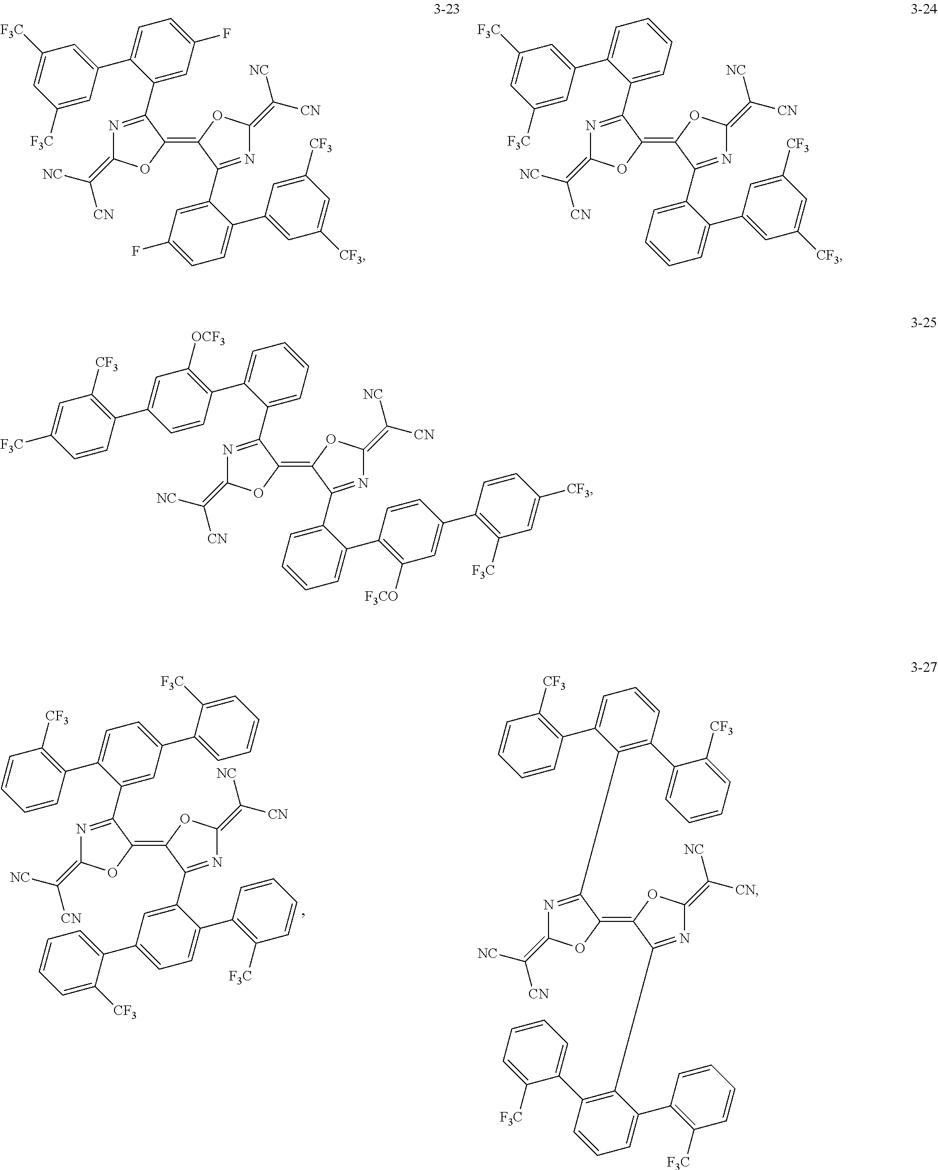

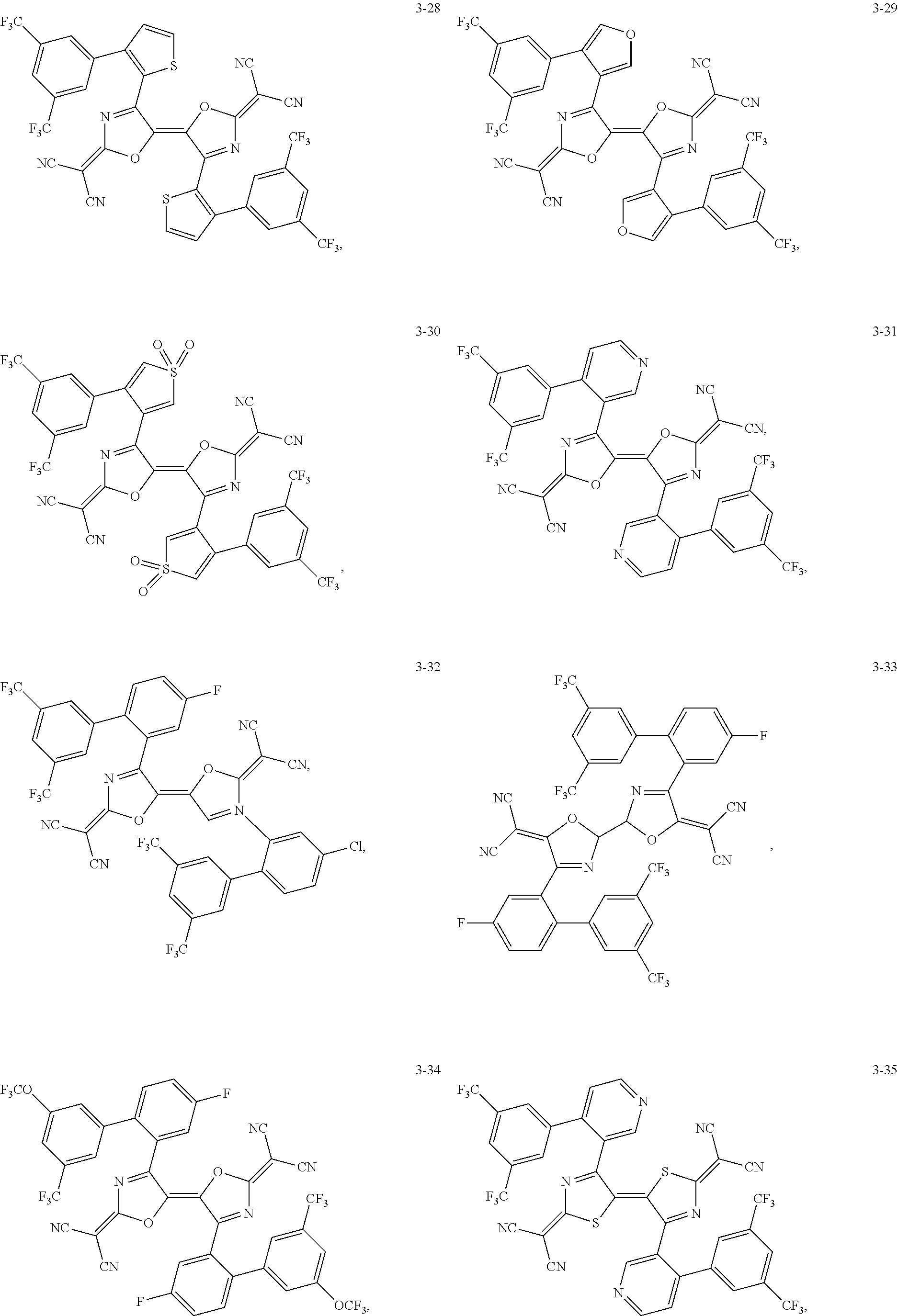

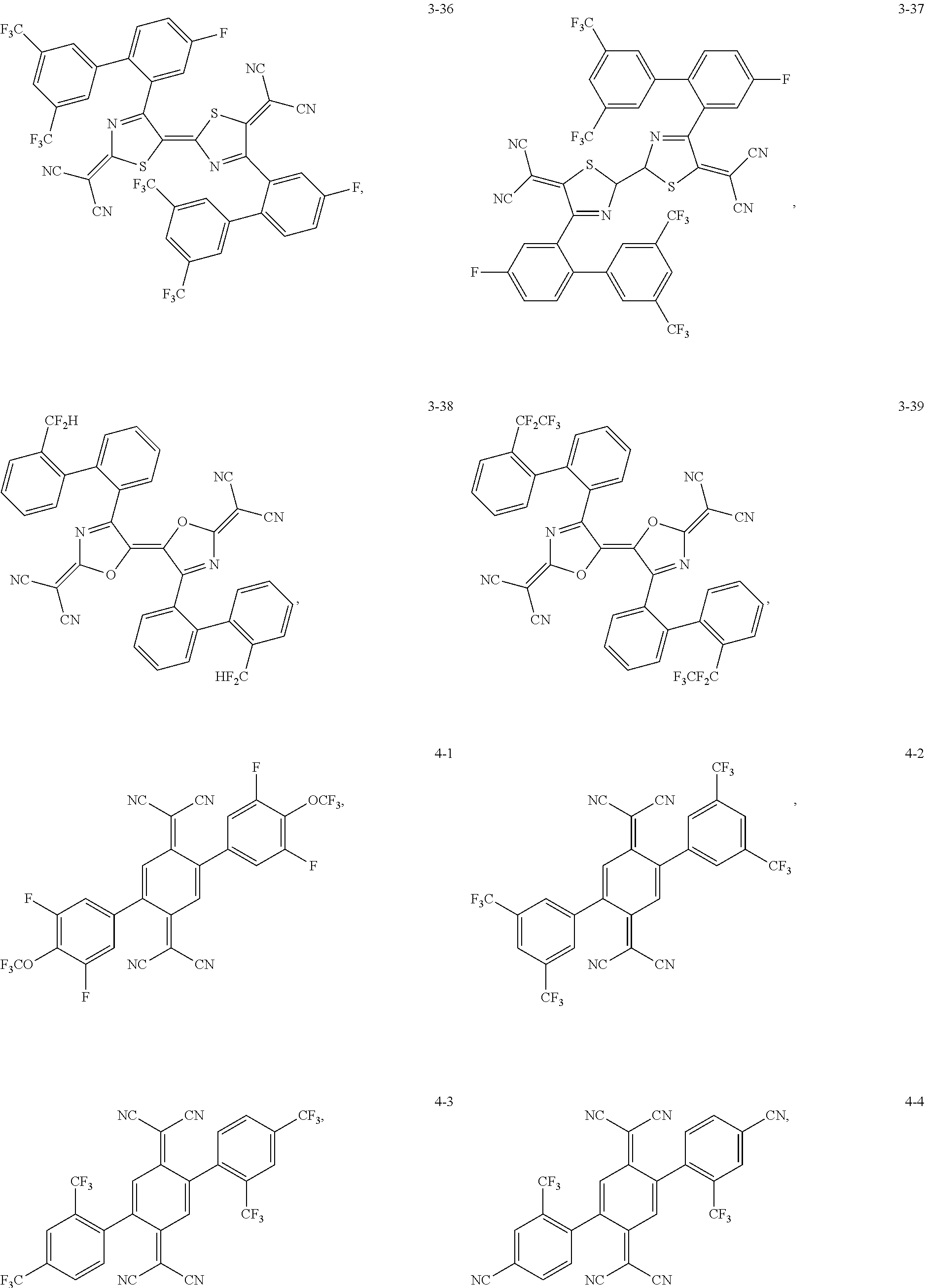

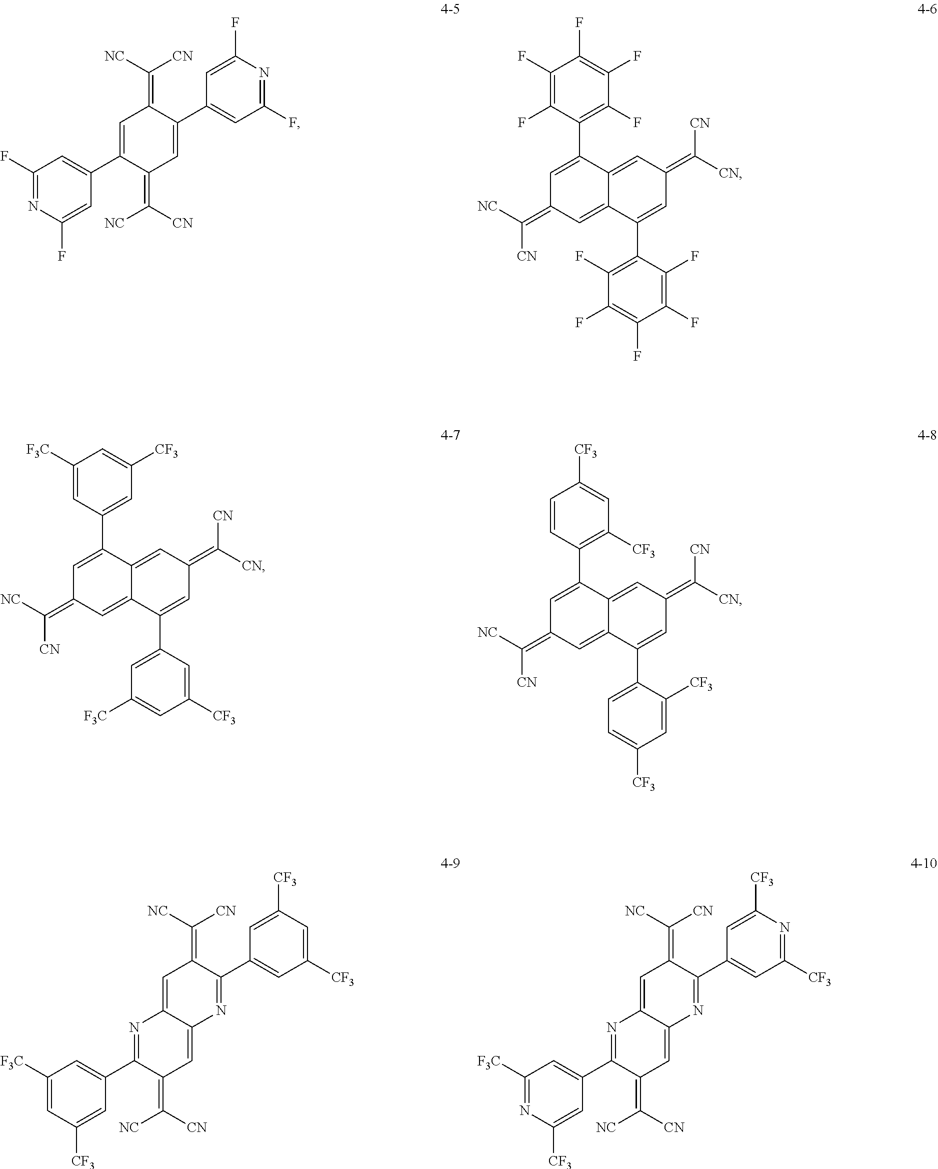

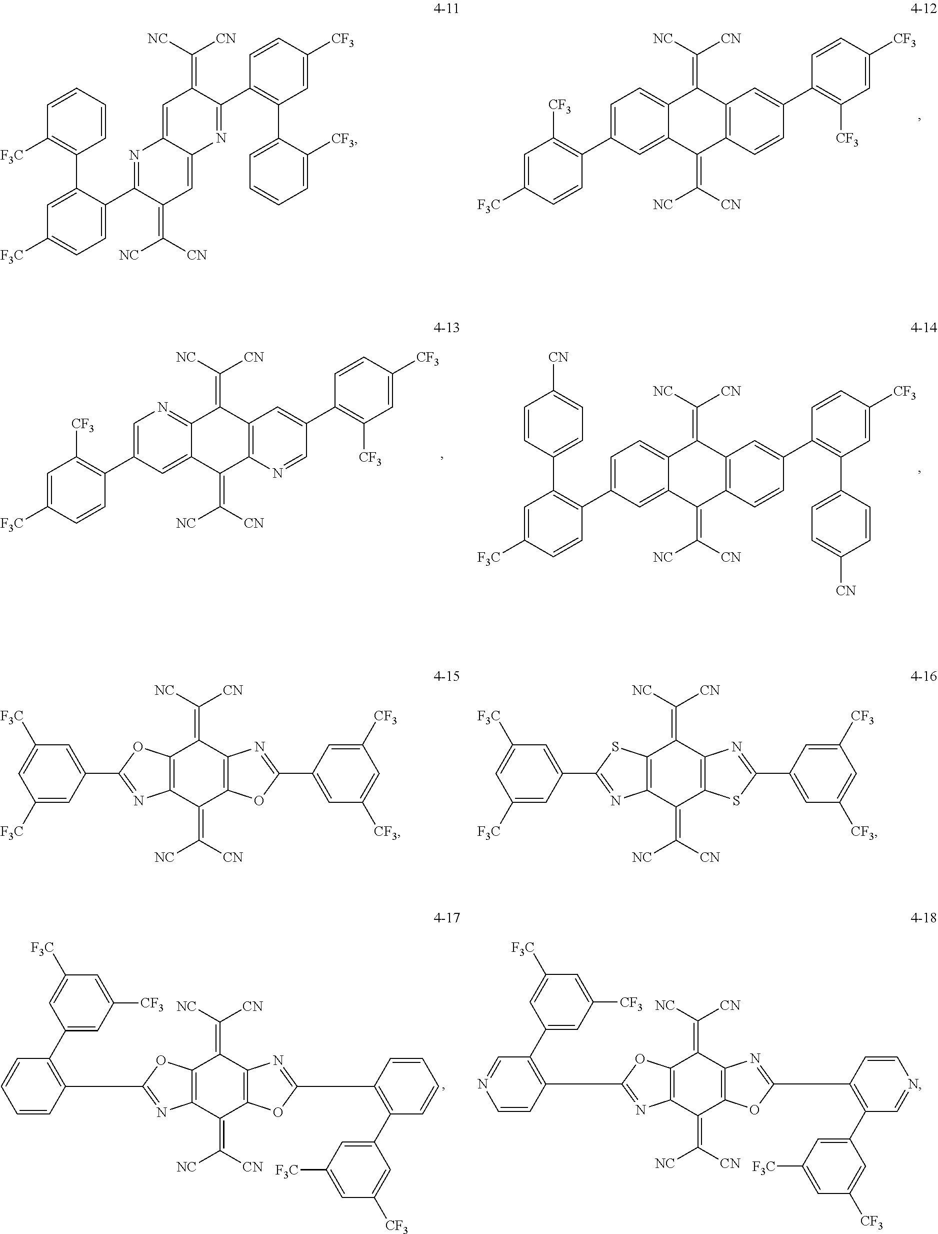

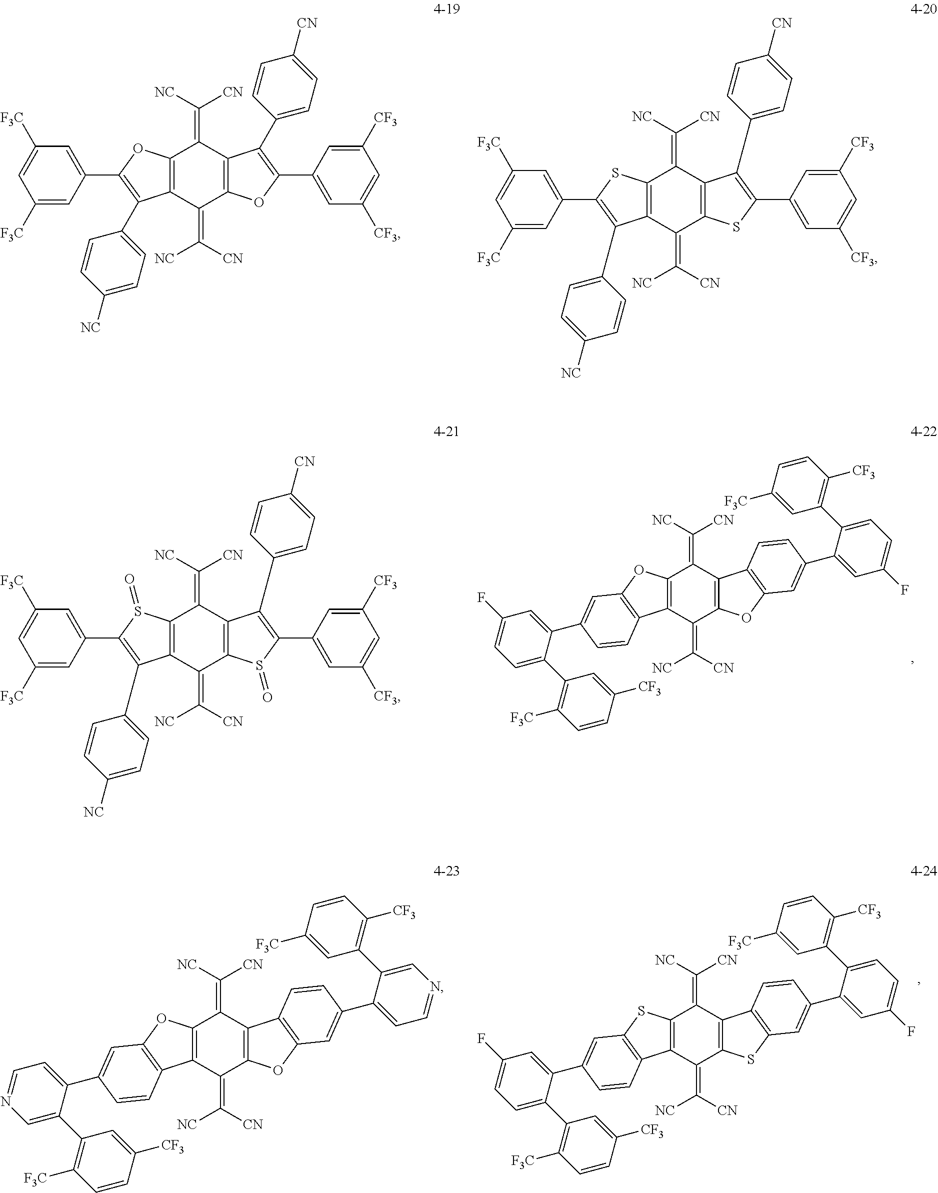

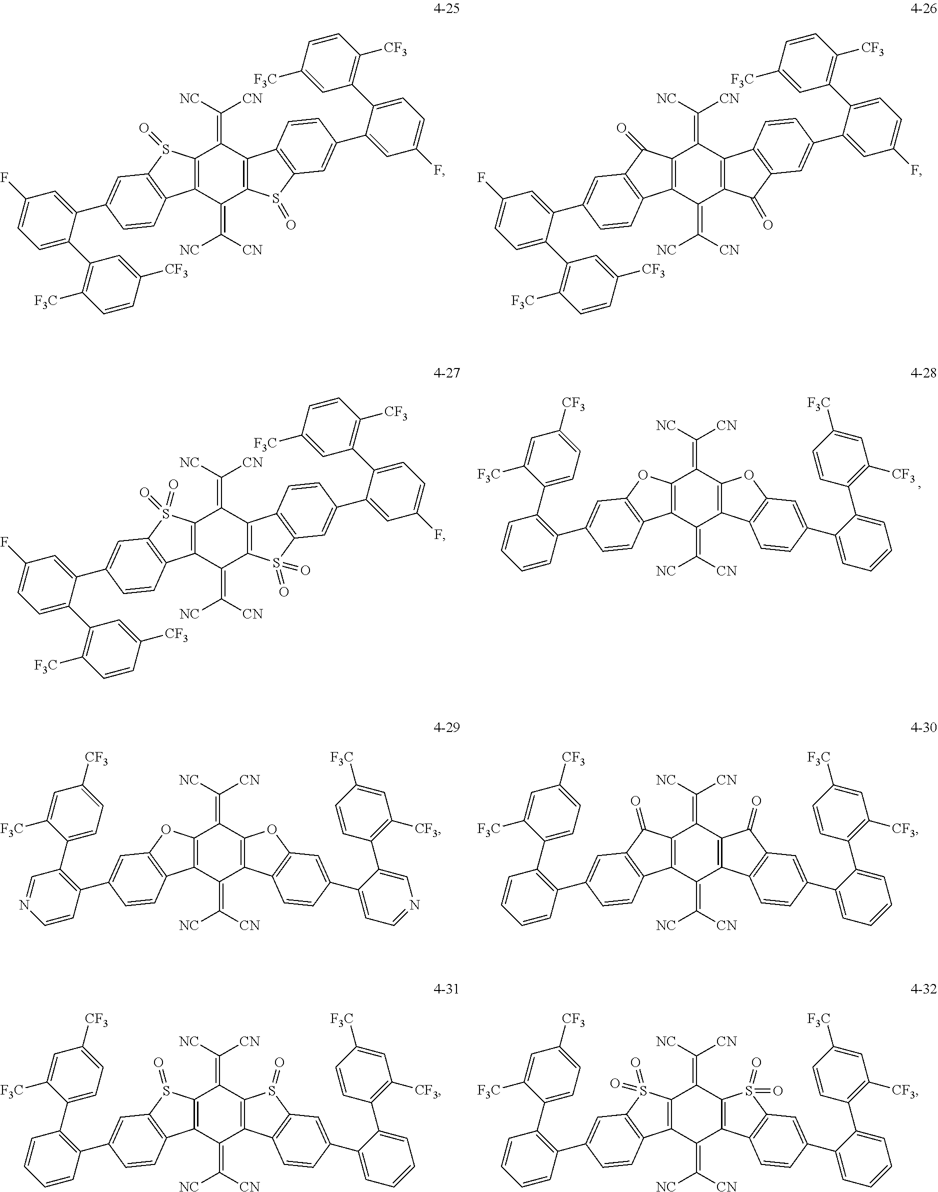

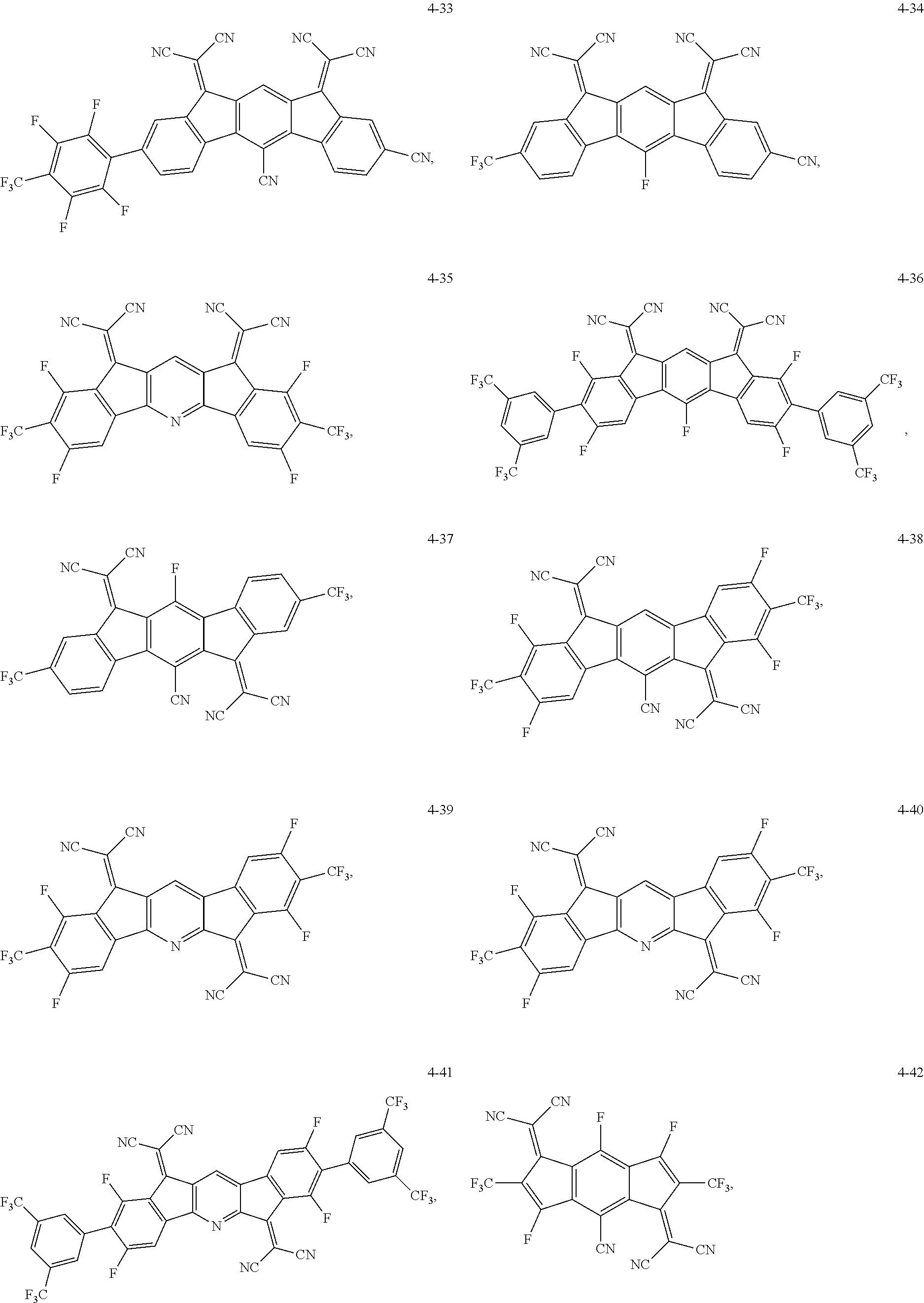

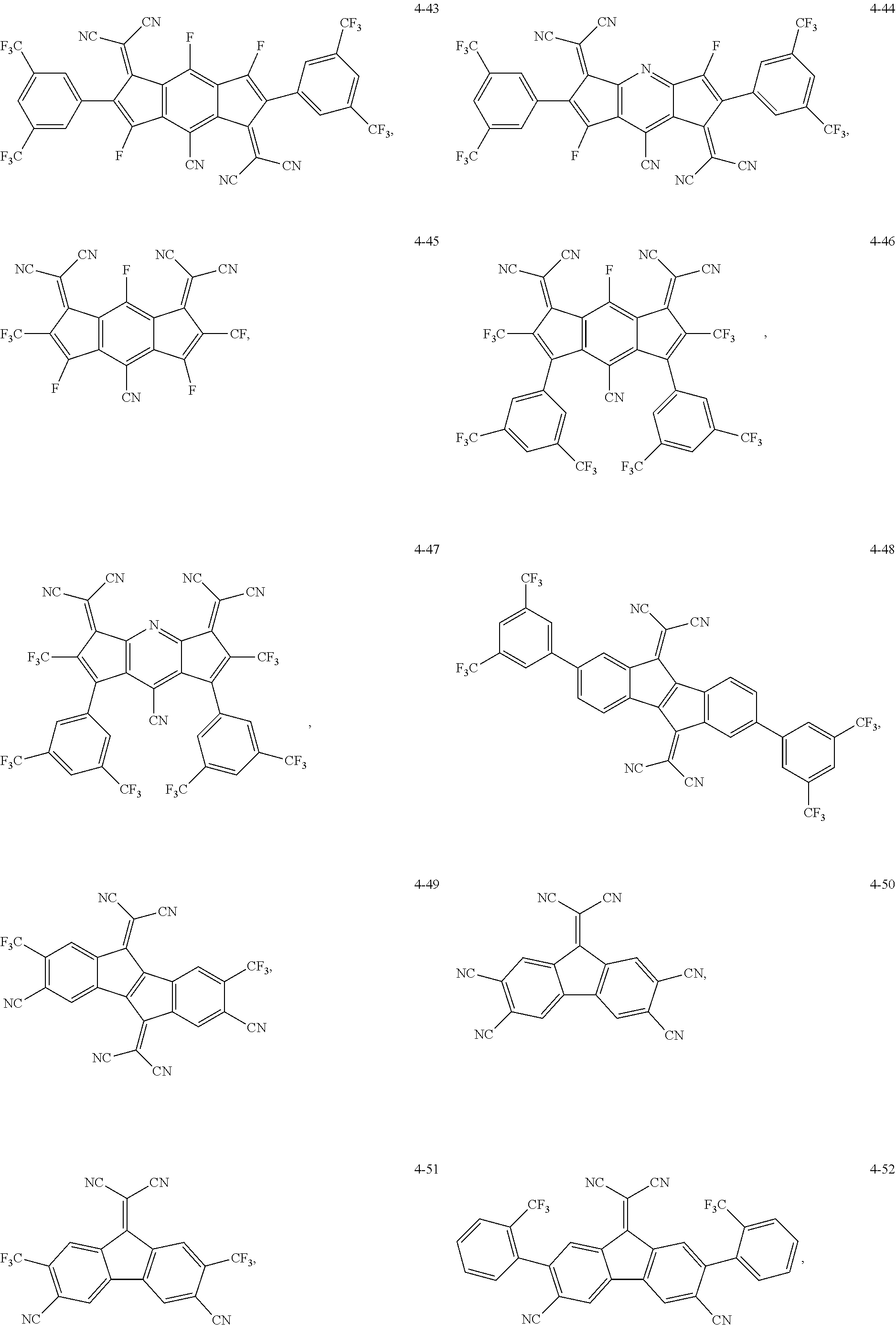

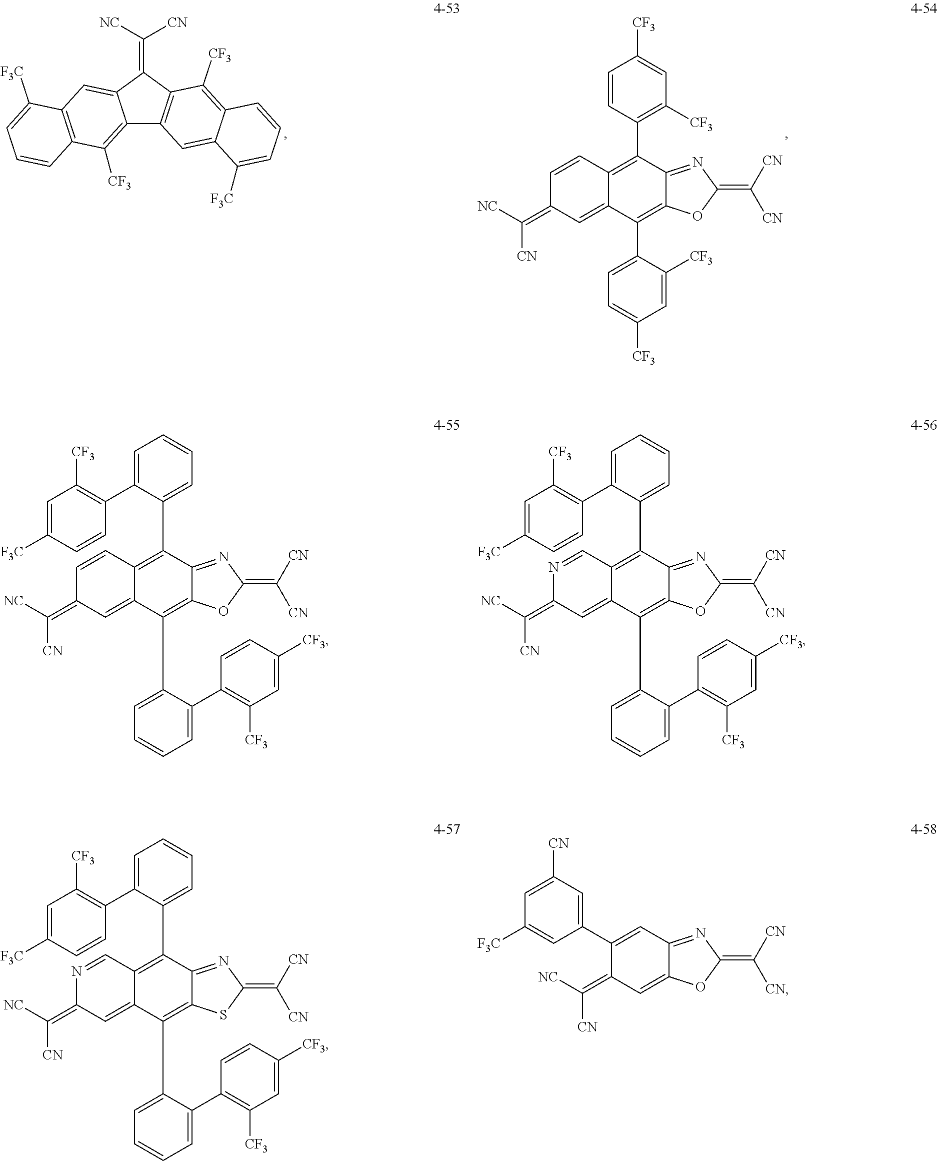

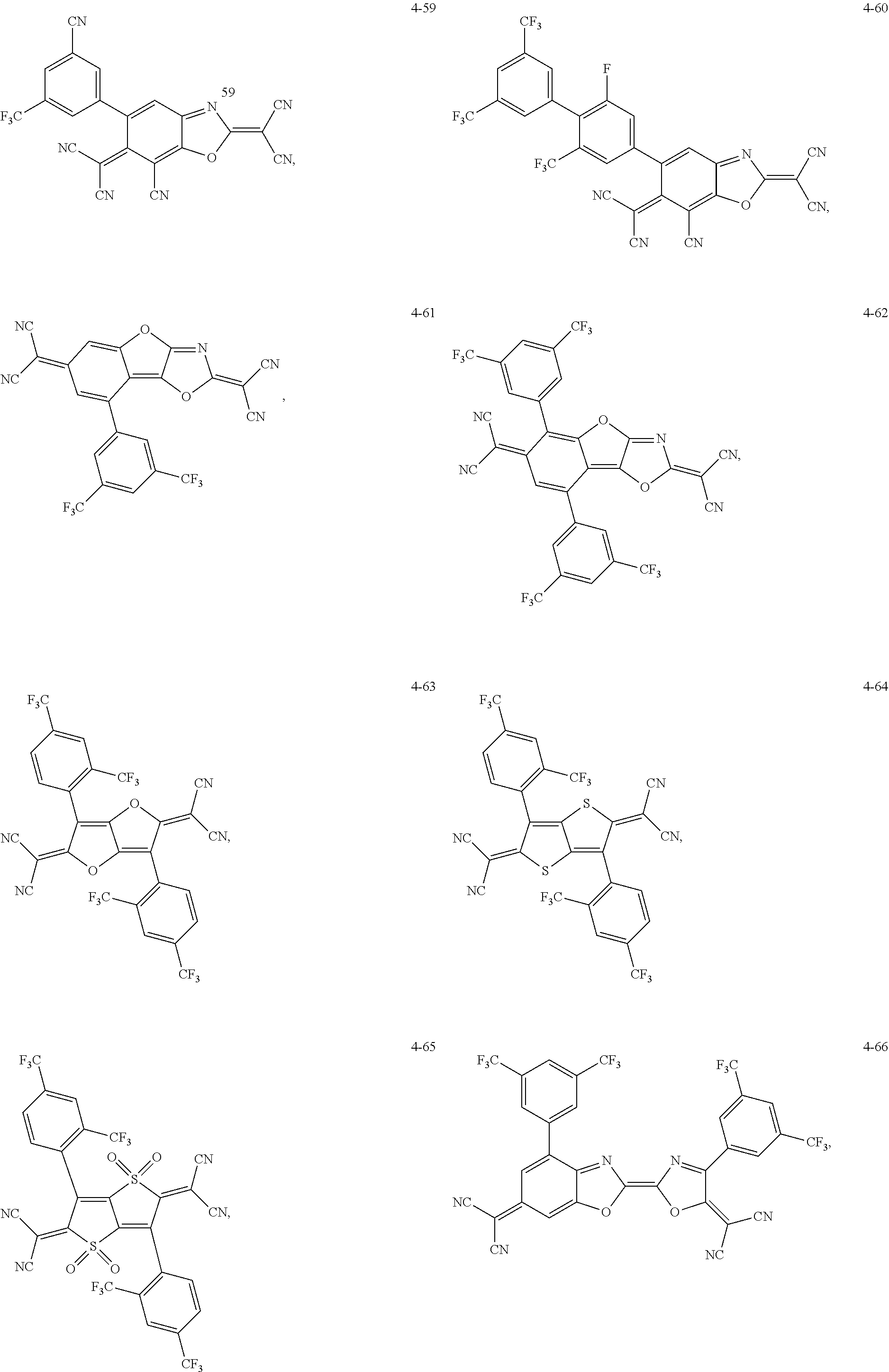

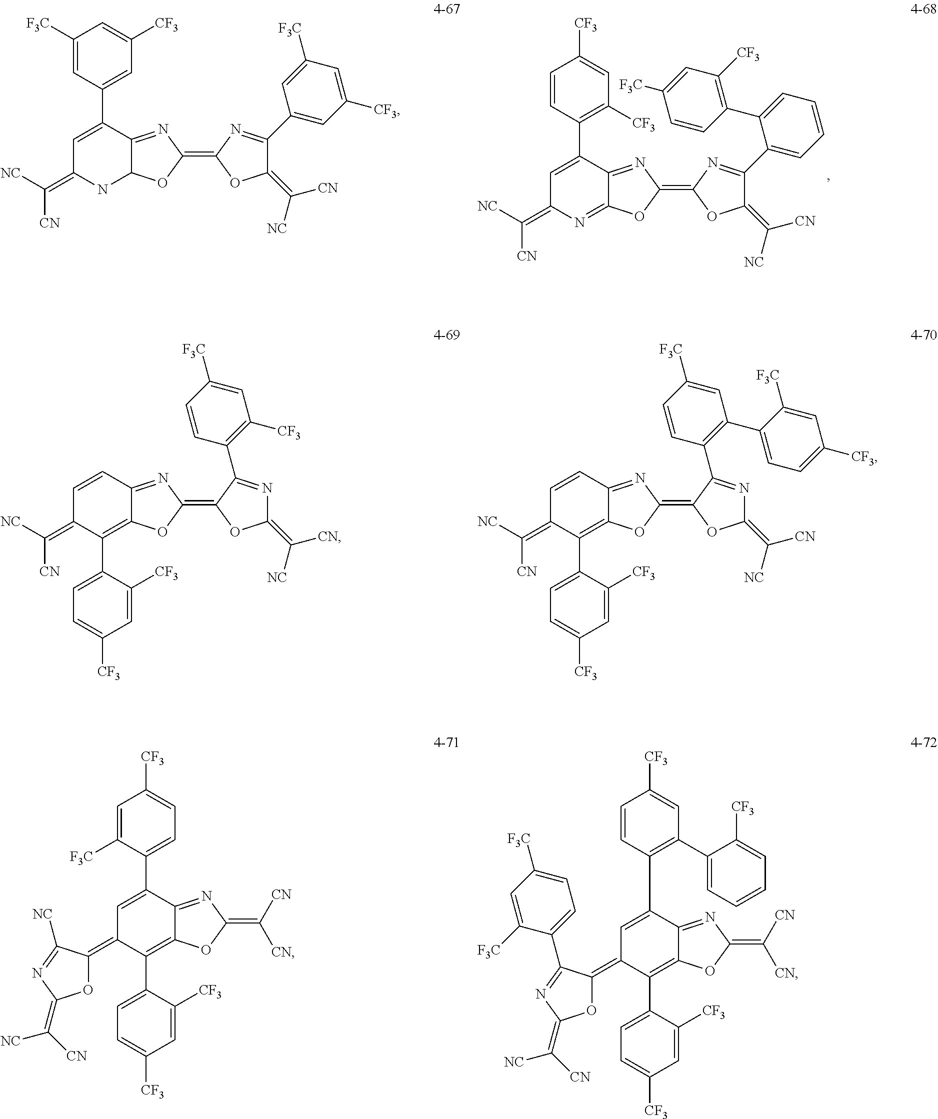

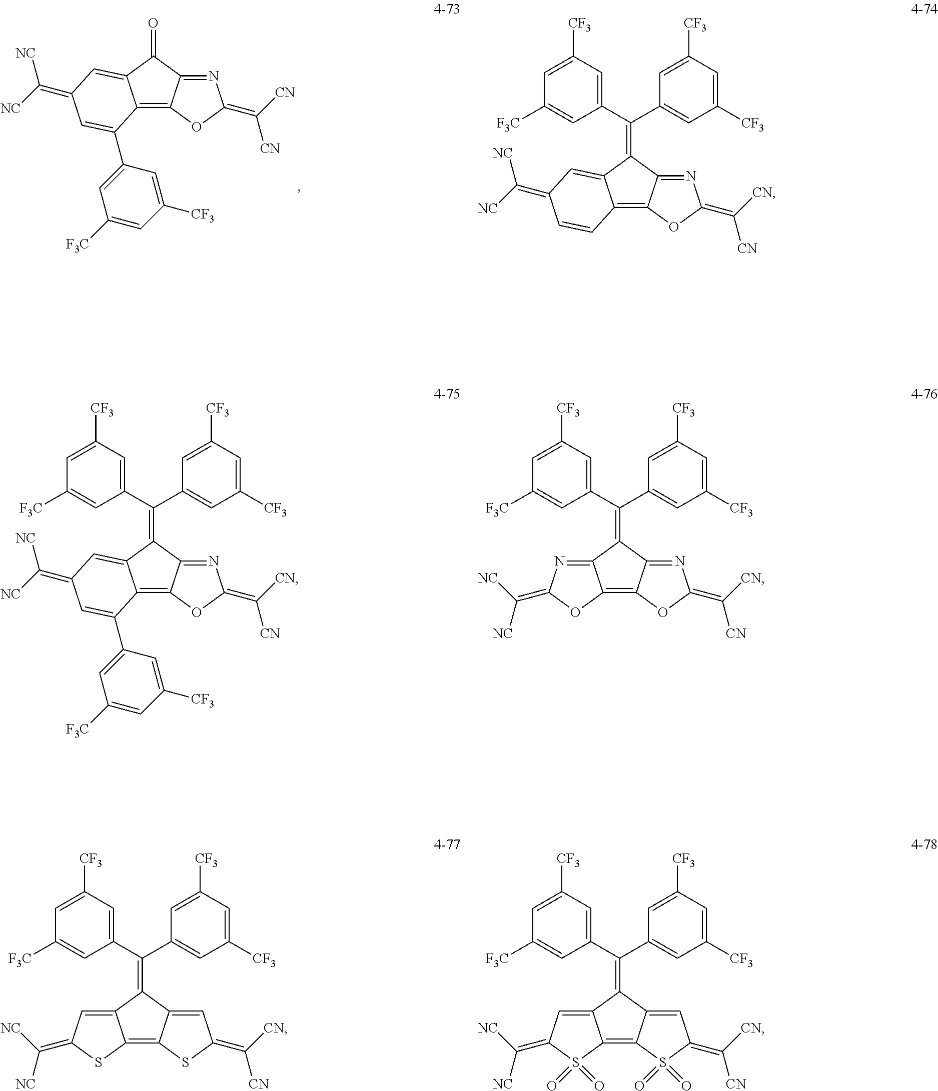

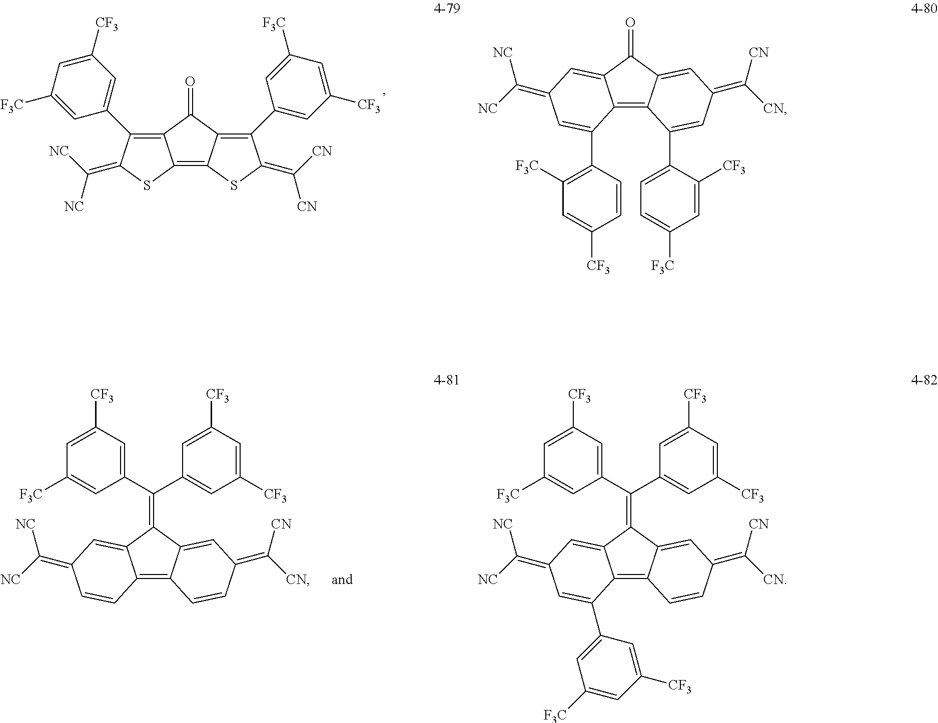 [SMILES: N#CC(C#N)=c1sc2c(c1-c1cc(C(F)(F)F)cc(C(F)(F)F)c1)C(=O)c1c(-c3cc(C(F)(F)F)cc(C(F)(F)F)c3)c(=C(C#N)C#N)sc1=2 ; N#CC(C#N)=c1cc2c(c(-c3ccc(C(F)(F)F)cc3C(F)(F)F)c1)=c1c(cc(=C(C#N)C#N)cc1-c1ccc(C(F)(F)F)cc1C(F)(F)F)C2=O ; N#CC(C#N)=c1ccc2c(c1)C(=C(c1cc(C(F)(F)F)cc(C(F)(F)F)c1)c1cc(C(F)(F)F)cc(C(F)(F)F)c1)c1cc(=C(C#N)C#N)ccc1=2 ; N#CC(C#N)=c1ccc2c(c1)C(=C(c1cc(C(F)(F)F)cc(C(F)(F)F)c1)c1cc(C(F)(F)F)cc(C(F)(F)F)c1)c1cc(=C(C#N)C#N)cc(-c3cc(C(F)(F)F)cc(C(F)(F)F)c3)c1=2]

According to an embodiment of the present disclosure, hydrogen in the structures of Compound 1-1 to Compound 1-55, Compound 2-1 to Compound 2-11, Compound 3-1 to Compound 3-39 and Compound 4-1 to Compound 4-82 can be partially or fully substituted with deuterium.

According to an embodiment of the present disclosure, the hole transport material (the first hole transport material, the second hole transport material or the third hole transport material) is selected from the group consisting of the following compounds: compounds having a triarylamine unit, spirobifluorene compounds, pentacene compounds, oligothiophene compounds, oligophenyl compounds, oligophenylenevinylene compounds, oligofluorene compounds, porphyrin complexes and metallic phthalocyanine complexes.

According to an embodiment of the present disclosure, the hole transport material comprises any one or more chemical structural units selected from the group consisting of triarylamine, carbazole, fluorene, spirobifluorene, thiophene, furan, phenyl, oligophenylene ethylene, oligofluorene and combinations thereof.

According to an embodiment of the present disclosure, the hole transport material comprises a monotriarylamine structural unit or a bistriarylamine structural unit.

According to an embodiment of the present disclosure, the hole transport material has a structure represented by Formula 2 or Formula 3:

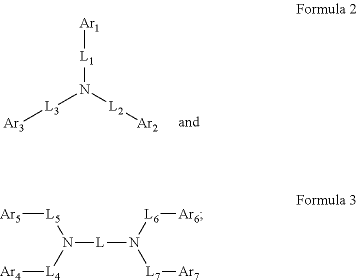

wherein Ar₁ to Ar₇ are, at each occurrence identically or differently, selected from substituted or unsubstituted aryl having 6 to 30 carbon atoms, substituted or unsubstituted heteroaryl having 3 to 30 carbon atoms or a combination thereof,
L is selected from substituted or unsubstituted arylene having 6 to 30 carbon atoms, substituted or unsubstituted heteroarylene having 3 to 30 carbon atoms or a combination thereof, and
L₁ to L₇ are, at each occurrence identically or differently, selected from a single bond, substituted or unsubstituted arylene having 6 to 30 carbon atoms, substituted or unsubstituted heteroarylene having 3 to 30 carbon atoms or a combination thereof.

According to an embodiment of the present disclosure, Formula 2 represents a monoamine compound containing only the one amino N atom shown.

According to an embodiment of the present disclosure, Ar₁ to Ar₇ are, at each occurrence identically or differently, selected from substituted or unsubstituted phenyl, substituted or unsubstituted biphenyl, substituted or unsubstituted terphenyl, substituted or unsubstituted naphthyl, substituted or unsubstituted dibenzofuranyl, substituted or unsubstituted dibenzothienyl, substituted or unsubstituted dibenzoselenophenyl, substituted or unsubstituted carbazolyl, substituted or unsubstituted phenanthryl, substituted or unsubstituted triphenylenyl, substituted or unsubstituted pyridyl, substituted or unsubstituted anthryl, substituted or unsubstituted pyrenyl, substituted or unsubstituted fluorenyl or a combination thereof.

According to an embodiment of the present disclosure, Ar₁ to Ar₃ and substituents thereof cannot be selected from carbazolyl.

According to an embodiment of the present disclosure, Ar₁ to Ar₇ and substituents thereof cannot be selected from carbazolyl.

According to an embodiment of the present disclosure, L is identically or differently selected from substituted or unsubstituted phenylene, substituted or unsubstituted biphenylylene, substituted or unsubstituted terphenylene, substituted or unsubstituted naphthylene, substituted or unsubstituted dibenzofuranylene, substituted or unsubstituted dibenzothienylene, substituted or unsubstituted dibenzoselenophenylene, substituted or unsubstituted carbazolylene, substituted or unsubstituted phenanthrylene, substituted or unsubstituted triphenylenylene, substituted or unsubstituted pyridylene, substituted or unsubstituted anthrylene, substituted or unsubstituted pyrenylene, substituted or unsubstituted fluorenylene or a combination thereof.

According to an embodiment of the present disclosure, L₁ to L₇ are, at each occurrence identically or differently, selected from a single bond, substituted or unsubstituted phenylene, substituted or unsubstituted biphenylylene, substituted or unsubstituted terphenylene, substituted or unsubstituted naphthylene, substituted or unsubstituted dibenzofuranylene, substituted or unsubstituted dibenzothienylene, substituted or unsubstituted dibenzoselenophenylene, substituted or unsubstituted carbazolylene, substituted or unsubstituted phenanthrylene, substituted or unsubstituted triphenylenylene, substituted or unsubstituted pyridylene, substituted or unsubstituted anthrylene, substituted or unsubstituted pyrenylene, substituted or unsubstituted fluorenylene or a combination thereof.

According to an embodiment of the present disclosure, the hole transport material has a structure represented by Formula 2-1 or Formula 3-1:

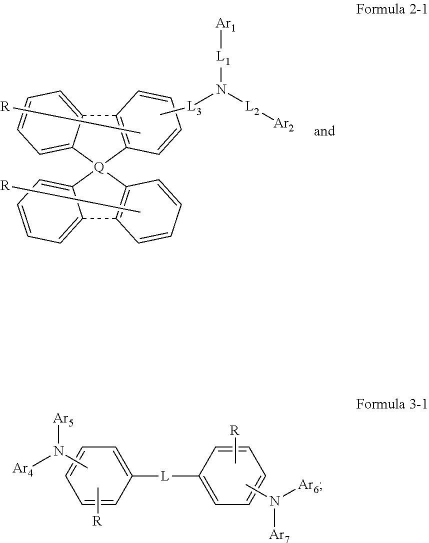

wherein Q is selected from C, Si or Ge;
Ar₁, Ar₂, Ar₄, Ar₅, Ar₆ and Ar₇ are, at each occurrence identically or differently, selected from substituted or unsubstituted aryl having 6 to 30 carbon atoms, substituted or unsubstituted heteroaryl having 3 to 30 carbon atoms or a combination thereof,
L, L₁, L₂ and L₃ are, at each occurrence identically or differently, selected from a single bond, substituted or unsubstituted arylene having 6 to 30 carbon atoms, substituted or unsubstituted heteroarylene having 3 to 30 carbon atoms or a combination thereof,
R represents, at each occurrence identically or differently, mono-substitution, multiple substitutions, or non-substitution;
R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof, and
the dashed line indicates no bond or a single bond, and adjacent substituents R can be optionally joined to form a ring.

According to an embodiment of the present disclosure, the hole transport material is selected from the group consisting of Compound HT-1 to Compound HT-66:

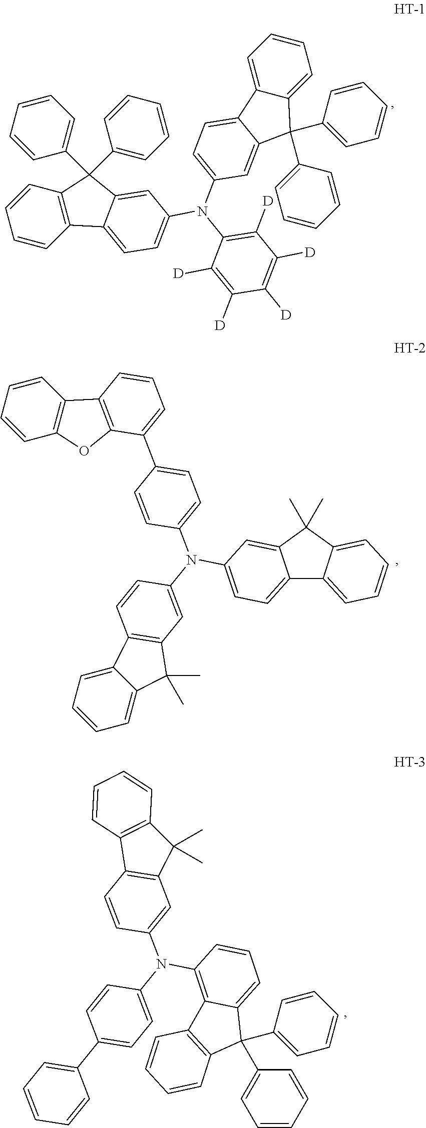 [SMILES: [2H]c1c([2H])c([2H])c(N(c2ccc3c(c2)C(c2ccccc2)(c2ccccc2)c2ccccc2-3)c2ccc3c(c2)C(c2ccccc2)(c2ccccc2)c2ccccc2-3)c([2H])c1[2H] ; CC1(C)c2ccccc2-c2ccc(N(c3ccc(-c4cccc5c4oc4ccccc45)cc3)c3ccc4c(c3)C(C)(C)c3ccccc3-4)cc21 ; CC1(C)c2ccccc2-c2ccc(N(c3ccc(-c4ccccc4)cc3)c3cccc4c3-c3ccccc3C4(c3ccccc3)c3ccccc3)cc21]

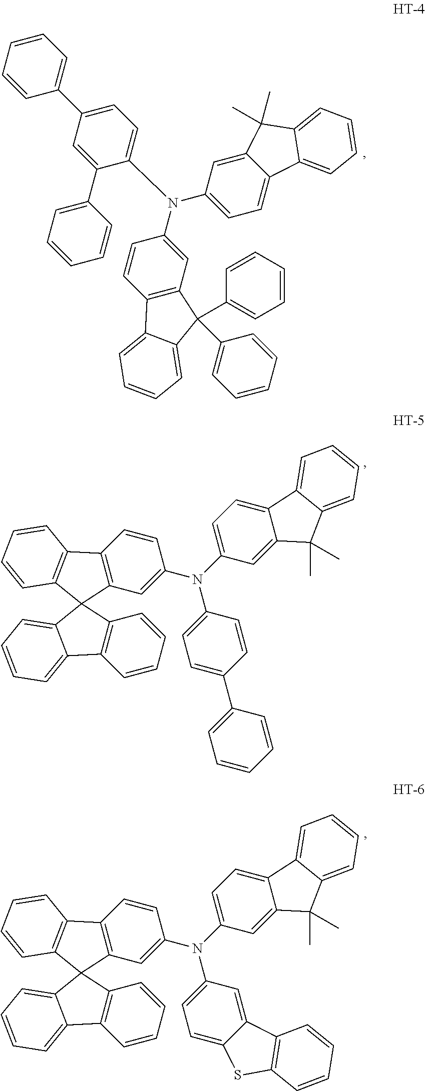 [SMILES: CC1(C)c2ccccc2-c2ccc(N(c3ccc4c(c3)C(c3ccccc3)(c3ccccc3)c3ccccc3-4)c3ccc(-c4ccccc4)cc3-c3ccccc3)cc21 ; CC1(C)c2ccccc2-c2ccc(N(c3ccc(-c4ccccc4)cc3)c3ccc4c(c3)C3(c5ccccc5-c5ccccc53)c3ccccc3-4)cc21 ; CC1(C)c2ccccc2-c2ccc(N(c3ccc4c(c3)C3(c5ccccc5-c5ccccc53)c3ccccc3-4)c3ccc4sc5ccccc5c4c3)cc21]

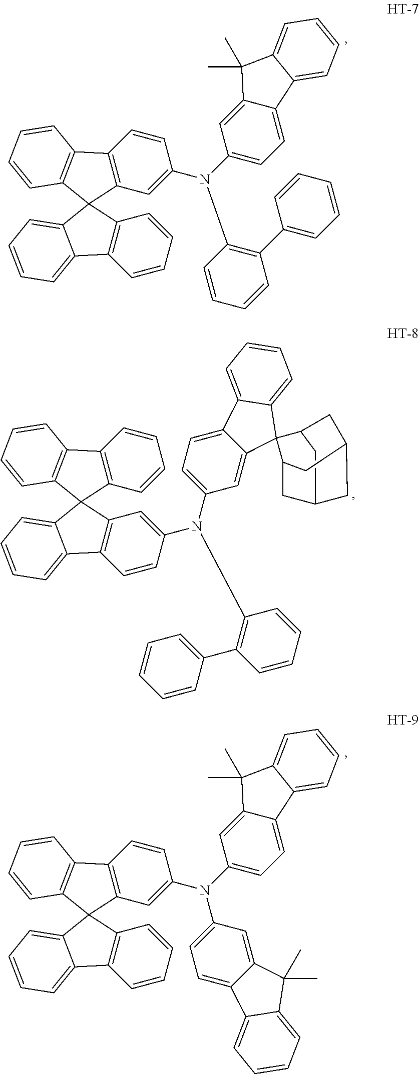

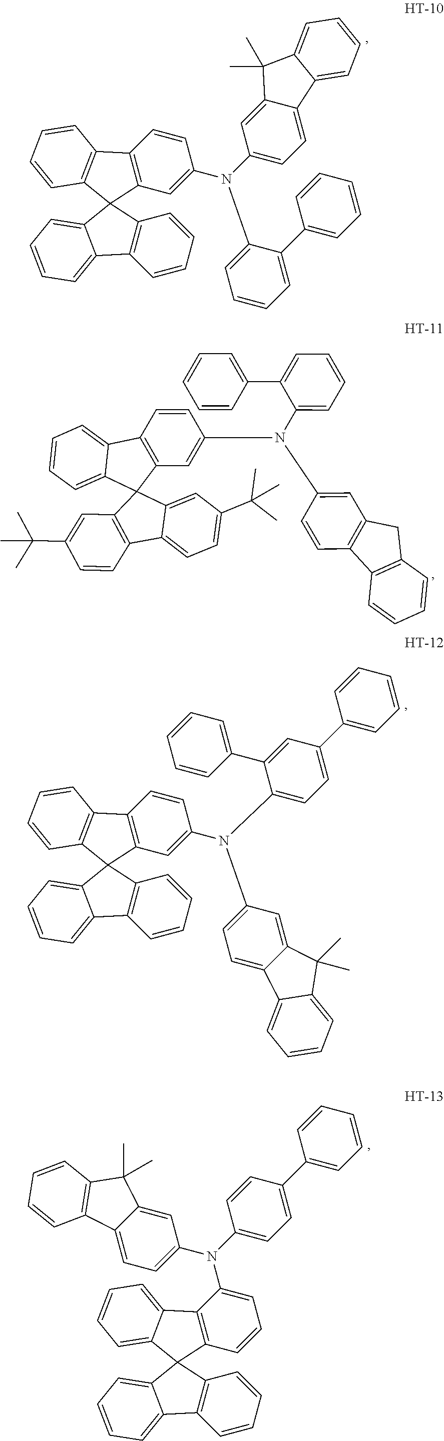 [SMILES: CC1(C)c2ccccc2-c2ccc(N(c3ccc4c(c3)C3(c5ccccc5-c5ccccc53)c3ccccc3-4)c3ccccc3-c3ccccc3)cc21 ; CC(C)(C)c1ccc2c(c1)C1(c3ccccc3-c3ccc(N(c4ccc5c(c4)Cc4ccccc4-5)c4ccccc4-c4ccccc4)cc31)c1cc(C(C)(C)C)ccc1-2 ; CC1(C)c2ccccc2-c2ccc(N(c3ccc4c(c3)C3(c5ccccc5-c5ccccc53)c3ccccc3-4)c3ccc(-c4ccccc4)cc3-c3ccccc3)cc21 ; CC1(C)c2ccccc2-c2ccc(N(c3ccc(-c4ccccc4)cc3)c3cccc4c3-c3ccccc3C43c4ccccc4-c4ccccc43)cc21]

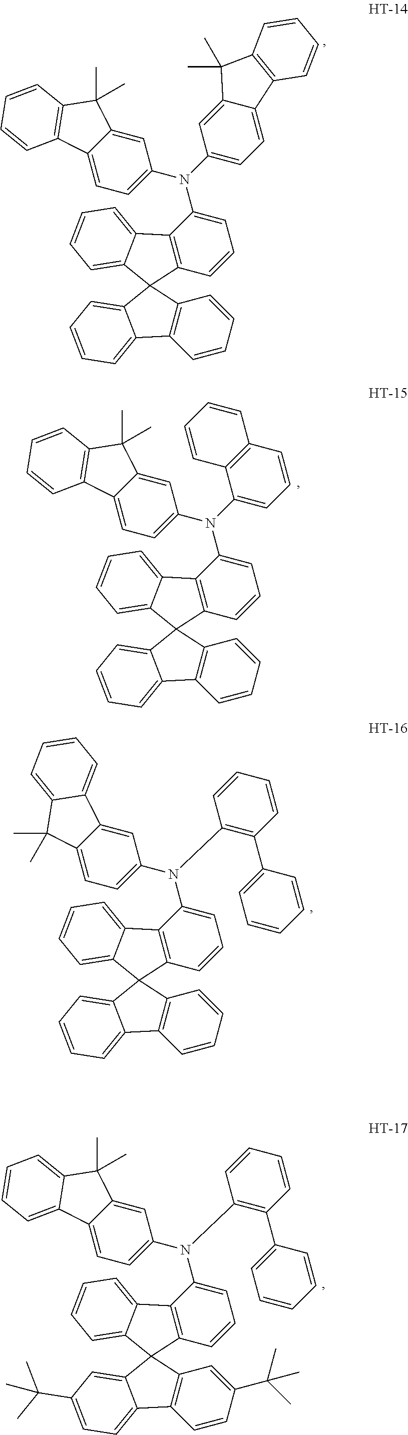

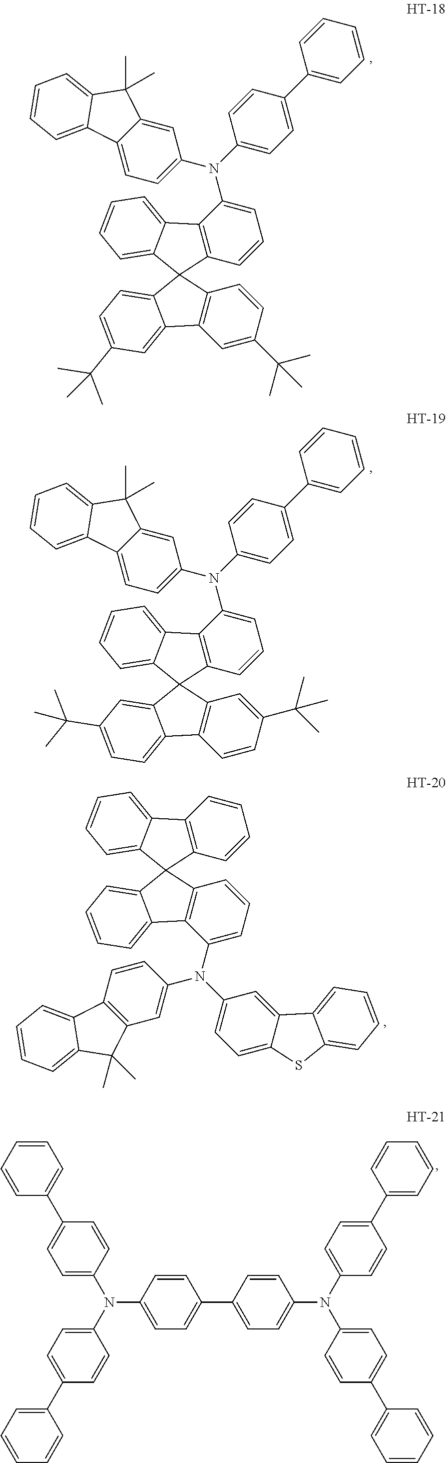

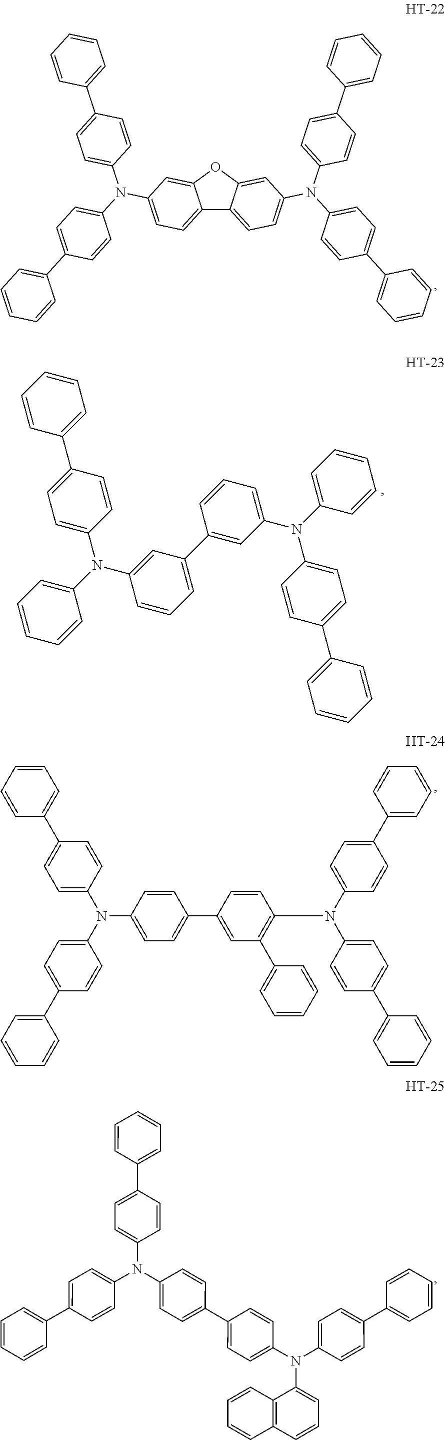 [SMILES: c1ccc(-c2ccc(N(c3ccc(-c4ccccc4)cc3)c3ccc4c(c3)oc3cc(N(c5ccc(-c6ccccc6)cc5)c5ccc(-c6ccccc6)cc5)ccc34)cc2)cc1 ; c1ccc(-c2ccc(N(c3ccccc3)c3cccc(-c4cccc(N(c5ccccc5)c5ccc(-c6ccccc6)cc5)c4)c3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)c(-c5ccccc5)c4)cc3)cc2)cc1 ; c1ccc(-c2ccc(N(c3ccc(-c4ccccc4)cc3)c3ccc(-c4ccc(N(c5ccc(-c6ccccc6)cc5)c5cccc6ccccc56)cc4)cc3)cc2)cc1]

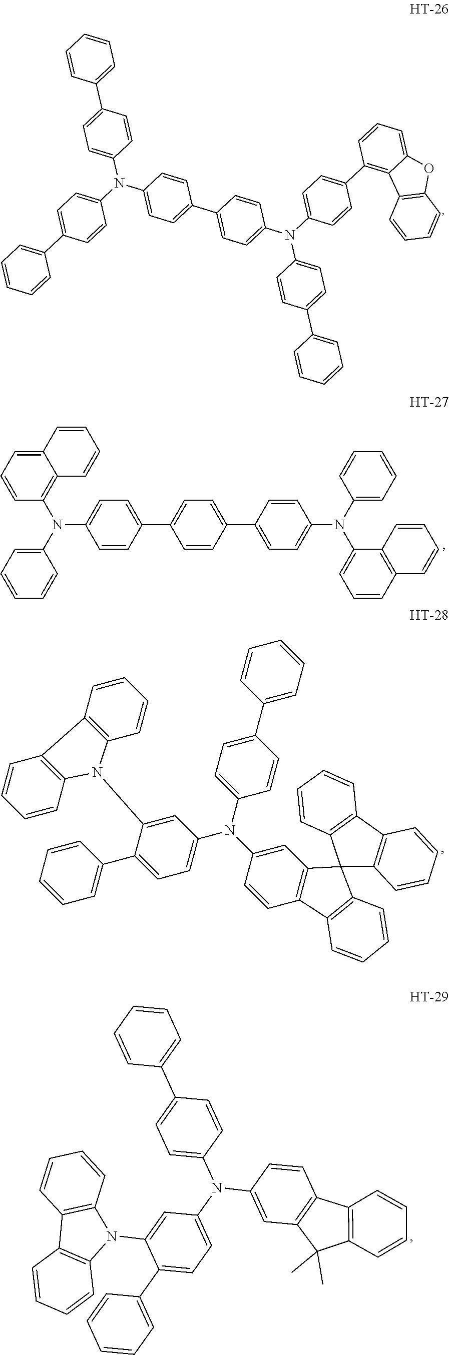 [SMILES: c1ccc(-c2ccc(N(c3ccc(-c4ccccc4)cc3)c3ccc(-c4ccc(N(c5ccc(-c6ccccc6)cc5)c5ccc(-c6cccc7oc8ccccc8c67)cc5)cc4)cc3)cc2)cc1 ; c1ccc(N(c2ccc(-c3ccc(-c4ccc(N(c5ccccc5)c5cccc6ccccc56)cc4)cc3)cc2)c2cccc3ccccc23)cc1 ; c1ccc(-c2ccc(N(c3ccc(-c4ccccc4)c(-n4c5ccccc5c5ccccc54)c3)c3ccc4c(c3)C3(c5ccccc5-c5ccccc53)c3ccccc3-4)cc2)cc1 ; CC1(C)c2ccccc2-c2ccc(N(c3ccc(-c4ccccc4)cc3)c3ccc(-c4ccccc4)c(-n4c5ccccc5c5ccccc54)c3)cc21]

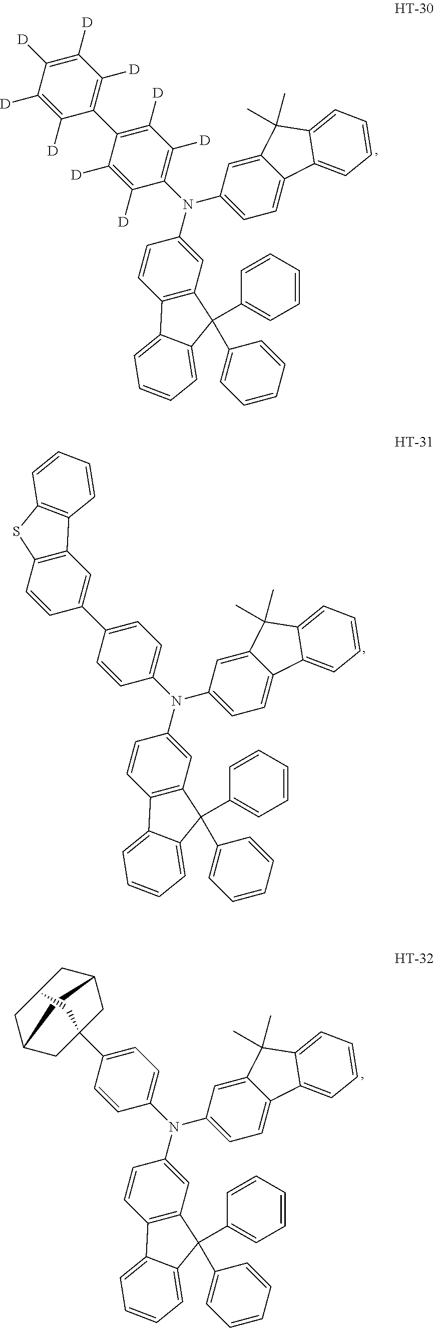 [SMILES: [2H]c1c([2H])c([2H])c(-c2c([2H])c([2H])c(N(c3ccc4c(c3)C(C)(C)c3ccccc3-4)c3ccc4c(c3)C(c3ccccc3)(c3ccccc3)c3ccccc3-4)c([2H])c2[2H])c([2H])c1[2H] ; CC1(C)c2ccccc2-c2ccc(N(c3ccc(-c4ccc5sc6ccccc6c5c4)cc3)c3ccc4c(c3)C(c3ccccc3)(c3ccccc3)c3ccccc3-4)cc21 ; CC1(C)c2ccccc2-c2ccc(N(c3ccc([C@]45C[C@H]6C[C@H](C[C@H](C6)C4)C5)cc3)c3ccc4c(c3)C(c3ccccc3)(c3ccccc3)c3ccccc3-4)cc21]

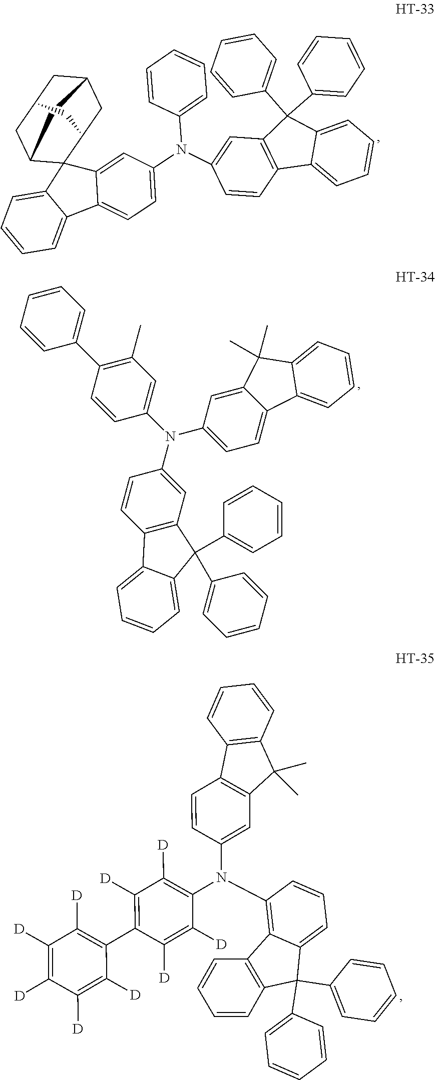

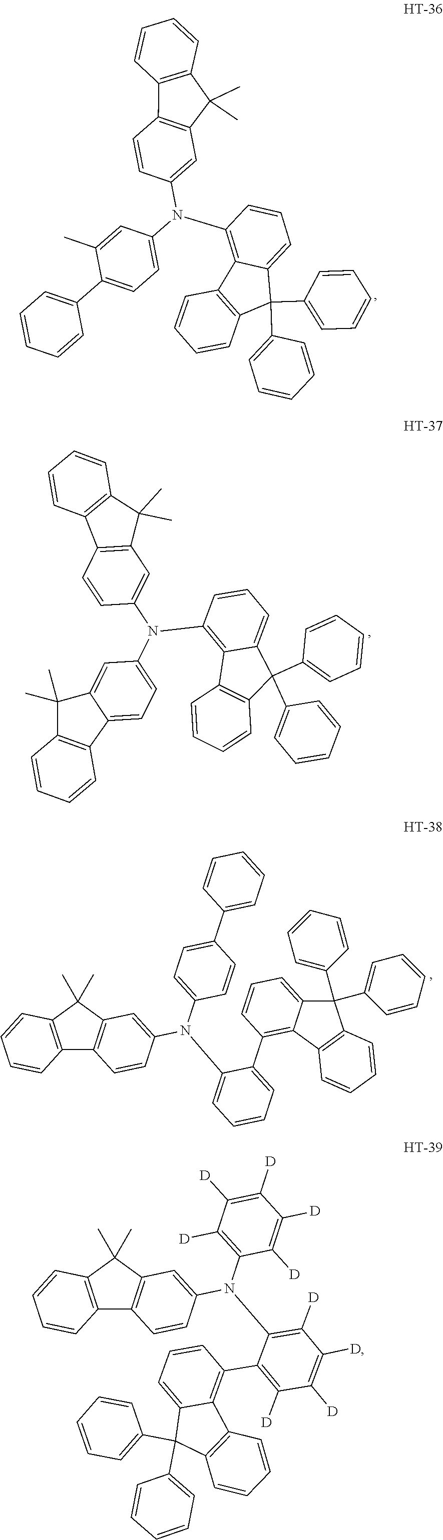

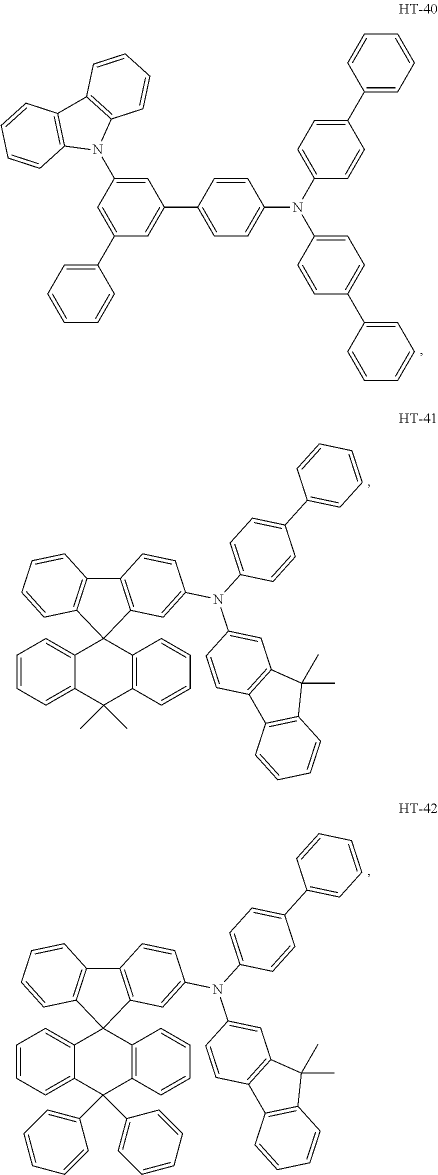 [SMILES: c1ccc(-c2ccc(N(c3ccc(-c4ccccc4)cc3)c3ccc(-c4cc(-c5ccccc5)cc(-n5c6ccccc6c6ccccc65)c4)cc3)cc2)cc1 ; CC1(C)c2ccccc2-c2ccc(N(c3ccc(-c4ccccc4)cc3)c3ccc4c(c3)C3(c5ccccc5-4)c4ccccc4C(C)(C)c4ccccc43)cc21 ; CC1(C)c2ccccc2-c2ccc(N(c3ccc(-c4ccccc4)cc3)c3ccc4c(c3)C3(c5ccccc5-4)c4ccccc4C(c4ccccc4)(c4ccccc4)c4ccccc43)cc21]

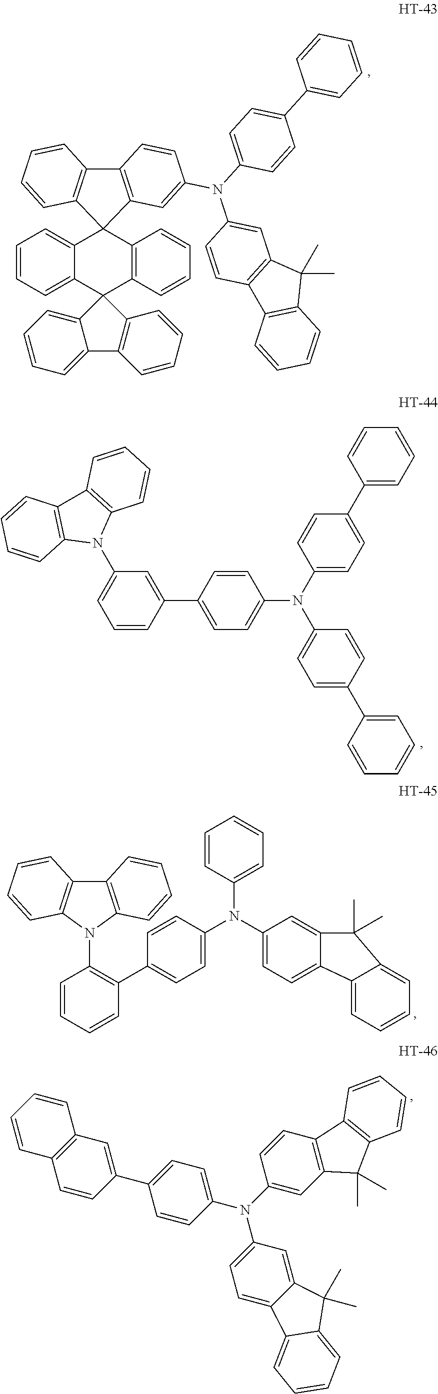

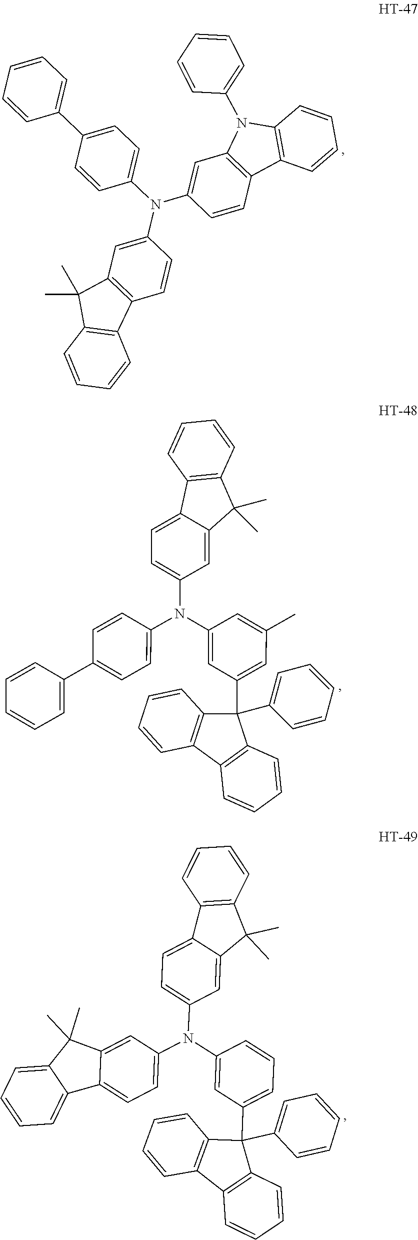

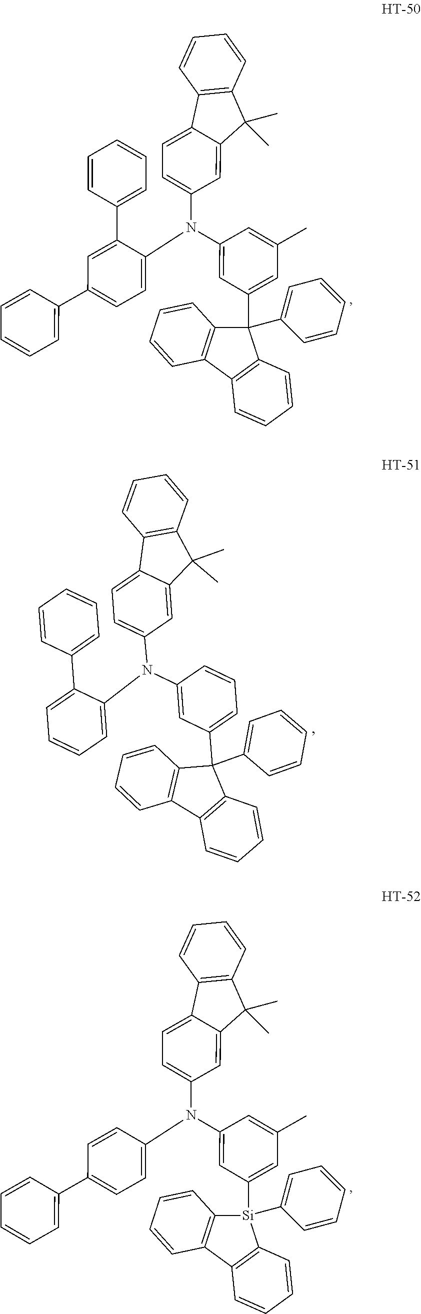 [SMILES: Cc1cc(N(c2ccc3c(c2)C(C)(C)c2ccccc2-3)c2ccc(-c3ccccc3)cc2-c2ccccc2)cc(C2(c3ccccc3)c3ccccc3-c3ccccc32)c1 ; CC1(C)c2ccccc2-c2ccc(N(c3cccc(C4(c5ccccc5)c5ccccc5-c5ccccc54)c3)c3ccccc3-c3ccccc3)cc21 ; Cc1cc(N(c2ccc(-c3ccccc3)cc2)c2ccc3c(c2)C(C)(C)c2ccccc2-3)cc([Si]2(c3ccccc3)c3ccccc3-c3ccccc32)c1]

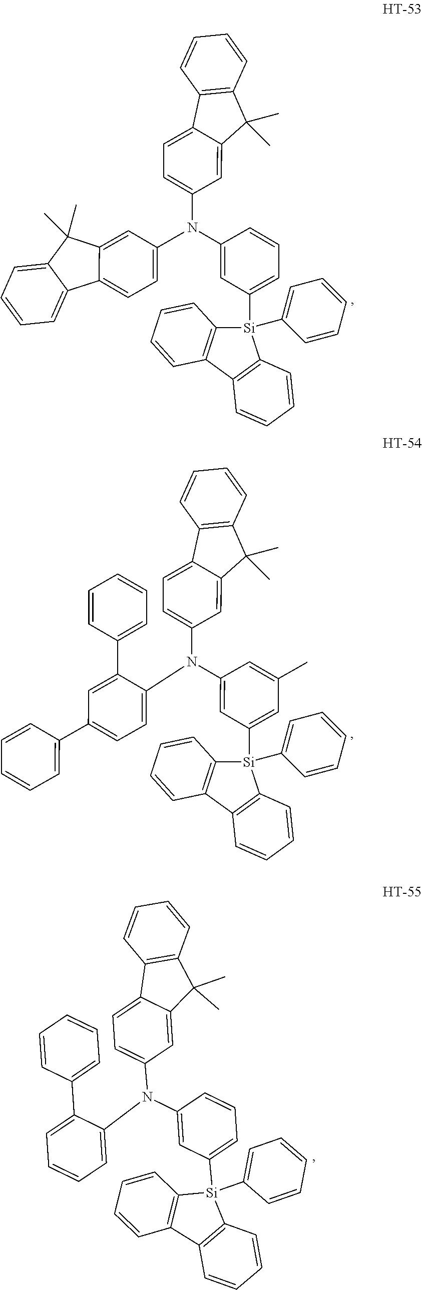 [SMILES: CC1(C)c2ccccc2-c2ccc(N(c3cccc([Si]4(c5ccccc5)c5ccccc5-c5ccccc54)c3)c3ccc4c(c3)C(C)(C)c3ccccc3-4)cc21 ; Cc1cc(N(c2ccc3c(c2)C(C)(C)c2ccccc2-3)c2ccc(-c3ccccc3)cc2-c2ccccc2)cc([Si]2(c3ccccc3)c3ccccc3-c3ccccc32)c1 ; CC1(C)c2ccccc2-c2ccc(N(c3cccc([Si]4(c5ccccc5)c5ccccc5-c5ccccc54)c3)c3ccccc3-c3ccccc3)cc21]

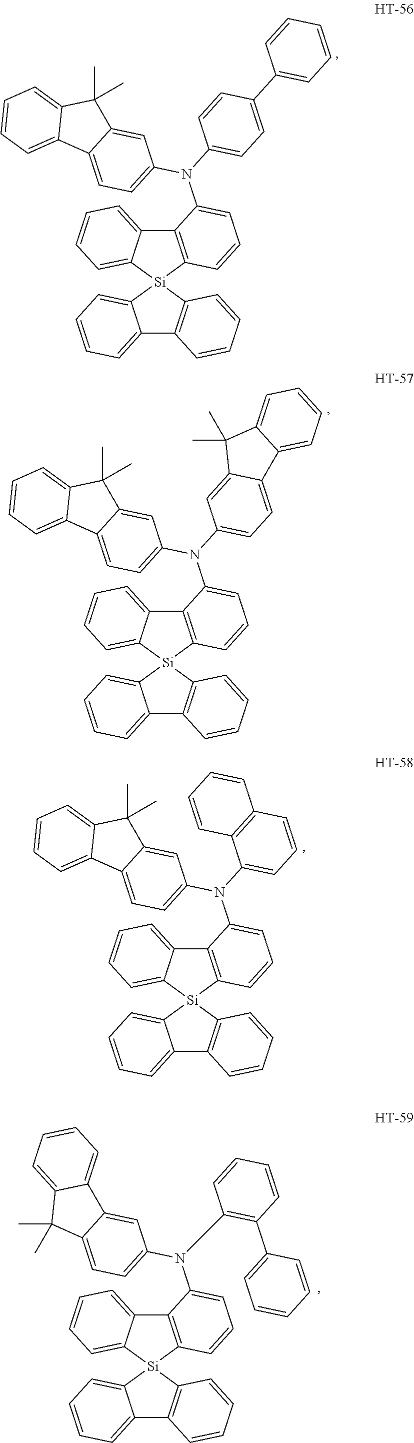

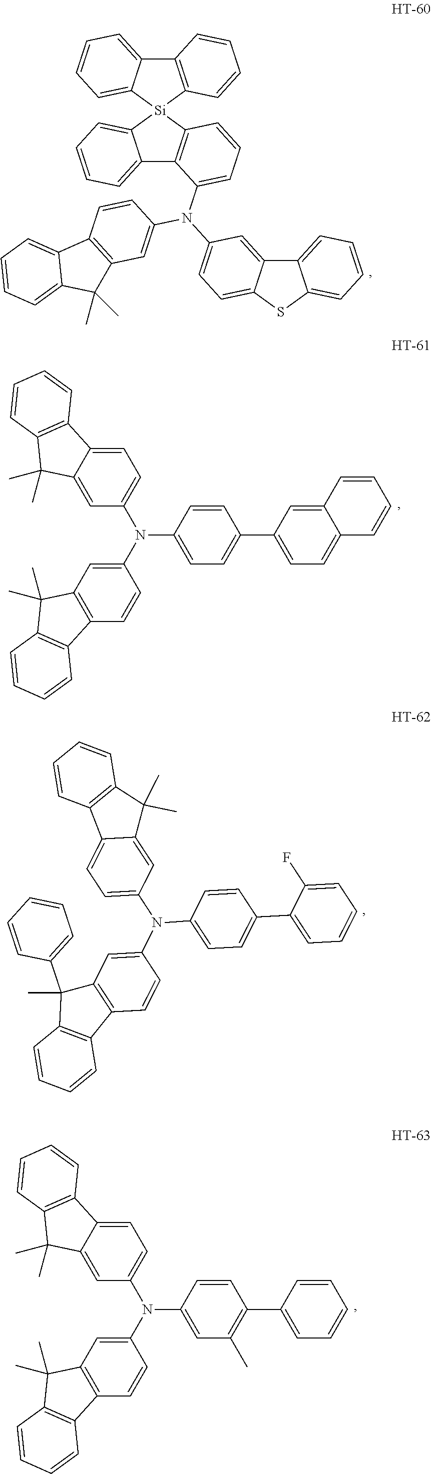 [SMILES: CC1(C)c2ccccc2-c2ccc(N(c3ccc4sc5ccccc5c4c3)c3cccc4c3-c3ccccc3[Si]43c4ccccc4-c4ccccc43)cc21 ; CC1(C)c2ccccc2-c2ccc(N(c3ccc(-c4ccc5ccccc5c4)cc3)c3ccc4c(c3)C(C)(C)c3ccccc3-4)cc21 ; CC1(C)c2ccccc2-c2ccc(N(c3ccc(-c4ccccc4F)cc3)c3ccc4c(c3)C(C)(c3ccccc3)c3ccccc3-4)cc21 ; Cc1cc(N(c2ccc3c(c2)C(C)(C)c2ccccc2-3)c2ccc3c(c2)C(C)(C)c2ccccc2-3)ccc1-c1ccccc1]

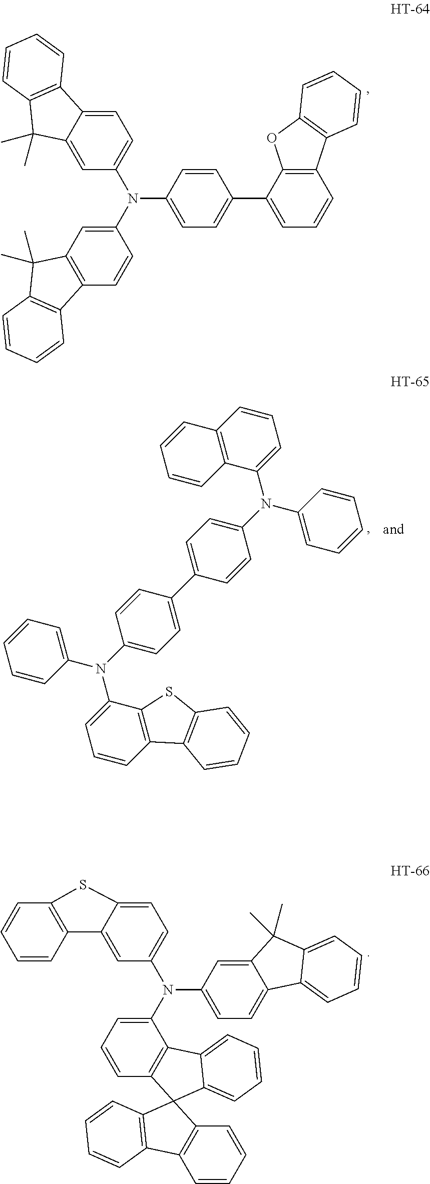 [SMILES: CC1(C)c2ccccc2-c2ccc(N(c3ccc(-c4cccc5c4oc4ccccc45)cc3)c3ccc4c(c3)C(C)(C)c3ccccc3-4)cc21 ; c1ccc(N(c2ccc(-c3ccc(N(c4ccccc4)c4cccc5c4sc4ccccc45)cc3)cc2)c2cccc3ccccc23)cc1 ; CC1(C)c2ccccc2-c2ccc(N(c3ccc4sc5ccccc5c4c3)c3cccc4c3-c3ccccc3C43c4ccccc4-c4ccccc43)cc21]

According to an embodiment of the present disclosure, hydrogen in the structures of Compound HT-1 to Compound HT-66 can be partially or fully substituted with deuterium.

According to an embodiment of the present disclosure, the common P-type charge generation layer and the common hole transport layer are shared by all pixels.

According to an embodiment of the present disclosure, the stacked organic electroluminescent device comprises at least one N-type charge generation layer.

According to an embodiment of the present disclosure, the N-type charge generation layer is shared by at least two adjacent pixels.

According to an embodiment of the present disclosure, the N-type charge generation layer is shared by all pixels.

According to an embodiment of the present disclosure, the N-type charge generation layer comprises at least one metal, and the metal is selected from Yb, Li, Na, K, Zn, Cs, Mg, Ca, Sr, Ba, Sm, Eu or a combination thereof.

According to an embodiment of the present disclosure, the metal is selected from Yb, Li or a combination thereof.

According to an embodiment of the present disclosure, the N-type charge generation layer comprises at least one electron transport material, and the electron transport material comprises at least one substituted or unsubstituted heteroaryl having 3 to 30 carbon atoms.

According to an embodiment of the present disclosure, the electron transport material comprises any one or more chemical structural units selected from the group consisting of: pyridine, pyrimidine, triazine, imidazole, carbazole, cyano, acridine, azine, phosphoroso, sulfone, sulfoxide, benzoxazole, quinone, benzoquinone, quinoxaline, benzoquinoxaline, phenanthroline and benzacridine.

According to an embodiment of the present disclosure, the N-type charge generation layer comprises at least one electron transport material and at least one metal.

According to an embodiment of the present disclosure, the mass ratio of the electron transport material to the metal in the N-type charge generation layer is 10000:1 to 1:10000.

According to an embodiment of the present disclosure, the mass ratio of the electron transport material to the metal in the N-type charge generation layer is 1000:1 to 1:1000.

According to an embodiment of the present disclosure, the mass ratio of the electron transport material to the metal in the N-type charge generation layer is 100:1 to 1:100.

According to an embodiment of the present disclosure, the stacked organic electroluminescent device comprises at least two light-emitting units disposed between the anode and the cathode, and each light-emitting unit comprises at least one light-emitting layer.

According to an embodiment of the present disclosure, the stacked organic electroluminescent device comprises at least three light-emitting units disposed between the anode and the cathode, and each light-emitting unit comprises at least one light-emitting layer.

According to an embodiment of the present disclosure, the stacked organic electroluminescent device comprises at least four light-emitting units disposed between the anode and the cathode, and each light-emitting unit comprises at least one light-emitting layer.

According to an embodiment of the present disclosure, the multiple pixels can emit light of the same color or light of different colors.

According to an embodiment of the present disclosure, an electronic device is further disclosed, which comprises the active matrix organic electroluminescent display in the preceding embodiments.

Combination with Other Materials

The materials described in the present disclosure for a particular layer in an organic light emitting device can be used in combination with various other materials present in the device. The combinations of these materials are described in more detail in U.S. Pat. App. No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, compounds disclosed herein may be used in combination with a wide variety of light-emitting dopants, hosts, transporting layers, blocking layers, injection layers, electrodes, and other layers that may be present. The combination of these materials is described in detail in paragraphs 0080-0101 of U.S. Pat. App. No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (including, but not limited to, evaporator produced by ANGSTROM ENGINEERING, optical testing system produced by SUZHOU FSTAR, life testing system produced by SUZHOU FSTAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this patent.

Herein, the lateral resistance of relevant film layers was measured using the following method. Under a vacuum degree of approximately 10⁻⁶ Torr, on a test substrate pre-patterned with ITO interdigitated electrodes, a first P-type conductive doping material and a first hole transport material were first co-deposited to form a common P-type charge generation layer (Common P-CGL, with a thickness of 100 Å), and a second hole transport material (or a first hole transport material) was deposited by evaporation onto the common P-type charge generation layer to form a common hole transport layer (Common HTL, with a thickness of 400 Å), where the test substrate included a total of 40 ITO fingers, each with a width of 0.02 mm, the 40 ITO fingers formed 39 trench areas, and each trench area had a length of 1.92 mm, a width of 20 μm and a height of 200 nm; at room temperature, a test fixture was clamped onto the ITO electrode, a voltage was applied, and the current was measured, where the voltage range was 3 V to 21 V, with a step size of 3 V; the voltage (V)-current (I) data was recorded, a scatter plot of voltage and current was generated, and the voltage-current line (with the current on the x-axis and the voltage on the y-axis) was obtained by linear fitting. The slope of the line represented the lateral resistance. The lateral resistance of the relevant film layers is recorded and presented in Table 1.

TABLE 1
Resistance data of relevant film layers

| | Film layer structure | | | | Film layer structure | | | |
|---|---|---|---|---|---|---|---|---|
| | | Common | | | | Common | | |
| | Common | hole | | | Common | hole | | |
| | P-type | transport | | | P-type | transport | | |
| | charge | layer | | | charge | layer | | |
| | generation | (second | | | generation | (first | | |
| Film | layer | hole | | Film | layer | hole | | |
| layer | (Common | transport | R₁ | layer | (Common | transport | R₂ | |
| No. | P-CGL) | material) | (MΩ) | No. | P-CGL) | material) | (MΩ) | R₁/R₂ |
| Example | 1-20:HT-11 | HT-13 | 57 | Comparative | 1-20:HT-11 | HT-11 | 30 | 1.9 |
| Film | (20:80, 100 Å) | (400 Å) | | Example | (20:80, 100 Å) | (400 Å) | | |
| Layer 1 | | | | Film | | | | |
| | | | | Layer 1 | | | | |
| Example | 1-20:HT-11 | HT-23 | 166 | Comparative | 1-20:HT-11 | HT-11 | 127 | 1.3 |
| Film | (14:86, 100 Å) | (400 Å) | | Example | (14:86, 100 Å) | (400 Å) | | |
| Layer 2 | | | | Film | | | | |
| | | | | Layer 2 | | | | |
| Example | 1-28:HT-21 | HT-23 | 36 | Comparative | 1-28:HT-21 | HT-21 | 12 | 3.0 |
| Film | (14:86, 100 Å) | (400 Å) | | Example | (14:86, 100 Å) | (400 Å) | | |
| Layer 3 | | | | Film | | | | |
| | | | | Layer 3 | | | | |
| Example | 1-32:HT-61 | HT-13 | 26 | Comparative | 1-32:HT-61 | HT-61 | 6 | 4.3 |
| Film | (20:80, 100 Å) | (400 Å) | | Example | (20:80, 100 Å) | (400 Å) | | |
| Layer 4 | | | | Film | | | | |
| | | | | Layer 4 | | | | |

Herein, the HOMO energy levels of the hole transport materials were measure through cyclic voltammetry (CV). The cyclic voltammetry (CV) was conducted using an electrochemical workstation CorrTest CS120 produced by Wuhan Corrtest Instruments Corp., Ltd., and using a three-electrode working system where a platinum disk electrode served as a working electrode, an Ag/AgNO₃ electrode served as a reference electrode, and a platinum wire electrode served as an auxiliary electrode. With anhydrous DCM as a solvent and 0.1 mol/L tetrabutyl ammonium hexafluorophosphate as a supporting electrolyte, a compound to be tested was prepared into a solution of 10⁻³ mol/L, and the solution was purged with nitrogen for 10 minutes to remove oxygen before the test. The instrument parameters were set as follows: a scan rate of 100 mV/s, a potential interval of 0.5 mV, and a test window ranging from −1 V to 1 V The HOMO energy levels of some of the first hole transport materials and the second hole transport materials were measured using the above method, and the energy level differences were calculated. The data are presented in Table 2.

TABLE 2
HOMO energy levels of some of hole transport materials
and energy level differences thereof

| | Film layer structure | | | | |
|---|---|---|---|---|---|
| | Common | | | | |
| | P-type charge | | | | |
| | generation | | | | |
| | layer | Common hole | | | HOMO₁ − |
| | (Common | transport layer | HOMO₁ | HOMO₂ | HOMO₂ |
| Film layer No. | P-CGL) | (Common HTL) | (eV) | (eV) | (eV) |
| Example Film | 1-20:HT-11 | HT-13 | −5.13 | −5.24 | 0.11 |
| Layer 1 | (20:80, 100 Å) | (400 Å) | | | |
| Example Film | 1-20:HT-11 | HT-23 | −5.13 | −5.33 | 0.20 |
| Layer 2 | (14:86, 100 Å) | (400 Å) | | | |
| Example Film | 1-28:HT-21 | HT-23 | −5.09 | −5.33 | 0.24 |
| Layer 3 | (14:86, 100 Å) | (400 Å) | | | |
| Example Film | 1-32:HT-61 | HT-13 | −5.10 | −5.24 | 0.14 |
| Layer 4 | (20:80, 100 Å) | (400 Å) | | | |
| Comparative | 1-20:HT-11 | HT-11 | −5.13 | / | / |
| Example Film | (20:80, 100 Å) | (400 Å) | | | |
| Layer 1 | | | | | |
| Comparative | 1-20:HT-11 | HT-11 | −5.13 | / | / |
| Example Film | (14:86, 100 Å) | (400 Å) | | | |
| Layer 2 | | | | | |
| Comparative | 1-28:HT-21 | HT-21 | −5.09 | / | / |
| Example Film | (14:86, 100 Å) | (400 Å) | | | |
| Layer 3 | | | | | |
| Comparative | 1-32:HT-61 | HT-61 | −5.10 | / | / |
| Example Film | (20:80, 100 Å) | (400 Å) | | | |
| Layer 4 | | | | | |

The structures of the materials used in the devices are as follows:

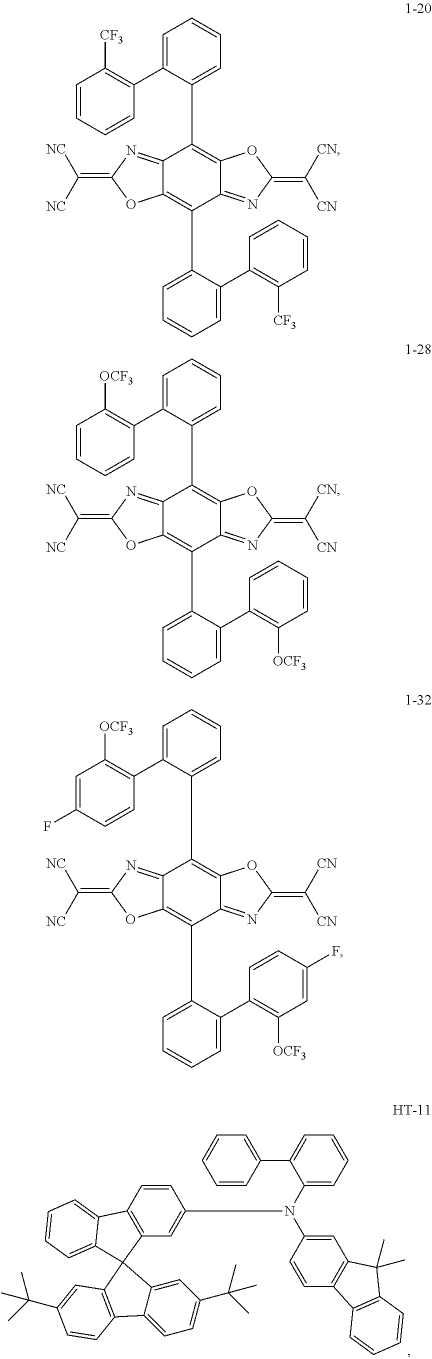

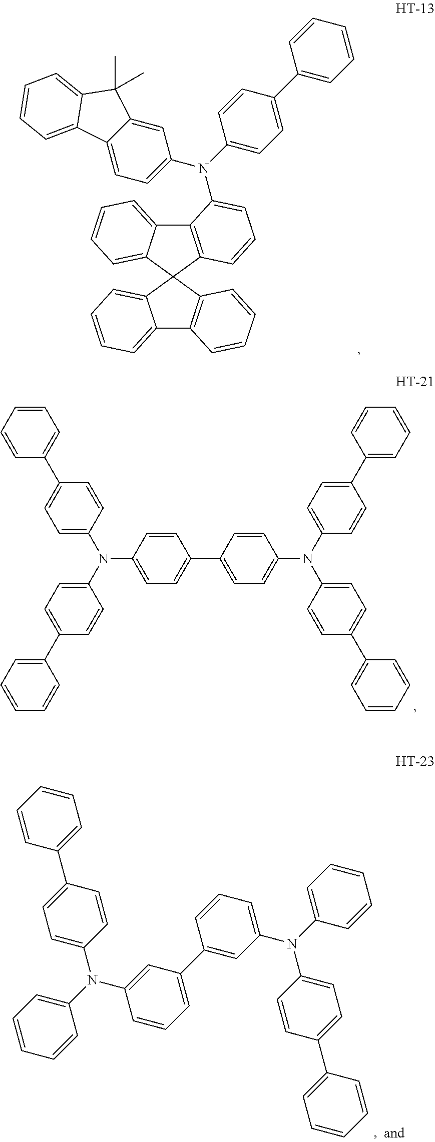 [SMILES: CC1(C)c2ccccc2-c2ccc(N(c3ccc(-c4ccccc4)cc3)c3cccc4c3-c3ccccc3C43c4ccccc4-c4ccccc43)cc21 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2ccc(N(c3ccccc3)c3cccc(-c4cccc(N(c5ccccc5)c5ccc(-c6ccccc6)cc5)c4)c3)cc2)cc1]

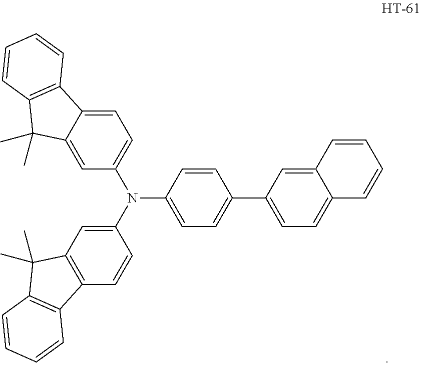 [SMILES: CC1(C)c2ccccc2-c2ccc(N(c3ccc(-c4ccc5ccccc5c4)cc3)c3ccc4c(c3)C(C)(C)c3ccccc3-4)cc21]

As can be seen from Table 1 and Table 2, the common HTL of Comparative Example Film Layers 1 to 4 employs the same hole transport material (the first hole transport material) as that in the common P-CGL, which is a commonly used film layer structure in the industry. However, the inventors have discovered through research that when the second hole transport material with a deeper HOMO energy level is used in the common HTL, the lateral resistance of the film layer can be significantly increased, and the ratio R₁/R₂ is generally higher than 1.1. The lateral resistance values of Example Film Layers 1 to 4 are all more than 1.3 times those of their corresponding Comparative Example Film Layers 1 to 4. In particular, the lateral resistance of Example Film Layer 4 is even 4.3 times that of Comparative Example Film Layer 4 (R₁/R₂=4.3). Therefore, Example Film Layers 1 to 4 possess higher lateral resistance, and consequently, when these example film layers are used as common layers in active matrix OLED displays, the example film layers can more significantly suppress the lateral crosstalk phenomenon between pixels in the display.

The reason may be as follows: When the lateral resistance of the corresponding comparative example film layer is relatively high, the carrier concentration within the film layer is low. Since the Common P-CGL and the Common HTL use the same hole transport material, no potential barrier difference exists, or the potential barrier difference is small, leading to a certain distribution of carriers in both the Common P-CGL and the Common HTL. When the first hole transport material in the Common HTL is replaced with the second hole transport material having a deeper HOMO energy level, a certain potential barrier difference arises between the first hole transport material in the Common P-CGL and the second hole transport material in the Common HTL. Consequently, the distribution of carriers in the Common HTL is significantly reduced, and carrier migration predominantly occurs within the Common P-CGL layer, resulting in a further increase in the lateral resistance of the entire film layer.

In summary, Example Film Layers 1 to 4 utilize, in their Common HTL, the second hole transport material that is different from the first hole transport material used in the Common P-CGL and possesses a deeper HOMO energy level and thus exhibit high lateral resistance (R₁≥15 MΩ). Moreover, compared to the commonly used film layer structures in the industry, Example Film Layers 1 to 4 show significantly enhanced lateral resistance (R₁/R₂ 1.1). Therefore, when these example film layers are employed as common layers in active matrix OLED displays, the example film layers can obviously more significantly suppress lateral current leakage, thereby mitigating the lateral crosstalk phenomenon between pixels in the display. The above conclusion is further verified below through a crosstalk test.

### Crosstalk Test Device Example 1

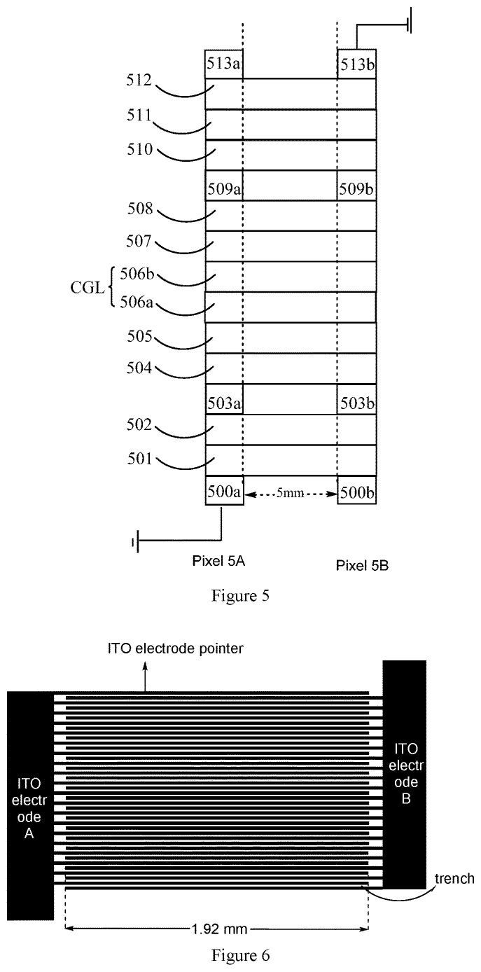

As shown in FIG. 5, a glass substrate having a thickness of 0.7 mm, on which two ITO anodes 500a and 500b with a thickness of 80 nm had been patterned, was washed with deionized water and detergent, and then the anode surfaces were treated with oxygen plasma and UV ozone. The substrate was dried in a glovebox to remove moisture, mounted on a support, and transferred into a vacuum chamber. Organic layers specified below were sequentially deposited through vacuum thermal evaporation on the anode layer at a rate of 0.1 to 10 Angstroms per second and a vacuum degree of about 10⁻⁶ torr. First, a first light-emitting unit was evaporated. Specifically, Compound HT-11 was deposited as a hole transport layer 501 (HTL, 100 Å). Compound HT-B was deposited as an electron blocking layer 502 (EBL, 50 Å). Compound H-1 and Compound BD-1 (at a weight ratio of 96:4) were deposited to form two mutually independent blue light-emitting layers 503a and 503b (EMLs, 250 Å). Compound HB was deposited as a hole blocking layer 504 (HBL, 50 Å). Compound ET and Liq (at a weight ratio of 2:3) were co-deposited as an electron transport layer 505 (ETL, 200 Å). Metal Yb and Compound ET-2 (at a weight ratio of 1:99) were deposited as an N-type charge generation layer 506a (N-CGL, 140 Å). Compound 1-28 and Compound HT-21 (at a weight ratio of 14:86) were deposited as a P-type charge generation layer 506b (P-CGL, 100 Å). Then, a second light-emitting unit was evaporated. Specifically, Compound HT-23 was deposited as a hole transport layer 507 (HTL, 400 Å). Compound HT-B was deposited as an electron blocking layer 508 (EBL, 50 Å). Compound H-1 and Compound BD-1 (at a weight ratio of 96:4) were deposited to form two mutually independent blue light-emitting layers 509a and 509b (EMLs, 250 Å). Compound HB was deposited as a hole blocking layer 510 (HBL, 50 Å). Compound ET and Liq (at a weight ratio of 2:3) were co-deposited as an electron transport layer 511 (ETL, 250 Å). Liq with a thickness of 10 Å was deposited as an electron injection layer 512 (EIL). Metal Al was deposited as cathodes 513a and 513b (1200 Å). The device was transferred back to the glovebox and encapsulated with a glass lid to complete the device.

Crosstalk Test Device Comparative Example 1: The preparation method in Crosstalk Test Device Comparative Example 1 was the same as the preparation method in Crosstalk Test Device Example 1 except that Compound HT-23 was replaced with Compound HT-21 as the hole transport layer 507 (HTL, 400 Å).

The structures of the materials used in the crosstalk test devices are as follows:

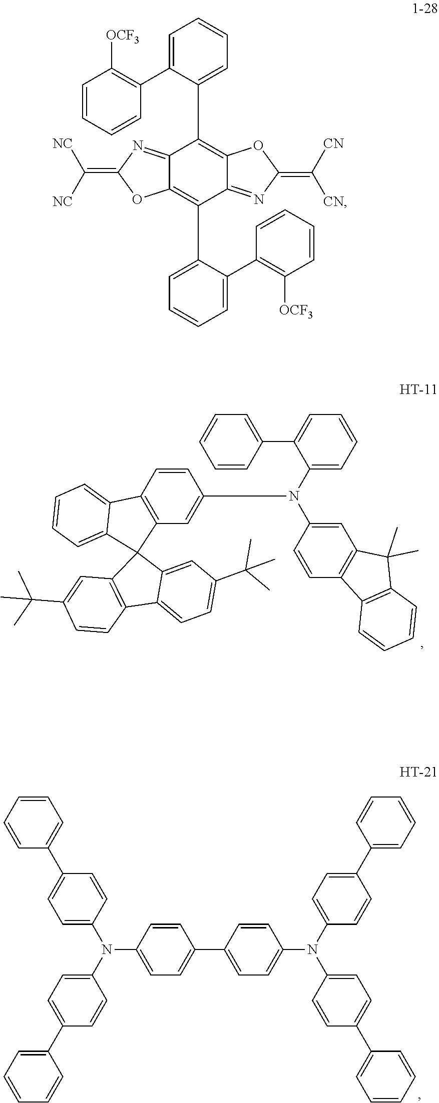 [SMILES: N#CC(C#N)=c1nc2c(-c3ccccc3-c3ccccc3OC(F)(F)F)c3oc(=C(C#N)C#N)nc3c(-c3ccccc3-c3ccccc3OC(F)(F)F)c2o1 ; CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

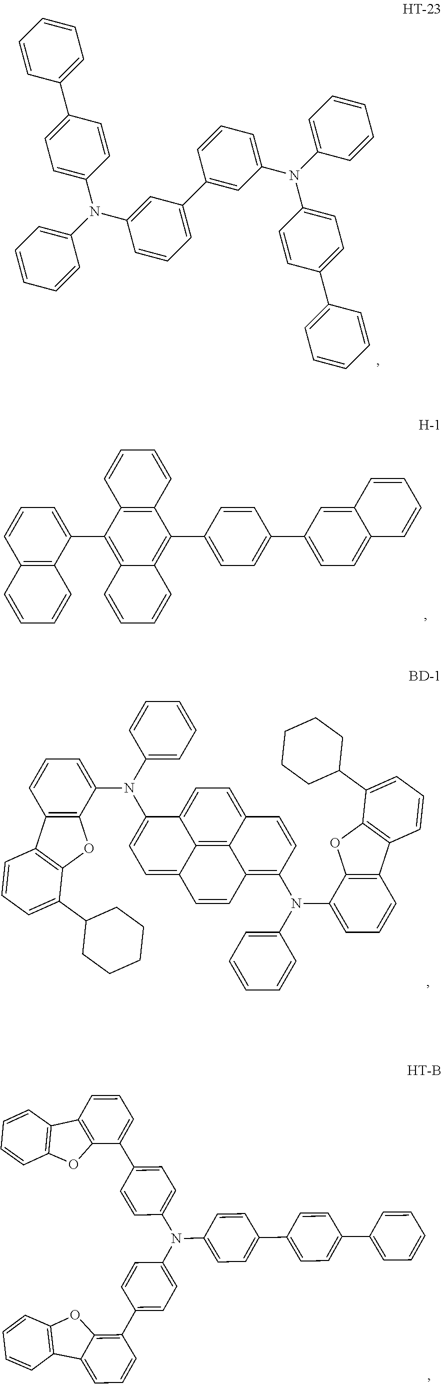

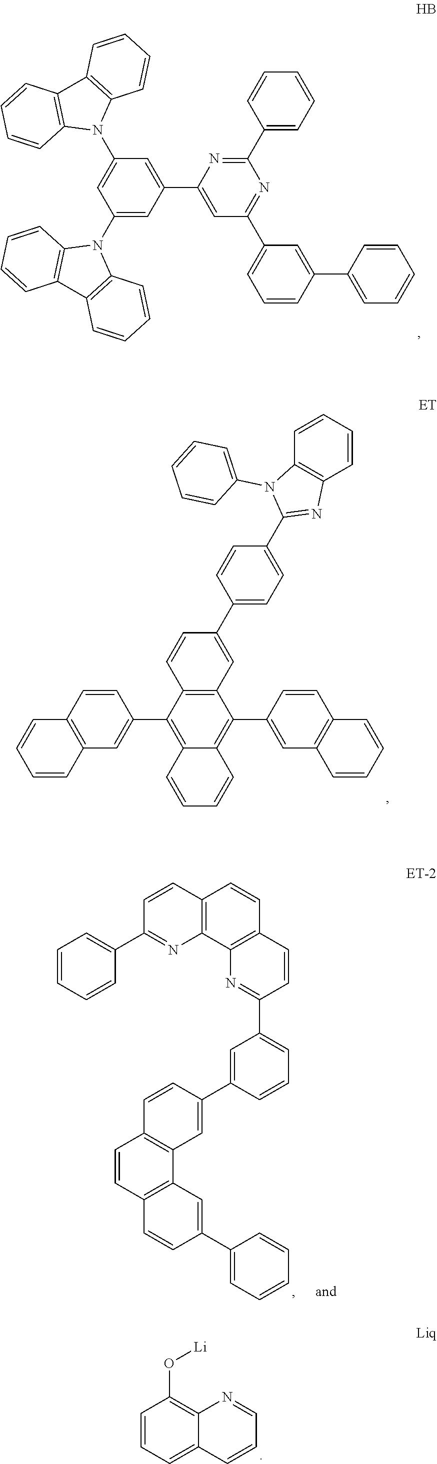

As shown in FIG. 5, the crosstalk test device includes a pixel 5A and a pixel 5B. The anode 500a and the cathode 513b were electrically connected to a driving device, and the brightness (cd/m²) of the pixel 5B was tested at a constant voltage of 21 V. The data are recorded and presented in Table 3.

TABLE 3
Brightness of the pixel 5B of crosstalk test devices

| | Common | | | |
|---|---|---|---|---|
| | P-type | Common | | |
| | charge | hole | | |
| | generation | transport | | |
| | layer | layer | | Bright- |
| | (Common | (Common | Resistance | ness |
| Device No. | P-CGL) | HTL) | (MΩ) | (cd/m²) |
| Crosstalk Test Device | 1-28:HT-21 | HT-23 | 36 | 0 |
| Example 1 | (14:86, 100 Å) | (400 Å) | | |
| Crosstalk Test Device | 1-28:HT-21 | HT-21 | 12 | 0.8 |
| Comparative Example | (14:86, 100 Å) | (400 Å) | | |
| 1 | | | | |

In Crosstalk Test Device Example 1, the Common P-CGL of the pixel 5A and the pixel 5B is composed of the first P-type conductive doping material and the first hole transport material, and the Common HTL is composed of the second hole transport material, that is, the hole transport materials used in the Common P-CGL and the Common HTL are different. As can be seen from the data in Table 3, Crosstalk Test Device Example 1 exhibits high lateral resistance (36 MΩ), and under a constant voltage of 21 V, the measured brightness of the pixel 5B is 0 cd/m². This indicates that in Crosstalk Test Device Example 1, holes can hardly migrate from the pixel 5A to the pixel 5B through the Common P-CGL and the Common HTL, so the pixel 5B does not emit light, demonstrating that the crosstalk between the two pixels is very small or even nonexistent. In contrast, in Crosstalk Test Device Comparative Example 1, the hole transport materials used in the Common P-CGL and the Common HTL of the pixel 5A and the pixel 5B are the same, which is a commonly used film layer structure in the industry. As can be seen from the data in Table 3, the lateral resistance of Crosstalk Test Device Comparative Example 1 is relatively low (12 MΩ), which is lower than the lateral resistance of Crosstalk Test Device Example 1, and under a constant voltage of 21 V, the measured brightness of the pixel 5B in Crosstalk Test Device Comparative Example 1 is 0.8 cd/m², and the pixel 5B emits light with a relatively high brightness, indicating significant lateral crosstalk between the two pixels. The above data analysis indicates that due to the higher lateral resistance of the Common P-CGL layer and the Common HTL of the present disclosure, when applied in active matrix OLED displays, the Common P-CGL layer and the Common HTL can more effectively suppress lateral crosstalk between pixels.

Furthermore, applying the Common P-CGL layer and the Common HTL of the present disclosure in active matrix OLED displays can not only effectively suppress lateral crosstalk between pixels but also enable the devices to achieve excellent device performance. Device examples and device data are provided below for demonstration.

### Device Example

### Embodiment 1

As shown in FIG. 3, a glass substrate having a thickness of 0.7 mm, on which two ITO anodes 310 with a thickness of 80 nm had been patterned, was washed with deionized water and detergent, and then the anode surface was treated with oxygen plasma and UV ozone. The substrate was dried in a glovebox to remove moisture, mounted on a support, and transferred into a vacuum chamber. Organic layers specified below were sequentially deposited through vacuum thermal evaporation on the anode layer 310 at a rate of 0.1 to 10 Angstroms per second and a vacuum degree of about 10⁻⁶ torr. First, a first light-emitting unit 330a was evaporated. Specifically, Compound PD-1 and Compound HT-11 (at a weight ratio of 3:97) were deposited as a hole injection layer 331a (HIL, 100 Å). Compound HT-11 was deposited as a hole transport layer 332a (HTL, 100 Å). Compound HT-B was deposited as an electron blocking layer 333a (EBL, 50 Å). Compound H-1 and Compound BD-1 (at a weight ratio of 96:4) were deposited as a blue light-emitting layer 334a (EML, 250 Å). Compound HB was deposited as a hole blocking layer 335a (HBL, 50 Å). Compound ET and Liq (at a weight ratio of 40:60) were co-deposited as an electron transport layer 336a (ETL, 200 Å). Metal Yb and Compound ET-2 (at a weight ratio of 1:99) were deposited as an N-type charge generation layer 340a (N-CGL, 140 Å). Compound 1-20 and Compound HT-11 (at a weight ratio of 20:80) were deposited as a P-type charge generation layer 340b (P-CGL, 100 Å). Then, a second light-emitting unit 330b was evaporated. Specifically, Compound HT-13 was deposited as a hole transport layer 331b (HTL, 400 Å). Compound HT-B was deposited as an electron blocking layer 332b (EBL, 50 Å). Compound H-1 and Compound BD-1 (at a weight ratio of 96:4) were deposited as a blue light-emitting layer 333b (EML, 250 Å). Compound HB was deposited as a hole blocking layer 334b (HBL, 50 Å). Compound ET and Liq (at a weight ratio of 40:60) were co-deposited as an electron transport layer 335b (ETL, 250 Å). Liq with a thickness of 10 Å was deposited as an electron injection layer 336b (EIL). Metal Al was deposited as a cathode 320 (1200 Å). The device was transferred back to the glovebox and encapsulated with a glass lid to complete the device.

Example 2: The preparation method in Example 2 was the same as the preparation method in Example 1 except that the weight ratio of Compound 1-20 to Compound HT-11 in the P-type charge generation layer 340b was adjusted to 14:86 and Compound HT-23 was deposited as a hole transport layer 331b (HTL, 400 Å).

Example 3: The preparation method in Example 3 was the same as the preparation method in Example 2 except that Compound 1-28 and Compound HT-21 (at a weight ratio of 14:86) were deposited as a P-type charge generation layer 340b (P-CGL, 100 Å).

Example 4: The preparation method in Example 4 was the same as the preparation method in Example 1 except that Compound 1-32 and Compound HT-61 (at a weight ratio of 20:80) were deposited as a P-type charge generation layer 340b (P-CGL, 100 Å).

Comparative Example 1: The preparation method in Comparative Example 1 was the same as the preparation method in Example 2 except that Compound HT-11 was deposited as a hole transport layer 331b (HTL, 400 Å).

Comparative Example 2: The preparation method in Comparative Example 2 was the same as the preparation method in Example 3 except that Compound HT-21 was deposited as a hole transport layer 331b (HTL, 400 Å).

The structures and thicknesses of some layers of the devices are shown in Table 4. A layer using more than one material is obtained by doping different compounds at their weight ratios as recorded.

TABLE 4
Part of device structures in Examples
1 to 4 and Comparative Examples 1 to 2

| | | HTL in |
|---|---|---|
| | | the second |
| | | light- |
| | | emitting |
| Device No. | P-CGL | unit |
| Example 1 | 1-20:HT-11 | HT-13 |
| | (20:80, 100 Å) | (400 Å) |
| Example 2 | 1-20:HT-11 | HT-23 |
| | (14:86, 100 Å) | (400 Å) |
| Example 3 | 1-28:HT-21 | HT-23 |
| | (14:86, 100 Å) | (400 Å) |
| Example 4 | 1-32:HT-61 | HT-13 |
| | (20:80, 100 Å) | (400 Å) |
| Comparative | 1-20:HT-11 | HT-11 |
| Example 1 | (14:86, 100 Å) | (400 Å) |
| Comparative | 1-28:HT-21 | HT-21 |
| Example 2 | (14:86, 100 Å) | (400 Å) |

The structures of the materials used in the devices are as follows:

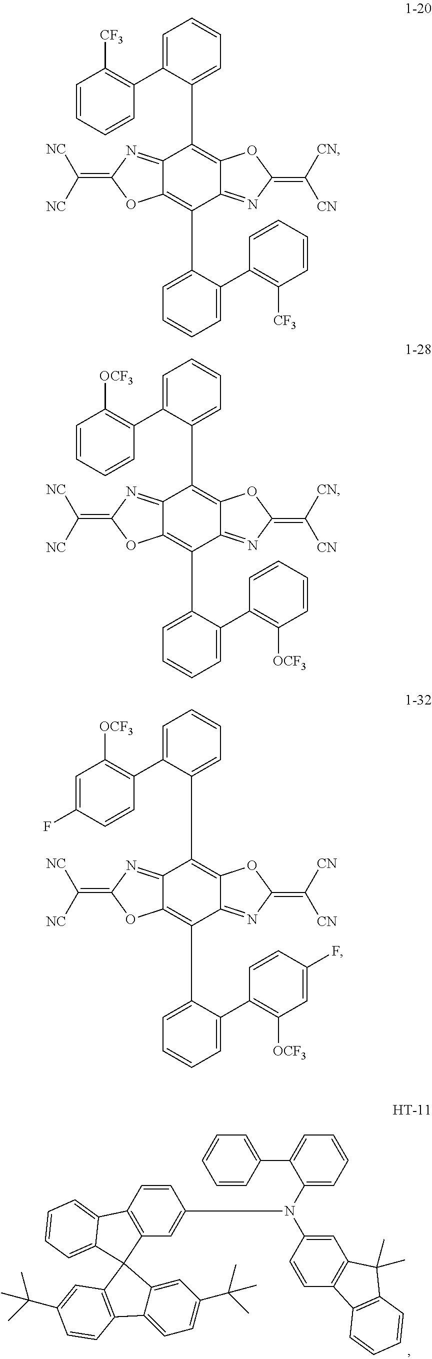

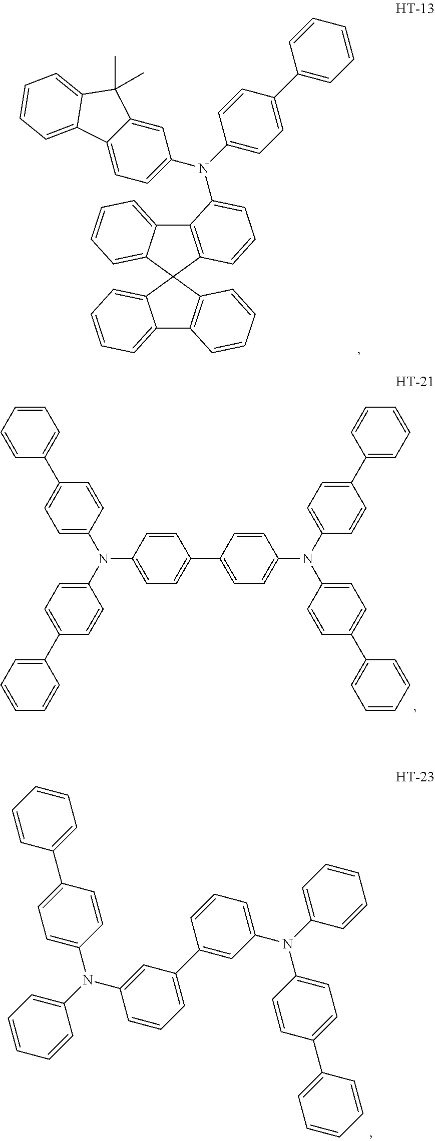 [SMILES: CC1(C)c2ccccc2-c2ccc(N(c3ccc(-c4ccccc4)cc3)c3cccc4c3-c3ccccc3C43c4ccccc4-c4ccccc43)cc21 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2ccc(N(c3ccccc3)c3cccc(-c4cccc(N(c5ccccc5)c5ccc(-c6ccccc6)cc5)c4)c3)cc2)cc1]

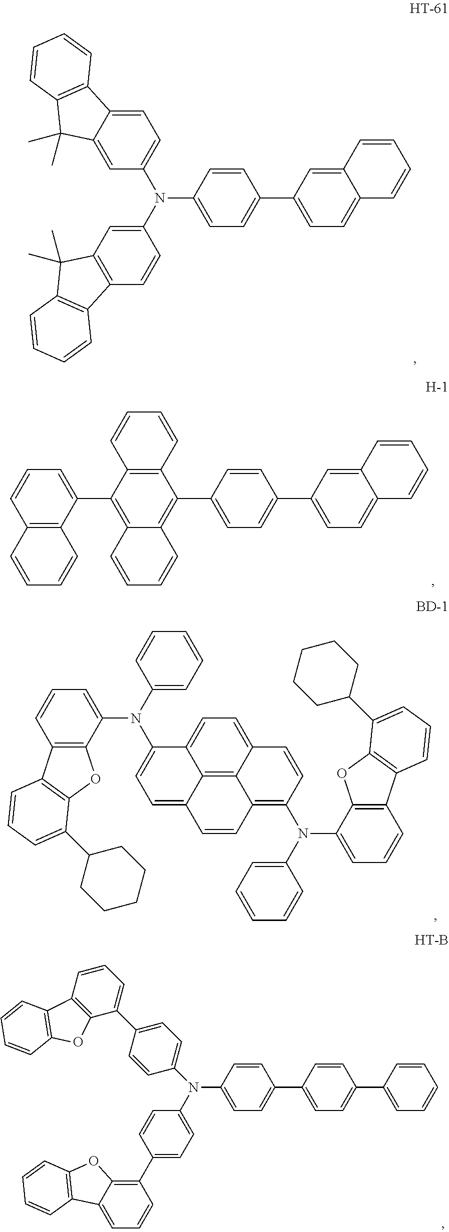

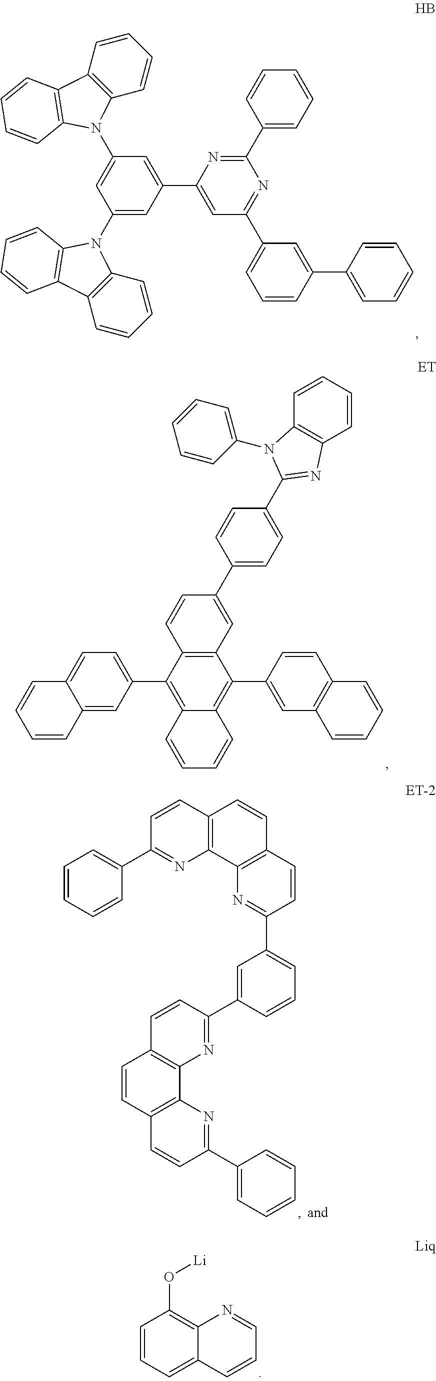

The performance of devices of Examples 1 to 4 and Comparative Examples 1 to 2 is summarized in Table 5. The voltage, current efficiency (CE), power efficiency (PE) and external quantum efficiency (EQE) were measured at a constant current density of 10 mA/cm².

TABLE 5
Device data

| Device No. | Voltage (V) | CE (cd/A) | PE (lm/W) | EQE (%) |
|---|---|---|---|---|
| Example 1 | 7.9 | 11 | 4 | 15 |
| Example 2 | 7.8 | 10 | 4 | 14 |
| Example 3 | 7.9 | 11 | 4 | 15 |
| Example 4 | 7.9 | 11 | 4 | 15 |
| Comparative | 7.8 | 10 | 4 | 14 |
| Example 1 | | | | |
| Comparative | 7.8 | 11 | 5 | 15 |
| Example 2 | | | | |

### Discussion:

In the stacked OLEDs of Comparative Examples 1 to 2, the first P-type conductive doping material and the first hole transport material are used to form the P-type charge generation layer 340b, and the first hole transport material is used to form the hole transport layer 331b, that is, the hole transport materials used in the P-type charge generation layer 340b and the hole transport layer 331b are the same, which is a device structure commonly used in the industry. In Examples 1 to 4 of the present disclosure, the hole transport materials used in the P-type charge generation layer 340b and the hole transport layer 331b are different. As described above, the example film layers of the present disclosure exhibit significantly improved lateral resistance, and when used in active matrix OLED displays, these example film layers can more significantly suppress lateral current leakage, thereby mitigating the lateral crosstalk phenomenon between pixels in the display. Meanwhile, as can be seen from the data in Table 5, the device performance of Comparative Examples 1 to 2 is already at a very high level, featuring a very low device voltage and very high device efficiency (CE, PE, and EQE). Compared with Comparative Examples 1 to 2, Examples 1 to 4 have a substantially comparable low voltage and substantially comparable high efficiency (CE, PE, and EQE) and can maintain excellent device performance. More importantly, the only difference between Example 2 and Comparative Example 1 and between Example 3 and Comparative Example 2 lies in that the hole transport material used in the hole transport layer 331b is different. While the lateral resistance of the relevant film layers in Examples 2 and 3 is significantly increased, the device voltage does not increase or increases only minimally, and Examples 2 and 3 still maintain a low voltage level substantially equivalent to that of the comparative examples, demonstrating that the active matrix organic electroluminescent display of the present disclosure can increase lateral resistance while keeping the device voltage substantially unchanged, which is highly uncommon.

In summary, the active matrix organic electroluminescent display of the present disclosure, due to the possession of a specific common P-type charge generation layer and a common hole transport layer, exhibits significantly improved lateral resistance, thereby significantly suppressing lateral crosstalk between pixels in the display. Meanwhile, the active matrix organic electroluminescent display achieves excellent device performance with low voltage and high efficiency, thereby possessing broad prospects for commercial application.

It should be understood that various embodiments described herein are merely embodiments and not intended to limit the scope of the present disclosure. Therefore, it is apparent to those skilled in the art that the present disclosure as claimed may include variations of specific embodiments and preferred embodiments described herein. Many of the materials and structures described herein may be replaced with other materials and structures without departing from the spirit of the present disclosure. It should be understood that various theories as to why the present disclosure works are not intended to be limitative.

What is claimed is:

1. An active matrix organic electroluminescent display, comprising a plurality of pixels;
wherein each of the plurality of pixels at least comprises a stacked organic electroluminescent device; and
the stacked organic electroluminescent device comprises an anode, a cathode, at least one common P-type charge generation layer disposed between the anode and the cathode, and a common hole transport layer which is disposed between the common P-type charge generation layer and the cathode and is in direct contact with the common P-type charge generation layer;
wherein the common P-type charge generation layer and the common hole transport layer are shared by at least two adjacent pixels;
the common P-type charge generation layer comprises a first P-type conductive doping material and a first hole transport material;
the common hole transport layer comprises a second hole transport material;
the first hole transport material is different from the second hole transport material;
a highest occupied molecular orbital (HOMO) energy level of the first hole transport material is HOMO₁, a HOMO energy level of the second hole transport material is HOMO₂, and HOMO₁−HOMO₂>0 eV; and
the common P-type charge generation layer and the common hole transport layer simultaneously meet the following two conditions:
(1) a lateral resistance of a film layer A formed by the common P-type charge generation layer and the common hole transport layer measured using interdigitated electrodes is R₁, and R₁≥15 MΩ; and
(2) R₁/R₂≥1.1, wherein R₂ is a lateral resistance of a film layer B measured using interdigitated electrodes, and the film layer B is identical to the film layer A except that the second hole transport material in the common hole transport layer of the film layer A is replaced with the first hole transport material.

2. The active matrix organic electroluminescent display of claim 1, wherein R₁≥18 MΩ;
preferably, R₁≥20 MΩ; and
more preferably, R₁≥22 MΩ.

3. The active matrix organic electroluminescent display of claim 1, wherein R₁/R₂≥1.2; and
preferably, R₁/R₂≥1.3.

4. The active matrix organic electroluminescent display of claim 1, wherein HOMO₁−HOMO₂≥0.05 eV; and
preferably, HOMO₁−HOMO₂≥0.10 eV.

5. The active matrix organic electroluminescent display of claim 1, wherein at a constant current density of 10 mA/cm², a voltage of the stacked organic electroluminescent device is less than or equal to 8.6 V;
preferably, at the constant current density of 10 mA/cm², the voltage of the stacked organic electroluminescent device is less than or equal to 8.4 V;
more preferably, at the constant current density of 10 mA/cm², the voltage of the stacked organic electroluminescent device is less than or equal to 8.2 V; and
most preferably, at the constant current density of 10 mA/cm², the voltage of the stacked organic electroluminescent device is less than or equal to 8.0 V.

6. The active matrix organic electroluminescent display of claim 1, wherein a thickness of the common hole transport layer is greater than or equal to 20 nm;
preferably, the thickness of the common hole transport layer is greater than or equal to 40 nm;
more preferably, the thickness of the common hole transport layer is greater than or equal to 60 nm; and
most preferably, the thickness of the common hole transport layer is greater than or equal to 80 nm.

7. The active matrix organic electroluminescent display of claim 1, wherein a lowest unoccupied molecular orbital (LUMO) energy level of the first P-type conductive doping material is LUMO₁, and −5.30 eV≤LUMO₁≤−4.8 eV;
preferably, −5.20 eV≤LUMO₁≤−4.9 eV;
more preferably, −5.15 eV≤LUMO₁≤−4.95 eV; and
most preferably, −5.13 eV≤LUMO₁≤−4.95 eV.

8. The active matrix organic electroluminescent display of claim 1, wherein a LUMO energy level of the first P-type conductive doping material is LUMO₁, the HOMO energy level of the first hole transport material is HOMO₁, and LUMO₁−HOMO₁≥0 eV;
preferably, LUMO₁−HOMO₁≥0.02 eV;
more preferably, LUMO₁−HOMO₁≥0.04 eV; and
most preferably, LUMO₁−HOMO₁>0.06 eV.

9. The active matrix organic electroluminescent display of claim 1, wherein a mass doping proportion of the first P-type conductive doping material in the common P-type charge generation layer is greater than or equal to 7%;
preferably, the mass doping proportion of the first P-type conductive doping material in the common P-type charge generation layer is greater than or equal to 8%;
more preferably, the mass doping proportion of the first P-type conductive doping material in the common P-type charge generation layer is greater than or equal to 9%; and
most preferably, the mass doping proportion of the first P-type conductive doping material in the common P-type charge generation layer is greater than or equal to 10%.

10. The active matrix organic electroluminescent display of claim 1, wherein the P-type conductive doping material is selected from the following compounds: quinones or quinone derivatives, radialene compounds, dehydrobenzooxazole and dehydrobenzothiazole compounds, bisoxazole or bisthiazole compounds, metal oxides, and metal sulfides.

11. The active matrix organic electroluminescent display of claim 1, wherein the hole transport material comprises any one or more chemical structural units selected from the group consisting of triarylamine, carbazole, fluorene, spirobifluorene, thiophene, furan, phenyl, oligophenylene ethylene, oligofluorene and combinations thereof, and
preferably, the hole transport material is a monotriarylamine compound or a bistriarylamine compound.

12. An electronic device, comprising the active matrix organic electroluminescent display of claim 1.
